(19) United States
(12) Patent Application Publication
(10) Pub. No.: US 2018/0175090 A1
(43) Pub. Date: Jun. 21, 2018

(54) NEAR INFRARED ABSORBING COMPOSITION, FILM, NEAR INFRARED CUT FILTER, AND SOLID IMAGE PICKUP ELEMENT

(71) Applicant: FUJIFILM Corporation, Tokyo (JP)

(72) Inventors: Takahiro OKAWARA, Haibara-gun (JP); Takashi KAWASHIMA, Haibara-gun (JP); Kazuto SHIMADA, Haibara-gun (JP); Keisuke ARIMURA, Haibara-gun (JP); Kouitsu SASAKI, Haibara-gun (JP)

(73) Assignee: FUJIFILM Corporation, Tokyo (JP)

(21) Appl. No.: 15/900,197

(22) Filed: Feb. 20, 2018

Related U.S. Application Data
(63) Continuation of application No. PCT/JP2016/070759, filed on Jul. 14, 2016.

(30) Foreign Application Priority Data
Sep. 14, 2015 (JP) 2015-180580
Dec. 11, 2015 (JP) 2015-242111

(51) Int. Cl. H01L 27/146; G02B 5/20; C08K 5/00; C08K 5/33

(52) U.S. Cl. CPC H01L 27/14621; C08K 5/33; C08K 5/0091; G02B 5/208

(57) ABSTRACT

A near infrared absorbing composition includes: a copper compound; a radical trapping agent; and a resin which generates a radical at 180° C. or higher.

### CROSS-REFERENCE TO RELATED APPLICATIONS

This application is a Continuation of PCT International Application No. PCT/JP2016/70759, filed on Jul. 14, 2016, which claims priority under 35 U.S.C. § 119(a) to Japanese Patent Application No. 2015-180580, filed on Sep. 14, 2015 and Japanese Patent Application No. 2015-242111, filed on Dec. 11, 2015. Each of the above application(s) is hereby expressly incorporated by reference, in its entirety, into the present application.

### BACKGROUND OF THE INVENTION

### 1. Field of the Invention

The present invention relates to a near infrared absorbing composition, a film, a near infrared cut filter, and a solid image pickup element.

### 2. Description of the Related Art

In a video camera, a digital still camera, a mobile phone with a camera function, or the like, a charge coupled device (CCD) or a complementary metal-oxide semiconductor (CMOS), which is a solid image pickup element for a color image, is used. In a light receiving section of this solid image pickup element, a silicon photodiode having sensitivity to near infrared light is used. Therefore, it is necessary to correct visibility, and a near infrared cut filter is used in many cases.

JP2014-32380A and WO2014/168221A describe that a near infrared cut filter is manufactured using a near infrared absorbing composition including a copper compound.

### SUMMARY OF THE INVENTION

According to the investigation by the present inventors, it was found that a resin which generates a radical by heating has relatively high compatibility with a copper compound. However, it was found that, in a near infrared cut filter manufactured using a near infrared absorbing composition including a copper compound and a resin which generates a radical by heating, discoloration may occur by heating, and heat resistance may be insufficient. In a case where the heat resistance of the near infrared cut filter is low, discoloration may occur by heating, and visible transparency or infrared shielding properties may deteriorate. Recently, further improvement of heat resistance has been required.

Accordingly, an object of the present invention is to provide a near infrared absorbing composition with which a film having excellent heat resistance can be manufactured, a film, a near infrared cut filter, a solid image pickup element, a camera module, and an image display device.

As a result of thorough investigation, the present inventors found that a film having excellent heat resistance can be manufactured by adding a radical trapping agent to a near infrared absorbing composition, thereby completing the present invention. The present invention provides the following.

<1> A near infrared absorbing composition comprising:

a copper compound;

a radical trapping agent; and

a resin which generates a radical at 180° C. or higher.

<2> The near infrared absorbing composition according to <1>,

in which the copper compound is a copper complex which includes a compound having a carbon atom bonded to a hydrogen atom as a ligand.

<3> The near infrared absorbing composition according to <1> or <2>,

in which the copper compound is a copper complex which includes a compound having a coordination site coordinated by an unshared electron pair as a ligand.

<4> The near infrared absorbing composition according to any one of <l> to <3>,

in which the copper compound is a copper complex which includes a compound having at least two coordination sites as a ligand.

<5> The near infrared absorbing composition according to any one of <l> to <4,

wherein the radical trapping agent is at least one selected from the group consisting of an oxime compound, a hindered amine compound, a hindered phenol compound, a sulfur-based peroxide decomposition product, a phosphorus-based peroxide decomposing agent, an N-oxyl compound, an alkylphenone compound, an aldehyde compound, and a hydroxylamine compound.

<6> The near infrared absorbing composition according to any one of <l> to <5>,

in which the radical trapping agent is a compound represented by the following Formula (I), and

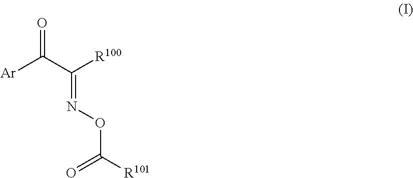

in Formula (I), Ar¹⁰⁰ represents an aryl group or a heterocyclic group, and R¹⁰⁰ and R¹⁰¹ each independently represent an alkyl group, an aryl group, or a heterocyclic group.

<7> The near infrared absorbing composition according to any one of <l> to <6>,

in which the radical trapping agent is an oxime compound having an amide type structure.

<8> The near infrared absorbing composition according to any one of <l> to <6>,

in which the radical trapping agent is an oxime compound having two or more partial structures represented by the following Formula (OX) in one molecule, and

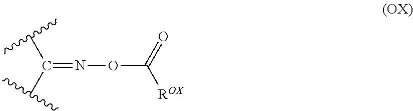

in Formula (OX), R^{OX} represents an alkyl group, an aryl group, or a heterocyclic group, and a wave line represents a linking site to an atomic group constituting the oxime compound.

<9> The near infrared absorbing composition according to any one of claims 1 to 8,

in which a content of the radical trapping agent is 0.1 to 30 mass % with respect to a total solid content of the near infrared absorbing composition.

<10> The near infrared absorbing composition according to any one of <l> to <9>,

in which a content of the copper compound is 25 to 75 mass % with respect to a total solid content of the near infrared absorbing composition.

<11> The near infrared absorbing composition according to any one of <1> to <10>,

in which the resin which generates a radical at 180° C. or higher has a partial structure represented by the following (a) or (b) at a main chain or a side chain of a repeating unit, and

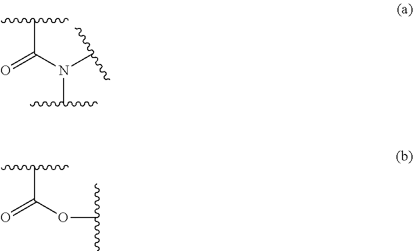

in (a) or (b), a wave line represents a linking site to an atomic group constituting the repeating unit of the resin.

<12> The near infrared absorbing composition according to any one of <1> to <10>,

in which the resin which generates a radical at 180° C. or higher includes a repeating unit represented by the following Formula (A),

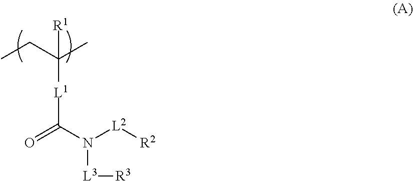

in Formula (A), R¹ represents a hydrogen atom or an alkyl group, L¹ to L³ each independently represent a single bond or a divalent linking group, R² and R³ each independently represent an aliphatic hydrocarbon group or an aromatic group,

R² may be bonded to a carbon atom of a main chain of the repeating unit or R³ to form a ring, and

L² may be bonded to a carbon atom of a main chain of the repeating unit to form a ring, and in a case where L² is bonded to a carbon atom of a main chain of the repeating unit to form a ring, R² is not present.

<13> The near infrared absorbing composition according to any one of <1> to <12>,

in which the resin which generates a radical at 180° C. or higher includes a repeating unit having a crosslinking group.

<14> The near infrared absorbing composition according to any one of <l> to <13>, further comprising:

a compound having a crosslinking group as a component other than the resin which generates a radical at 180° C. or higher.

<15> A film which is obtained using the near infrared absorbing composition according to any one of <l> to <14>.

<16> A near infrared cut filter which is obtained using the near infrared absorbing composition according to any one of <1> to <14>.

<17> A solid image pickup element comprising:

the near infrared cut filter according to <16>.

According to the present invention, it is possible to provide a near infrared absorbing composition with which a film having excellent heat resistance can be manufactured, a film, a near infrared cut filter, and a solid image pickup element.

### BRIEF DESCRIPTION OF THE DRAWINGS

FIG. 1 is a schematic cross-sectional view showing a configuration of a camera module including a near infrared cut filter according to an embodiment of the present invention.

FIG. 2 is a schematic cross-sectional view showing an example of the vicinity of the near infrared cut filter in the camera module.

FIG. 3 is a schematic cross-sectional view showing an example of the vicinity of the near infrared cut filter in the camera module.

FIG. 4 is a schematic cross-sectional view showing an example of the vicinity of the near infrared cut filter in the camera module.

### DESCRIPTION OF THE PREFERRED EMBODIMENTS

Hereinafter, the details of the present invention will be described. In this specification of the present application, numerical ranges represented by “to” include numerical values before and after “to” as lower limit values and upper limit values.

In this specification, “(meth)acrylate” denotes either or both of acrylate or methacrylate, “(meth)allyl” denotes either or both of allyl and methallyl, “(meth)acryl” denotes either or both of acryl and methacryl, and “(meth)acryloyl” denotes either or both of acryloyl and methacryloyl.

In this specification, unless specified as a substituted group or as an unsubstituted group, a group (atomic group) denotes not only a group (atomic group) having no substituent but also a group (atomic group) having a substituent.

In this specification, in a chemical formula, Me represents a methyl group, Et represents an ethyl group, Pr represents a propyl group, Bu represents a butyl group, and Ph represents a phenyl group.

In this specification, “near infrared light” denotes light (electromagnetic wave) in a wavelength range of 700 to 2500 nm.

In this specification, a total solid content denotes the total mass of components of a composition excluding a solvent.

In this specification, a solid content denotes a solid content at 25° C.

In this specification, a weight-average molecular weight and a number-average molecular weight are defined as values in terms of polystyrene obtained by gel permeation chromatography (GPC).

<Near Infrared Absorbing Composition>

A near infrared absorbing composition according to the present invention includes, a copper compound, a radical trapping agent, and a resin which generates a radical at 180° C. or higher. By using the near infrared absorbing composition according to the present invention, a film (near infrared cut filter) having excellent infrared shielding properties, visible transparency, and heat resistance can be manufactured. The mechanism for the effect is presumed to be as follows. The reason why discoloration occurs by heating in a film including a copper compound is presumed to be that a radical which is generated from a resin by heating, for example, during or after the manufacturing of the film reacts with the copper compound such that the copper compound is discolored. The near infrared absorbing composition according to the present invention includes the radical trapping agent. Therefore, a radical generated from the resin or the like is trapped by the radical trapping agent, and a reaction between the radical and the copper compound can be suppressed. Thus, it is presumed that a film having excellent heat resistance in which discoloration caused by heating is suppressed can be manufactured.

Hereinafter, each component of the near infrared absorbing composition according to the present invention will be described.

<<Radical Trapping Agent>>

The near infrared absorbing composition according to the present invention includes a radical trapping agent. By the near infrared absorbing composition according to the present invention including the radical trapping agent, even in a case where the resin or the like is thermally decomposed to generate a radical by heating during or after the manufacturing of a film, the radical generated in the composition is trapped by the radical trapping agent. Therefore, a reaction between the copper compound and the radical can be suppressed, and a film having excellent heat resistance in which discoloration caused by heating is suppressed can be manufactured. That is, in the near infrared absorbing composition according to the present invention, the radical trapping agent traps a radical generated from the resin or the like by heating such that a reaction between the radical and the copper compound is suppressed.

In the present invention, examples of the radical trapping agent include an oxime compound, a hindered amine compound, a hindered phenol compound, a sulfur-based peroxide decomposition product, a phosphorus-based peroxide decomposing agent, an N-oxyl compound, an alkylphenone compound, an aldehyde compound, a hydroxylamine compound, an α-hydroxy ketone compound, an acetophenone compound, a benzophenone compound, a benzoin compound, a benzoin ether compound, an aminoalkylphenone compound, and a thio compound. Among these, an oxime compound, a hindered amine compound, a hindered phenol compound, a sulfur-based peroxide decomposition product, a phosphorus-based peroxide decomposing agent, an N-oxyl compound, an alkylphenone compound, an aldehyde compound, or a hydroxylamine compound is preferable, an oxime compound, an alkylphenone compound, or an aldehyde compound is more preferable, and an oxime compound is still more preferable. The molecular weight of the oxime compound is preferably 300 or higher and more preferably 500 or higher. The upper limit is, for example, 2000 or lower. By increasing the molecular weight, volatilization is suppressed during heating. Therefore, excellent radical trapping performance is likely to be obtained. In addition, an oxime compound having a non-conjugated substituent or a compound two or more partial structures represented by Formula (OX) shown below in one molecule is preferable because excellent radical trapping performance can be obtained while increasing the molecular weight.

As the oxime compound, an oxime ether compound or an oxime ester compound is preferable, and an oxime ester compound is more preferable. In particular, by using the oxime ester compound, a film having excellent heat resistance can be easily obtained. In addition, as the oxime ester compound, a ketoxime ester compound is preferable. As the oxime compound, a compound represented by the following Formula (I) is preferable.

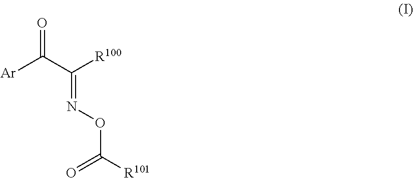

In Formula (I), Ar¹⁰⁰ represents an aryl group or a heterocyclic group, and R¹⁰⁰ and R¹⁰¹ each independently represent an alkyl group, an aryl group, or a heterocyclic group.

Ar¹⁰⁰ represents an aryl group or a heterocyclic group and preferably an aryl group.

The number of carbon atoms in the aryl group is preferably 6 to 20, more preferably 6 to 15, and still more preferably 6 to 10.

It is preferable that the heterocyclic group is a 5- or 6-membered ring. The heterocyclic group may be a monocycle or a fused ring. The number of rings composing the fused ring is preferably 2 to 8, more preferably 2 to 6, still more preferably 3 to 5, and even still more preferably 3 or 4. The number of carbon atoms constituting the heterocyclic group is preferably 3 to 40, more preferably 3 to 30, and still more preferably 3 to 20. The number of heteroatoms constituting the heterocyclic group is preferably 1 to 3. It is preferable that the heteroatoms constituting the heterocyclic group are a nitrogen atom, an oxygen atom, or a sulfur atom.

The aryl group and the heterocyclic group represented by Ar¹⁰⁰ may be unsubstituted or may have a substituent. Examples of the substituent include an alkyl group, an aryl group, a heterocyclic group, a nitro group, a cyano group, a halogen atom, —OR^{X1}, —SR^{X1}, —COR^{X1}, —COOR^{X1}, —OCOR^{X1}, —NR^{X1}R^{X2}, —NHCOR^{X1}, —CONR^{X1}R^{X2}, —NHCONR^{X1}R^{X2}, —NHCOOR^{X1}, —SO₂R^{X1}, —SO₂OR^{X1}, and —NHSO₂R^{X1}. R^{X1} and R^{X2} each independently represent a hydrogen atom, an alkyl group, an aryl group, or a heterocyclic group. As the substituent, for example, —SR^{X1} or —NHCOR^{X1} is preferable. In addition, as the substituent, a group having an amide structure is also preferable, and —NHCOR^{X1} is more preferable.

Examples of the halogen atom include a fluorine atom, a chlorine atom, a bromine atom, and an iodine atom.

The number of carbon atoms in the alkyl group as the substituent and the alkyl group represented by R^{X1} and R^{X2} is preferably 1 to 20. The alkyl group may be linear, branched, or cyclic and is preferably linear or branched. In the alkyl group, some or all of the hydrogen atoms may be substituted with a halogen atom. In addition, at least a portion or all of the hydrogen atoms in the alkyl group may be substituted with the above-described substituent.

The number of carbon atoms in the aryl group as the substituent and the aryl group represented by R^{X1} and R^{X2} is preferably 6 to 20, more preferably 6 to 15, and still more preferably 6 to 10. The aryl group may be a monocycle or a fused ring. In addition, at least a portion or all of the hydrogen atoms in the aryl group may be substituted with the above-described substituent.

The heterocyclic group as the substituent and the heterocyclic group represented by R^{X1} and R^{X2} are preferably a 5- or 6-membered ring. The heterocyclic group may be a monocycle or a fused ring. The number of carbon atoms constituting the heterocyclic group is preferably 3 to 30, more preferably 3 to 18, and still more preferably 3 to 12. The number of heteroatoms constituting the heterocyclic group is preferably 1 to 3. It is preferable that the heteroatoms constituting the heterocyclic group are a nitrogen atom, an oxygen atom, or a sulfur atom. In addition, at least a portion or all of the hydrogen atoms in the hetero group may be substituted with the above-described substituent.

R¹⁰⁰ and R¹⁰¹ each independently represent an alkyl group, an aryl group, or a heterocyclic group and preferably an alkyl group or an aryl group. Among these, it is preferable that one of R¹⁰⁰ and R¹⁰¹ represents an alkyl group and the other one of R¹⁰⁰ and R¹⁰¹ represents an aryl group, and it is more preferable that R¹⁰⁰ represents an alkyl group and R¹⁰¹ represents an aryl group.

The number of carbon atoms in the alkyl group is preferably 1 to 20, more preferably 1 to 15, and still more preferably 1 to 10. The alkyl group may be linear, branched, or cyclic and is preferably linear or branched.

The number of carbon atoms in the aryl group is preferably 6 to 20, more preferably 6 to 15, and still more preferably 6 to 10.

It is preferable that the heterocyclic group is a 5- or 6-membered ring. The heterocyclic group may be a monocycle or a fused ring. The number of rings composing the fused ring is preferably 2 to 8, more preferably 2 to 6, still more preferably 3 to 5, and even still more preferably 3 or 4. The number of carbon atoms constituting the heterocyclic group is preferably 3 to 40, more preferably 3 to 30, and still more preferably 3 to 20. The number of heteroatoms constituting the heterocyclic group is preferably 1 to 3. It is preferable that the heteroatoms constituting the heterocyclic group are a nitrogen atom, an oxygen atom, or a sulfur atom.

The groups represented by R¹⁰⁰ and R¹⁰¹ may have a substituent or may be unsubstituted. Examples of the substituent include the substituents described above regarding Ar¹⁰⁰.

As a commercially available product of the oxime compound, for example, IRGACURE-OXE01 (manufactured by BASF SE), IRGACURE-OXE02 (manufactured by BASF SE), TR-PBG-304 (manufactured by Changzhou Tronly New Electronic Materials Co., Ltd.), or ADEKA ARKLS NCI-930 (manufactured by Adeka Corporation) can be used. In addition, as the oxime compound, the following compound can also be used.

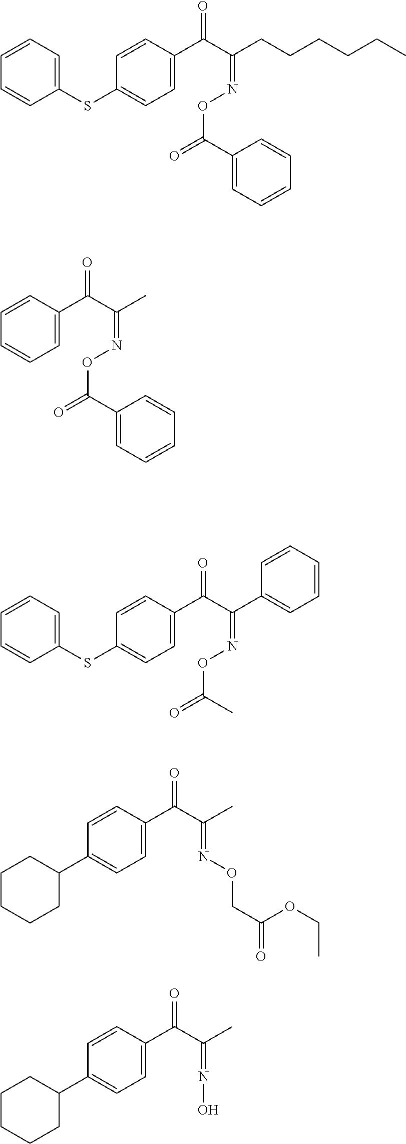 [SMILES: CCCCCC/C(=N/OC(=O)c1ccccc1)C(=O)c1ccc(Sc2ccccc2)cc1 ; C/C(=N/OC(=O)c1ccccc1)C(=O)c1ccccc1 ; CC(=O)O/N=C(\C(=O)c1ccc(Sc2ccccc2)cc1)c1ccccc1 ; CCOC(=O)CO/N=C(\C)C(=O)c1ccc(C2CCCCC2)cc1 ; CC(=NO)C(=O)c1ccc(C2CCCCC2)cc1]

In the present invention, it is preferable that the oxime compound is a compound not including an S atom.

In the present invention, an oxime compound having a fluorine atom can also be used as the oxime compound. Specific examples of the oxime compound having a fluorine atom include a compound described in JP2010-262028A, Compounds 24 and 36 to 40 described in paragraph “0345” of JP2014-500852A, and Compound (C-3) described in paragraph “0101” of JP2013-164471A. In addition, an oxime polymer described in JP2010-527339A or WO2015/004565 can also be used.

In the present invention, an oxime compound having a nitro group can also be used as the oxime compound. Specific examples of the oxime compound having a nitro group include compounds described in paragraphs “0031” to “0047” of JP2013-114249A and paragraphs “0008” to “0012” and “0070” to “0079” of JP2014-137466A, and ADEKA ARKLS NCI-831 (manufactured by Adeka Corporation).

In the present invention, it is also preferable that an oxime compound having an alkoxysilyl group is used as the oxime compound from the viewpoint of improving radical trapping performance. Specific examples of the oxime compound having an alkoxysilyl group will be shown below.

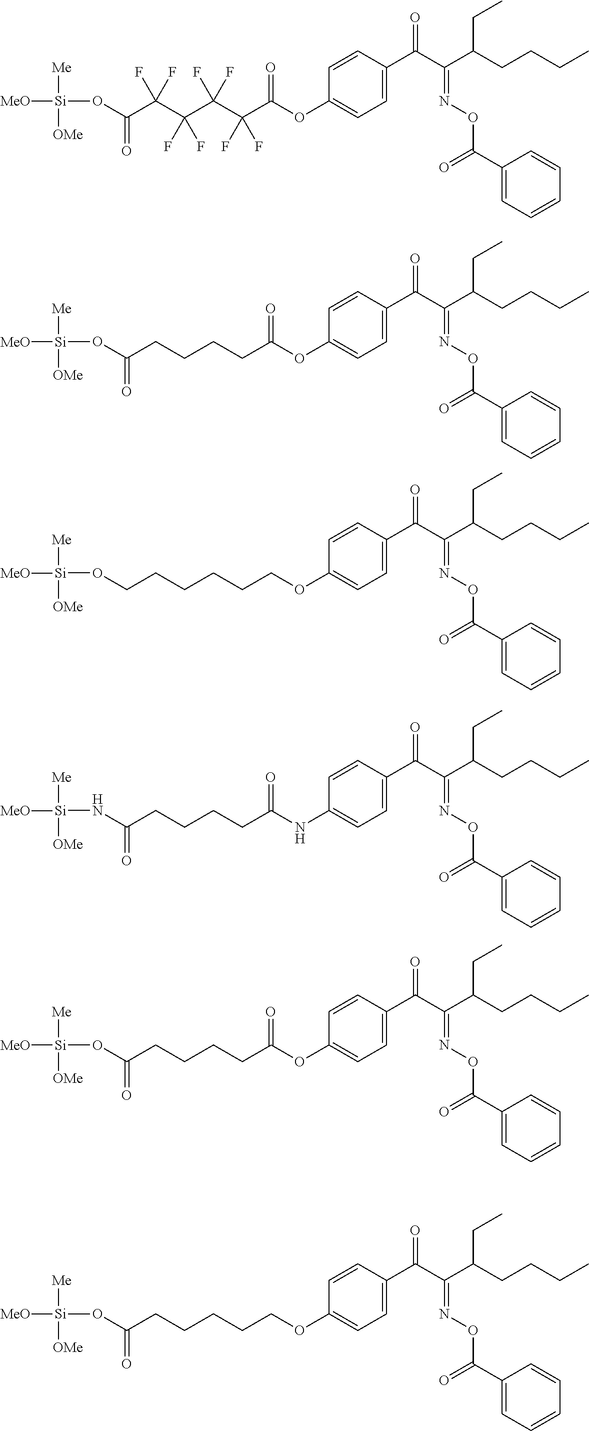

In the present invention, as the oxime compound, an oxime compound having an amide type structure, an ester type structure, an ether type structure, a urea type structure, a sulfonylamide type structure, or an imide type structure can also be used. In particular, it is preferable that the oxime compound having an amide type structure is used from the viewpoint of improving radical trapping performance. Specific examples of the oxime compound having an amide type structure, an ester type structure, an ether type structure, a urea type structure, a sulfonylamide type structure, or an imide type structure will be shown below.

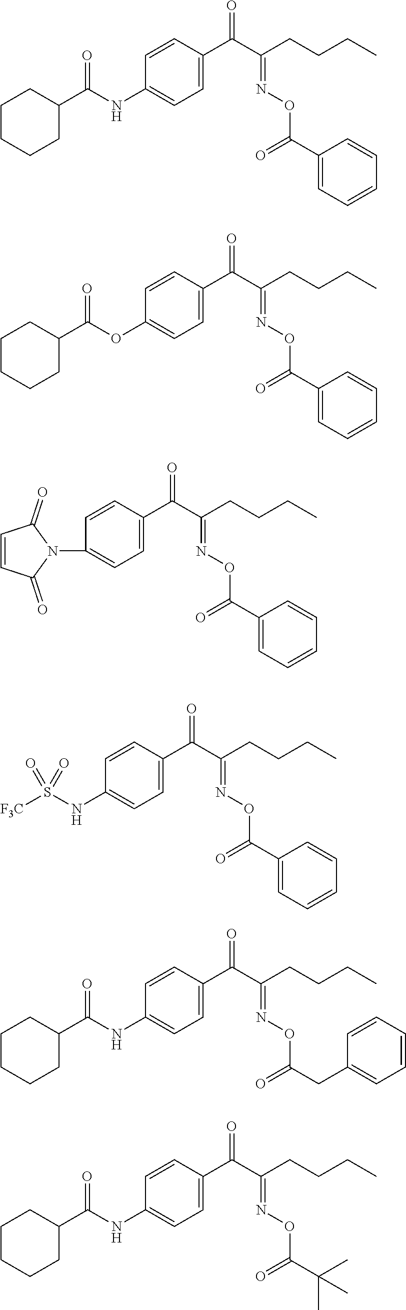 [SMILES: CCCC/C(=N\OC(=O)c1ccccc1)C(=O)c1ccc(NC(=O)C2CCCCC2)cc1 ; CCCC/C(=N\OC(=O)c1ccccc1)C(=O)c1ccc(OC(=O)C2CCCCC2)cc1 ; CCCC/C(=N\OC(=O)c1ccccc1)C(=O)c1ccc(N2C(=O)C=CC2=O)cc1 ; CCCC/C(=N\OC(=O)c1ccccc1)C(=O)c1ccc(NS(=O)(=O)C(F)(F)F)cc1 ; CCCC/C(=N\OC(=O)Cc1ccccc1)C(=O)c1ccc(NC(=O)C2CCCCC2)cc1 ; CCCC/C(=N\OC(=O)C(C)(C)C)C(=O)c1ccc(NC(=O)C2CCCCC2)cc1]

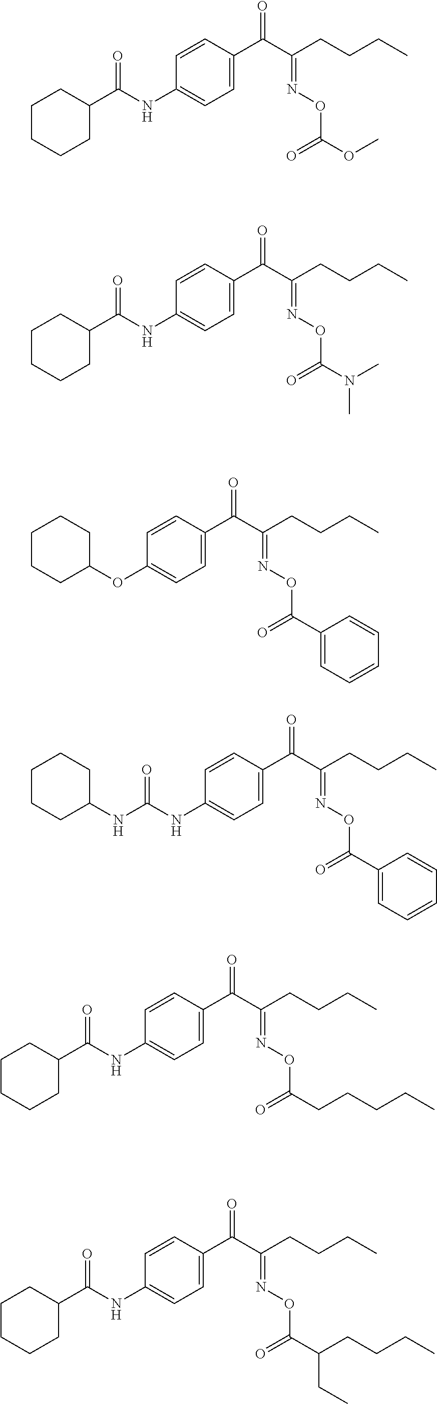 [SMILES: CCCC/C(=N\OC(=O)OC)C(=O)c1ccc(NC(=O)C2CCCCC2)cc1 ; CCCC/C(=N\OC(=O)N(C)C)C(=O)c1ccc(NC(=O)C2CCCCC2)cc1 ; CCCC/C(=N\OC(=O)c1ccccc1)C(=O)c1ccc(OC2CCCCC2)cc1 ; CCCC/C(=N\OC(=O)c1ccccc1)C(=O)c1ccc(NC(=O)NC2CCCCC2)cc1 ; CCCCCC(=O)O/N=C(\CCCC)C(=O)c1ccc(NC(=O)C2CCCCC2)cc1 ; CCCC/C(=N\OC(=O)C(CC)CCCC)C(=O)c1ccc(NC(=O)C2CCCCC2)cc1]

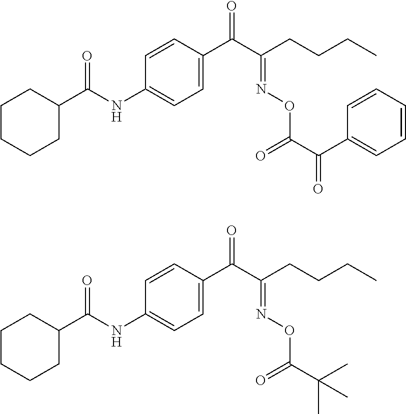 [SMILES: CCCC/C(=N\OC(=O)C(=O)c1ccccc1)C(=O)c1ccc(NC(=O)C2CCCCC2)cc1 ; CCCC/C(=N\OC(=O)C(C)(C)C)C(=O)c1ccc(NC(=O)C2CCCCC2)cc1]

In the present invention, as the oxime compound, an oxime compound having two or more partial structures represented by the following Formula (OX) in one molecule is also preferable. This oxime compound is preferable from the viewpoint of improving radical trapping performance.

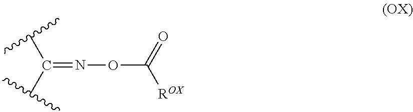

In Formula (OX), R^{OX} represents an alkyl group, an aryl group, or a heterocyclic group, and a wave line represents a linking site to an atomic group constituting the oxime compound.

The alkyl group, the aryl group, and the heterocyclic group represented by R^{OX} are the same as the groups described regarding R¹⁰⁰ and R¹⁰¹ in Formula (I), and preferable ranges thereof are also the same.

Examples of the oxime compound having two or more partial structures represented by the following Formula (OX) in one molecule include a compound represented by the following Formula (I-1).

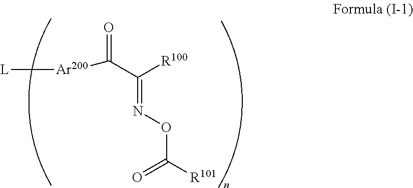

n represents an integer of 2 or more, preferably 2 to 10, more preferably 2 to 5, and still more preferably 2 or 3.

L represents an n-valent group. It is preferable that the n-valent group is a group composed of 1 to 100 carbon atoms, 0 to 10 nitrogen atoms, 0 to 50 oxygen atoms, 1 to 200 hydrogen atoms, and 0 to 20 sulfur atoms. Specific examples of the n-valent group include a group (in which a ring structure may be formed) including one of the following structural unit or a combination of two or more of the structural units.

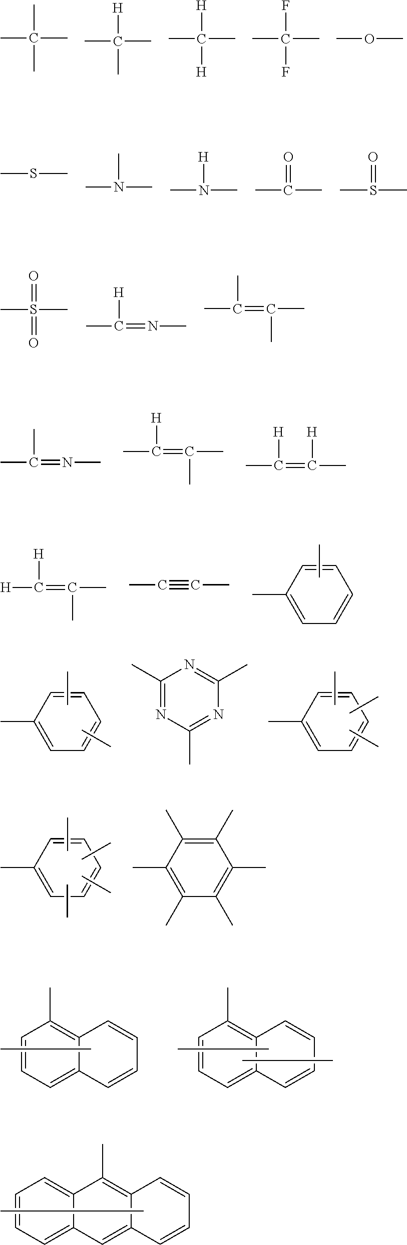

It is preferable that L represents —CH₂—, a group including a combination of two or more kinds of —CH₂—, or a group including a combination of —CH₂— and at least one selected from the group consisting of —O—, —CO—, and —COO—.

Ar²⁰⁰ represents an aryl group or a heterocyclic group, and R²⁰⁰ and R²⁰¹ each independently represent an alkyl group, an aryl group, or a heterocyclic group. The groups represented by Ar²⁰⁰, R²⁰⁰, and R²⁰¹ are the same as the groups described above regarding Ar¹⁰⁰, R¹⁰⁰, and R¹⁰¹ in Formula (I).

Specific examples of the compound represented by Formula (I-1) include the following compounds.

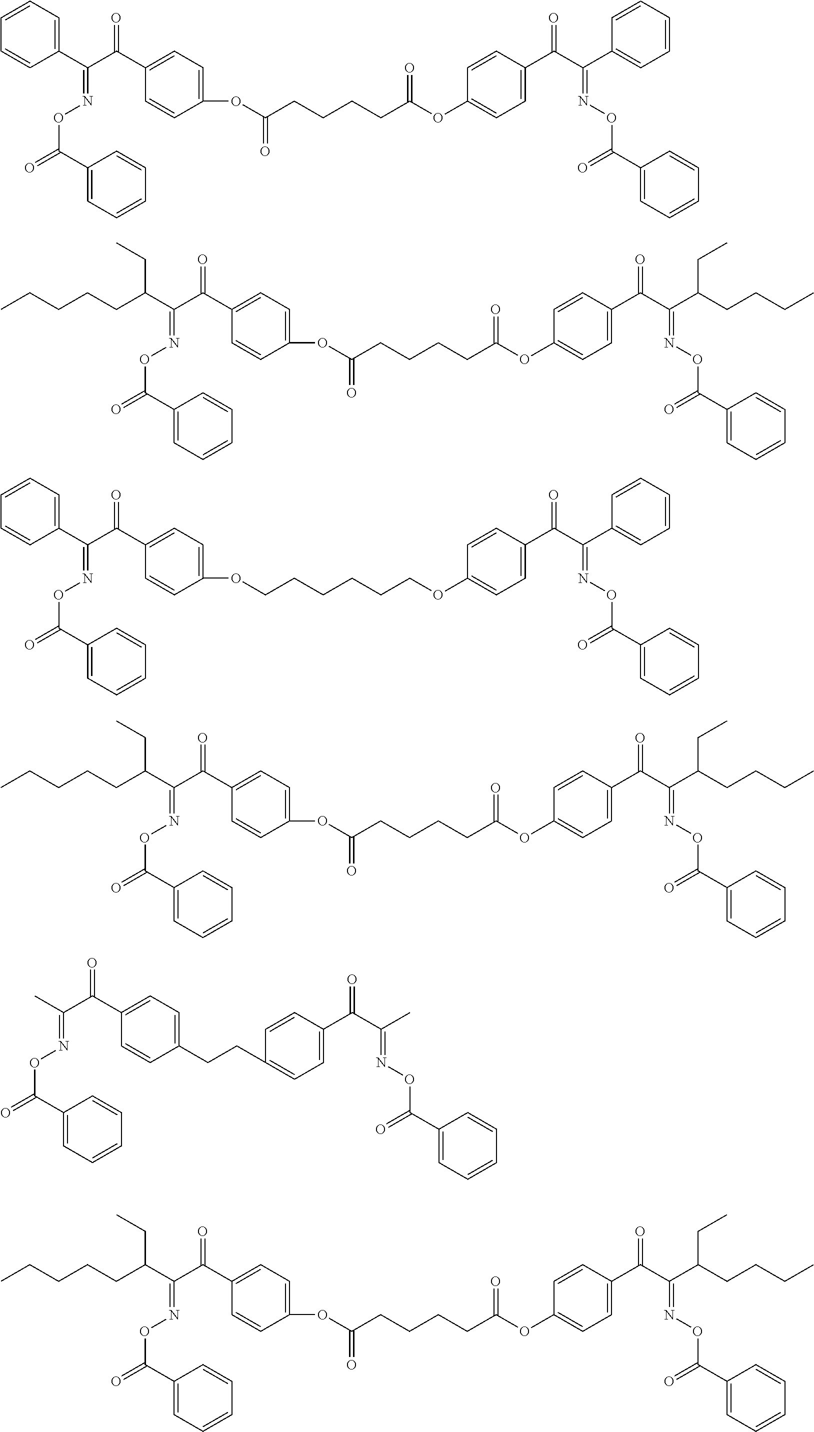

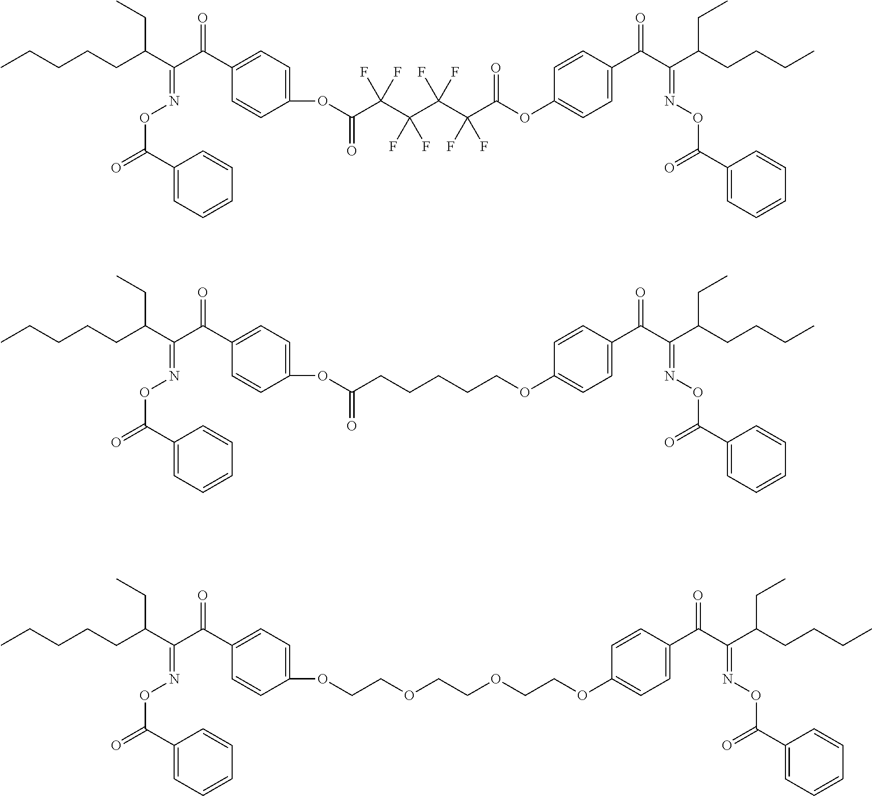

Examples of the hindered amine compound include TINUVIN 123, TINUVIN 144, and TINUVIN 292 (all of which are manufactured by BASF SE) and ADEKA STAB LA-52 (manufactured by Adeka Corporation).

Examples of the hindered phenol compound include SUMILIZER BHT and BBM-S (manufactured by Sumitomo Chemical Co., Ltd.), IRGANOX 245 and 1010 (manufactured by BASF SE), and ADEKA STAB AO-20, AO-30, AO-40, AO-50, AO-60, and AO-80 (manufactured by Adeka Corporation).

Examples of the sulfur-based peroxide decomposition product include SUMILIZER MB (manufactured by Sumitomo Chemical Co., Ltd.) and ADEKA STAB AO-412S (manufactured by Adeka Corporation).

Examples of the phosphorus-based peroxide decomposing agent include ADEKA STAB 2112, PEP-8, PEP-24G, PEP-36, PEP-45, and HP-10 (manufactured by Adeka Corporation), and IRGAFOS 38, 168 and P-EPQ (manufactured by BASF SE).

The N-oxyl compound is not particularly limited as long as it is a compound having an N-oxyl group, and a well-known compound can be used. Examples of the N-oxyl compound include a piperidine 1-oxyl free-radical compound and a pyrrolidine 1-oxyl free-radical compound. Examples of the piperidine 1-oxyl free-radical compound include a compound selected from the group consisting of piperidine 1-oxyl free radical, 2,2,6,6-tetramethylpiperidine 1-oxyl free radical, 4-oxo-2,2,6,6-tetramethylpiperidine 1-oxyl free radical, 4-hydroxy-2,2,6,6-tetramethylpiperidine 1-oxyl free radical, 4-acetamide-2,2,6,6-tetramethylpiperidine 1-oxyl free radical, 4-maleimide-2,2,6,6-tetramethylpiperidine 1-oxyl free radical, and 4-phosphonoxy-2,2,6,6-tetramethylpiperidine 1-oxyl free radical. Examples of the pyrrolidine 1-oxyl free-radical compound include 3-carboxyproxyl free radical (3-carboxy-2,2,5,5-tetramethylpyrrolidine 1-oxyl free radical).

Examples of the alkylphenone compound include 1-hydroxycyclohexyl phenyl ketone and 1-(4-isopropylphenyl)-2-hydroxy-2-methylpropane-1-one.

Examples of the aldehyde compound include an aliphatic aldehyde compound and an aromatic aldehyde compound. Among these, an aromatic aldehyde compound is preferable.

In addition, it is also preferable that the aldehyde compound is a compound in which at least one hydrogen atom is substituted with a halogen atom (preferably a fluorine atom) or a substituent having a halogen atom (preferably a substituent having a fluorine atom, and more preferably a fluoroalkyl group having 1 to 5 carbon atoms). Specific examples of the aldehyde compound include 2-methylbenzaldehyde, 2-chlorobenzaldehyde, 2-nitrobenzaldehyde, 2-ethoxybenzaldehyde, 2-(trifluoromethyl)benzaldehyde, 3,5-bis(trifluoromethyl)benzaldehyde, 2,4-dichlorobenzaldehyde, 2,4-dihydroxybenzaldehyde, 2,4-disulfobenzaldehyde sodium, o-sulfobenzaldehyde disodium, p-dimethylaminobenzaldehyde, 2,6-dimethylbenzaldehyde, 2,6-dichlorobenzaldehyde, 2-6-dimethoxybenzaldehyde, 2,4,6-trimethylbenzaldehyde (mesitaldehyde), 2,4,6-triethylbenzaldehyde, and 2,4,6-trichlorobenzaldehyde.

In the near infrared absorbing composition according to the present invention, it is preferable that the content of the radical trapping agent is 0.1 to 30 mass % with respect to a total solid content of the near infrared absorbing composition. The lower limit is preferably 0.5 mass % or higher, more preferably 1 mass % or higher, and still more preferably 3 mass % or higher. The upper limit is preferably 20 mass % or lower, more preferably 10 mass % or lower, and still more preferably 9 mass % or lower. As the radical trapping agent, one kind or two or more kinds may be used. In a case where two or more radical trapping agents are used, it is preferable that the total content of the two or more radical trapping agents is in the above-described range.

<<Resin which Generates Radical at 180° C. or Higher>>

The near infrared absorbing composition according to the present invention includes a resin (hereinafter, also referred to as “resin A”) which generates a radical at 180° C. or higher.

In the present invention, the radical generating temperature of the resin is a value measured by electron spin resonance (ESR). Specifically, the radical generating temperature is a value measured using a method described in Examples described below. The resin A is a component different from the copper compound described below. The resin A is a resin not including copper.

The kind of the radical generated from the resin A varies depending on the kind of the resin. Examples of the radical include alkyl radical, aryl radical, alkyloxy radical, aryloxy radical, alkylcarbonyl radical, arylcarbonyl radical, amine radical, hydrogen radical, and hydroxy radical.

The radical generating temperature of the resin A is 180° C. or higher, preferably 190° C. or higher, and more preferably 200° C. or higher. For example, the upper limit is preferably 400° C. or lower and more preferably 300° C. or lower. In a case where the radical generating temperature is 180° C. or higher, the amount of a radical generated from the resin during heating is small. In addition, even in a case where a radical is generated from the resin, the radical can be trapped by the radical trapping agent. Therefore, a film having excellent heat resistance can be easily obtained.

In the present invention, it is preferable that the resin A does not include a radically polymerizable group. Examples of the radically polymerizable group include a vinyl group, a styryl group, a (meth)allyl group, and a (meth)acryloyl group. Among these, a group having an ethylenically unsaturated bond such as a (meth)allyl group or a (meth)acryloyl group is preferable. In a case where the resin A includes a radically polymerizable group, the radical generating temperature tends to decrease. Further, the radical trapping agent may be consumed by reacting with the radically polymerizable group. Therefore, in order to obtain the desired effect, it is necessary to increase the amount of the radical trapping agent added.

In the present invention, examples of the resin A include an acrylate resin, an acrylamide resin, an acrylimide resin, a maleimide resin, an acrylonitrile resin, a polyvinyl acetal resin, a poly-N-vinylacetamide resin, a polyvinyl pyrrolidone resin, a cyclic polyolefin resin, an aromatic polyether resin, a polyimide resin, a fluorene polycarbonate resin, a fluorene polyester resin, a polycarbonate resin, a polyamide resin, a polyarylate resin, a polysulfone resin, a polyethersulfone resin, a polyparaphenylene resin, a polyamide imide resin, a polyethylene naphthalate resin, a fluorinated aromatic polymer resin, an epoxy resin, an allyl ester resin, and a silsesquioxane resin. The details of the resin can be found in paragraphs “0056” to “0060” of JP2014-218597A and paragraphs “0074” to “0156” of JP2013-218312A, the contents of which is incorporated herein by reference. Among these, as the resin A, an acrylate resin, an acrylamide resin, an acrylimide resin, a maleimide resin, an acrylonitrile resin, a polyvinyl acetal resin, a poly-N-vinylacetamide resin, or a polyvinyl pyrrolidone resin is preferable.

In the present invention, it is also preferable that the resin A includes a partial structure represented by the following (a) or (b) at a main chain or a side chain of a repeating unit.

In (a) or (b), a wave line represents a linking site to an atomic group constituting the repeating unit of the resin. Examples of the resin having a partial structure include an acrylate resin, an acrylamide resin, an acrylimide resin, and a maleimide resin.

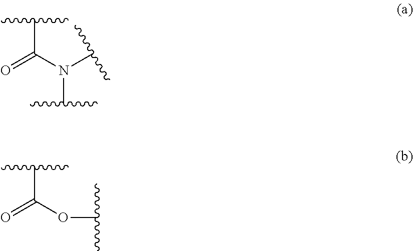

In the present invention, as the resin A, a resin having at least one selected from the group consisting of a repeating unit represented by the following Formula (A) and a repeating unit represented by the following Formula (B) is preferable, and a resin having a repeating unit represented by the following Formula (A) is more preferable.

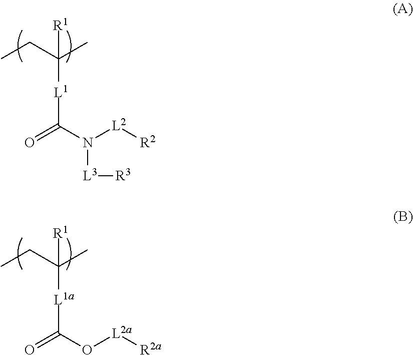

In Formula (A), R¹ represents a hydrogen atom or an alkyl group, L¹ to L³ each independently represent a single bond or a divalent linking group, R² and R³ each independently represent an aliphatic hydrocarbon group or an aromatic group. R² may be bonded to a carbon atom of a main chain of the repeating unit or R³ to form a ring. L² may be bonded to a carbon atom of a main chain of the repeating unit to form a ring. In a case where L² is bonded to a carbon atom of a main chain of the repeating unit to form a ring, R² is not present.

In Formula (B), R¹ represents a hydrogen atom or an alkyl group, L^{1a} and L^{2a} each independently represent a single bond or a divalent linking group, and R^{2a} represents an aliphatic hydrocarbon group, an aromatic group, a lactone ring group, or a carbonate group.

In Formula (A), R¹ represents a hydrogen atom or an alkyl group. The number of carbon atoms in the alkyl group is preferably 1 to 5, more preferably 1 to 3, and still more preferably 1. The alkyl group is preferably linear or branched and more preferably linear. As R¹, a hydrogen atom or a methyl group is preferable.

In Formula (A), L¹ to L³ each independently represent a single bond or a divalent linking group. Examples of the divalent linking group include an alkylene group, an arylene group, —O—, —S—, —SO—, —CO—, —COO—, —OCO—, —SO₂—, —NR¹⁰— (R¹⁰ represents a hydrogen atom or an alkyl group), and a group including a combination thereof. The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic. As the arylene group, an arylene group having 6 to 18 carbon atoms is preferable, an arylene group having 6 to 14 carbon atoms is more preferable, an arylene group having 6 to 10 carbon atoms is still more preferable, and a phenylene group is even still more preferable.

It is preferable that L¹ represents a single bond. It is preferable L² and L³ each independently represent a single bond, —O—, —S—, —SO—, —CO—, —COO—, —OCO—, —SO₂—, —NR^{10A}—(R^{10A} represents an alkyl group), or a group including a combination of the above-described groups, and it is more preferable L² and L³ each independently represent a single bond, —CO—, or —SO₂—.

R² and R³ each independently represent an aliphatic hydrocarbon group or an aromatic group. The aliphatic hydrocarbon group and the aromatic group may be unsubstituted or may have a substituent. Examples of the substituent include an alkyl group, an aryl group, a heteroaryl group, an amino group (for example, an alkylamino group, an arylamino group, or a heterocyclic amino group), an alkoxy group, an aryloxy group, a heteroaryloxy group, an acyl group, an alkylcarbonyl group, an arylcarbonyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a heteroarylthio group, an alkylsulfonyl group, an arylsulfonyl group, a sulfinyl group, an ureido group, a phosphoric amide group, a hydroxyl group, a mercapto group, a halogen atom, a cyano group, a sulfo group, a carboxyl group, a nitro group, a hydroxamic acid group, a sulfino group, a hydrazino group, an imino group, a silyl group, a lactone ring group, and a carbonate group.

Examples of the aliphatic hydrocarbon group include an alkyl group and an alkenyl group. The alkyl group may be linear, branched, or cyclic. The number of carbon atoms in the alkyl group is preferably 1 to 30, more preferably 1 to 20, and still more preferably 1 to 10. The alkenyl group may be linear, branched, or cyclic. The number of carbon atoms in the alkenyl group is preferably 2 to 30, more preferably 2 to 20, and still more preferably 2 to 10.

Examples of the aromatic group include an aryl group and a heteroaryl group. The number of carbon atoms in the aryl group is preferably 6 to 30, more preferably 6 to 20, and still more preferably 6 to 12. The number of carbon atoms constituting the heteroaryl group is preferably 1 to 30 and more preferably 1 to 12. Examples of the kind of the heteroatom constituting the heteroaryl group include a nitrogen atom, an oxygen atom, and a sulfur atom. The number of heteroatoms constituting the heteroaryl group is preferably 1 to 3 and more preferably 1 or 2. The heteroaryl group is preferably a monocycle or a fused ring, more preferably a monocycle or a fused ring composed of 2 to 8 rings, and still more preferably a monocycle or a fused ring composed of 2 to 4 rings. It is preferable that R² represents an alkyl group. It is preferable that R³ represents an alkyl group or an aryl group.

In Formula (A), R² may be bonded to a carbon atom of a main chain of the repeating unit or R³ to form a ring. In addition, L² may be bonded to a carbon atom of a main chain of the repeating unit to form a ring. Examples of the formed ring include an alicyclic ring (a nonaromatic hydrocarbon ring), an aromatic ring, and a heterocycle. The ring may be a monocycle or a polycycle.

In a case where L² is bonded to a carbon atom of a main chain of the repeating unit to form a ring, R² is not present. In a case where L² is bonded to a carbon atom of a main chain of the repeating unit to form a ring, it is preferable that L² represents —CO—. In addition, in a case where L² is bonded to a carbon atom of a main chain of the repeating unit to form a ring, it is preferable that Formula (A) represents a repeating unit represented by (A1-2) shown below.

A resin including a repeating unit in which L² and L³ represent a single bond and R² and R³ each independently represent an alkyl group in Formula (A) has particularly high compatibility with the copper compound and can be preferably used. In addition, the resin having the above-described repeating unit tends to generate a radical by heating during or after manufacturing. According to the present invention, the resin which is likely to generate a radical is mixed with the radical trapping agent. As a result, discoloration of the copper compound can be suppressed, and a film having excellent heat resistance can be manufactured.

In Formula (B), R¹ represents a hydrogen atom or an alkyl group, L^{1a} and L^{2a} each independently represent a single bond or a divalent linking group, and R^{2a} represents an aliphatic hydrocarbon group, an aromatic group, a lactone ring group, or a carbonate group.

Examples of the group represented by R¹ in Formula (B) include the group described above regarding R¹ in Formula (A). It is preferable that R¹ represents a hydrogen atom or a methyl group.

Examples of the divalent linking group represented by La in Formula (B) include the divalent linking group described above regarding L¹ in Formula (A). It is preferable that L^{1a} represents a single bond.

Examples of the divalent linking group represented by L^{2a} in Formula (B) include the divalent linking group described above regarding L² and L³ in Formula (A). Examples of the group represented by L^{2a} include a single bond, an alkylene group, an arylene group, —O—, —S—, —SO—, —CO—, —COO—, —OCO—, —SO₂—, —NR¹⁰— (R¹⁰ represents a hydrogen atom or an alkyl group), and a group including a combination thereof.

Examples of the aliphatic hydrocarbon group and the aromatic group represented by R^{2a} in Formula (B) include the aliphatic hydrocarbon group and the aromatic group described above regarding R² and R³ in Formula (A). Examples of the lactone ring group represented by R^{2a} include an acetolactone ring group, a propiolactone ring group, and a butyrolactone ring group.

In the present invention, it is preferable that the resin A includes a repeating unit represented by the following Formula (A1-1).

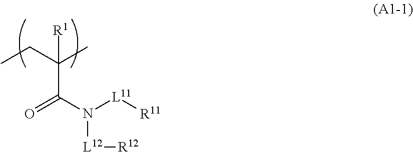

in Formula (A1-1), R¹ represents a hydrogen atom or an alkyl group, R¹¹ and R¹² each independently represent an aliphatic hydrocarbon group or an aromatic group, L¹¹ represents a single bond, —CO—, or —SO₂—, and L¹² represents a single bond or a divalent linking group. R¹ may be bonded to a carbon atom of a main chain of the repeating unit or R¹² to form a ring. L¹¹ may be bonded to a carbon atom of a main chain of the repeating unit to form a ring. In a case where L¹¹ is bonded to a carbon atom of a main chain of the repeating unit to form a ring, R¹¹ is not present.

R¹, R¹¹, R¹², and L¹² in Formula (A1-1) have the same definitions as R¹, R², R³, and L³ in Formula (A).

L¹¹ represents a single bond, —CO—, or —SO₂—. L¹¹ may be bonded to a carbon atom of a main chain of the repeating unit to form a ring. In a case where L¹¹ is bonded to a carbon atom of a main chain of the repeating unit to form a ring, it is preferable that L¹¹ represents —CO—. In a case where L¹¹ is bonded to a carbon atom of a main chain of the repeating unit to form a ring, R¹¹ is not present.

It is preferable that the resin A includes at least one repeating unit selected from the group consisting of repeating units represented by the following Formulae (A1-2) to (A1-4).

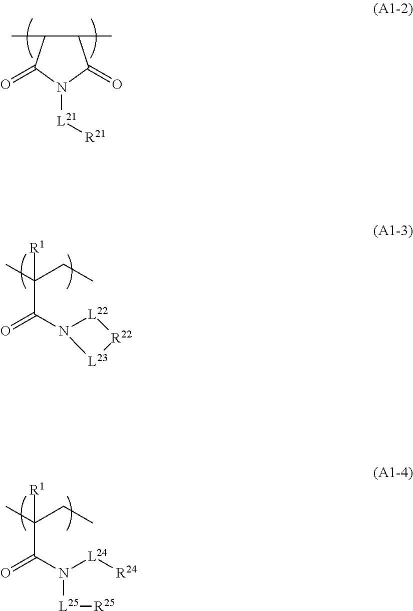

In Formula (A1-2), L²¹ represents a single bond or a divalent linking group, and R²¹ represents an aliphatic hydrocarbon group or an aromatic group. L²¹ and R²¹ in Formula (A1-2) have the same definitions and the same preferable ranges as L³ and R³ in Formula (A). In Formula (A1-2), L²¹ represents preferably a single bond. R²¹ represents preferably an alkyl group or an aryl group and more preferably an aryl group.

In Formula (A1-3), R¹ represents a hydrogen atom or an alkyl group, L²² represents a single bond or —CO—, L²³ represents a single bond or a divalent linking group, and R²² represents an aliphatic hydrocarbon group. R¹ and L²³ in Formula (A1-3) have the same definitions and the same preferable ranges as R¹ and L³ in Formula (A). It is preferable that R¹ represents a hydrogen atom or a methyl group. It is preferable that L²² represents —CO—. L²³ represents preferably a single bond, —CO—, or —SO₂—, and more preferably a single bond. The hydrocarbon group represented by R²² represents preferably an alkylene group. The number of carbon atoms in the alkylene group is preferably 1 to 30, more preferably 1 to 20, and still more preferably 1 to 10. The alkylene group is preferably linear or branched.

In Formula (A1-4), R¹ represents a hydrogen atom or an alkyl group, L²⁴ represents a single bond, —CO—, or —SO₂—, L²⁵ represents a single bond or a divalent linking group, and R²⁴ and R²⁵ each independently represent an aliphatic hydrocarbon group or an aromatic group. R¹, L²⁵, R²⁴, and R²⁵ in Formula (A1-4) have the same definitions and the same preferable ranges as R¹, L³, R², and R³ in Formula (A). It is preferable that R¹ represents a hydrogen atom or a methyl group. It is preferable that L²⁴ represents a single bond. L²⁵ represents preferably a single bond, —CO—, or —SO₂—, and more preferably a single bond. It is preferable that R²⁴ and R²⁵ each independently represent an alkyl group or an aryl group.

The content of the repeating unit represented by Formula (A) in the resin A is preferably 25 to 95 mol % and more preferably 30 to 70 mol % with respect to all the repeating units of the resin A. According to this aspect, a film having high heat resistance and solvent resistance can be easily obtained. Specific examples of the repeating unit represented by Formula (A) include the following structures.

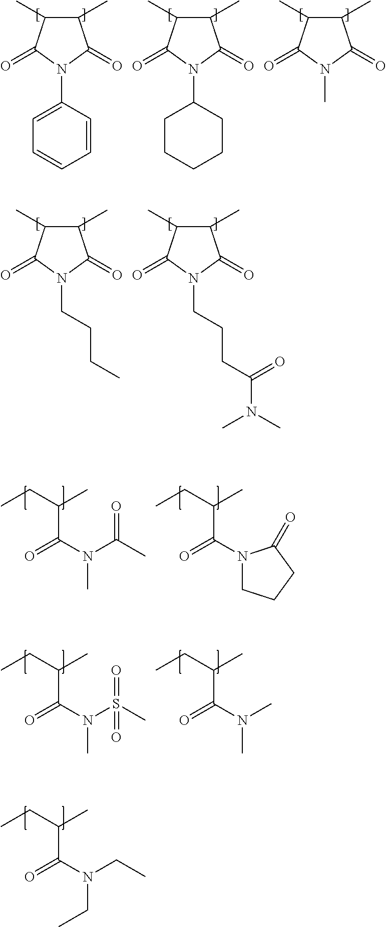

In the present invention, it is preferable that the resin A further includes a repeating unit having a crosslinking group. According to this aspect, a film having higher heat resistance and solvent resistance can be easily manufactured. Examples of the crosslinking group include a group having an ethylenically unsaturated bond, a cyclic ether group, a methylol group, and an alkoxysilyl group. Among these, a cyclic ether group, a methylol group, or an alkoxysilyl group is preferable, a cyclic ether group or an alkoxysilyl group is more preferable, and an alkoxysilyl group is still more preferable. Examples of the group having an ethylenically unsaturated bond include a vinyl group, a styryl group, a (meth)allyl group, and a (meth)acryloyl group. Among these, a (meth)allyl group or a (meth)acryloyl group is preferable. Examples of the cyclic ether group include an epoxy group and an oxetanyl group. Among these, an epoxy group is preferable. Examples of the alkoxysilyl group include a monoalkoxysilyl group, a dialkoxysilyl group, and a trialkoxysilyl group. Among these, a dialkoxysilyl group or a trialkoxysilyl group is preferable, and a trialkoxysilyl group is more preferable.

Examples of the repeating unit having a crosslinking group include the following (A2-1) to (A2-4).

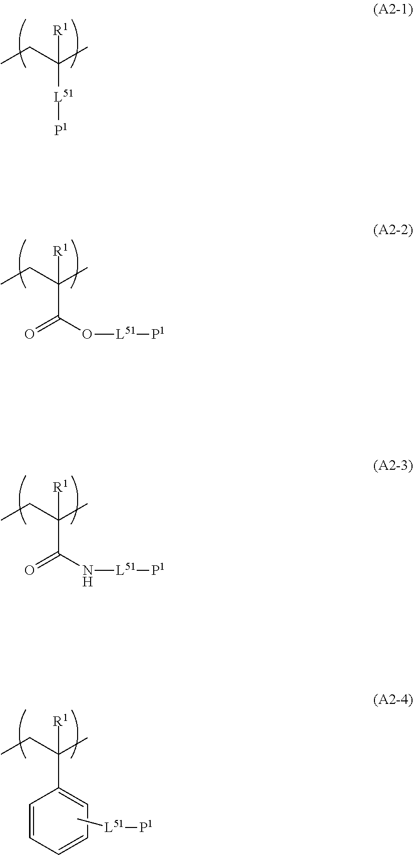

R¹ represents a hydrogen atom or an alkyl group. The number of carbon atoms in the alkyl group is preferably 1 to 5, more preferably 1 to 3, and still more preferably 1. It is preferable that R¹ represents a hydrogen atom or a methyl group.

L⁵¹ represents a single bond or a divalent linking group. Examples of the divalent linking group include the divalent linking groups represented by L¹ to L³ in Formula (A). It is preferable that L⁵¹ represents an alkylene group.

P¹ represents a crosslinking group. Examples of the crosslinking group include a group having an ethylenically unsaturated bond, a cyclic ether group, a methylol group, and an alkoxysilyl group. Examples of the group having an ethylenically unsaturated bond include a vinyl group, a styryl group, a (meth)allyl group, and a (meth)acryloyl group. Among these, a (meth)allyl group or a (meth)acryloyl group is preferable. Examples of the cyclic ether group include an epoxy group and an oxetanyl group. Among these, an epoxy group is preferable. Examples of the alkoxysilyl group include a monoalkoxysilyl group, a dialkoxysilyl group, and a trialkoxysilyl group. Among these, a dialkoxysilyl group or a trialkoxysilyl group is preferable, and a trialkoxysilyl group is more preferable. The number of carbon atoms in the alkoxy group of the alkoxysilyl group is preferably 1 to 5, more preferably 1 to 3, and still more preferably 1 or 2. It is preferable that the crosslinking group is an alkoxysilyl group.

In a case where the resin A includes a repeating unit having a crosslinking group, the content of the repeating unit having a crosslinking group is preferably 5 to 75 mol % and more preferably 30 to 70 mol % with respect to all the repeating units of the resin A. According to this aspect, a film having high heat resistance can be easily obtained. Specific examples of the repeating unit having a crosslinking group include the following structures. In the following formulae, Me represents a methyl group, and Et represents an ethyl group.

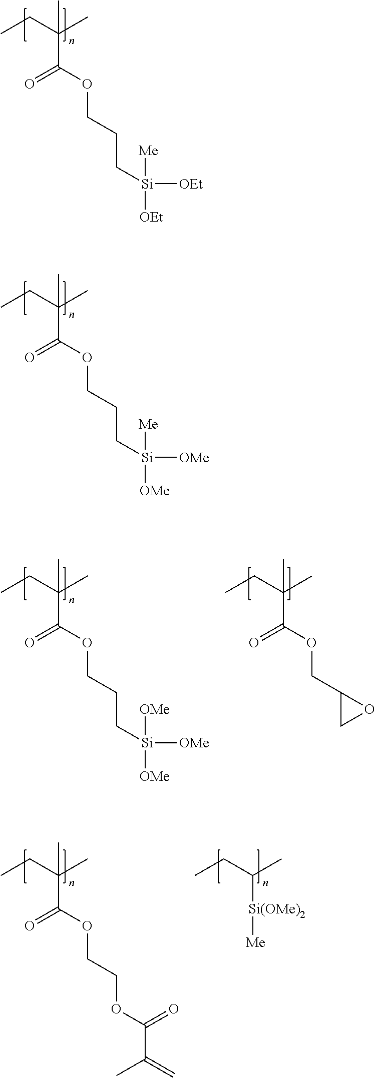

The resin A may include other repeating units in addition to the repeating unit represented by Formula (A) and the repeating unit having a crosslinking group. The details of components constituting the other repeating units can be found in the description of copolymerization components in paragraphs “0068” to “0075” of JP2010-106268A (corresponding to paragraphs “0112” to “0118” of US2011/0124824A), the content of which is incorporated herein by reference.

Preferable examples of the other repeating units include a repeating unit represented by the following Formula (A3-1).

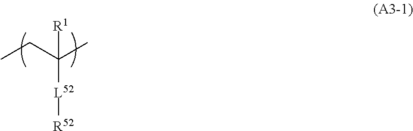

R¹ represents a hydrogen atom or an alkyl group. The number of carbon atoms in the alkyl group is preferably 1 to 5, more preferably 1 to 3, and still more preferably 1. It is preferable that R¹ represents a hydrogen atom or a methyl group.

L⁵² represents a single bond or a divalent linking group. Examples of the divalent linking group include the divalent linking groups represented by L¹ to L³ in Formula (A). It is preferable that L⁵² represents an alkylene group.

R⁵² represents an alkyl group or an aryl group. The alkyl group may be linear, branched, or cyclic. The number of carbon atoms in the alkyl group is preferably 1 to 30, more preferably 1 to 20, and still more preferably 1 to 10. The aryl group may be monocyclic or polycyclic and is preferably monocyclic. The number of carbon atoms in the aryl group is preferably 6 to 18 and more preferably 6 to 10.

In a case where the resin A includes the other repeating units (preferably the repeating unit represented by Formula (A3-1), the content of the other repeating units (preferably the repeating unit represented by Formula (A3-1)) is preferably 0 to 20 mol % and more preferably 0 to 10 mol % with respect to all the repeating units of the resin A.

In addition, the resin A may not substantially include the other repeating units. The resin A substantially not including the other repeating units represents that the content of the other repeating units is preferably 1 mol % or lower, more preferably 0.1 mol % or lower, and still more preferably 0% with respect to all the repeating units of the resin A.

In the present invention, preferable aspects of the resin A are as follows. Among these, the following aspects (4) to (7) are preferable, the following aspects (5) to (7) are more preferable, the following aspect (6) or (7) is still more preferable, and the following aspect (7) is even still more preferable. According to the aspects, the effects of the present invention can be more easily obtained. That is, heat resistance can be further improved by the addition of the radical trapping agent.

(1) an aspect where the resin A includes the repeating unit represented by Formula (A)

(2) an aspect where the resin A includes the repeating unit represented by Formula (A1-1)

(3) an aspect where the resin A includes at least one repeating unit selected from the group consisting of repeating units represented by the following Formulae (A1-2) to (A1-4)

(4) an aspect where the resin A includes the repeating unit having a crosslinking group

(5) an aspect where the resin A includes the repeating unit represented by Formula (A) and the repeating unit having a crosslinking group

(6) an aspect where the resin A includes the repeating unit represented by Formula (A1-1) and the repeating unit having a crosslinking group

(7) an aspect where the resin A includes at least one repeating unit selected from the group consisting of repeating units represented by the following Formulae (A1-2) to (A1-4) and the repeating unit having a crosslinking group

(8) an aspect where the resin A does not include a radically polymerizable group

(9) an aspect where the resin A does not include a radically polymerizable group in any one of the aspects (1) to (7)

In the present invention, the weight-average molecular weight of the resin A is preferably 500 to 300000. The lower limit is more preferably 3000 or higher and still more preferably 5000 or higher. The upper limit is more preferably 50000 or lower and still more preferably 30000 or lower. The number-average molecular weight of the resin A is preferably 300 to 200000. The lower limit is more preferably 1000 or higher and still more preferably 2500 or higher. The upper limit is more preferably 25000 or lower and still more preferably 15000 or lower.

In the near infrared absorbing composition according to the present invention, the content of the resin A is preferably 30 to 80 mass % with respect to the total solid content of the near infrared absorbing composition. The lower limit is preferably 40 mass % or higher, more preferably 45 mass % or higher, and still more preferably 50 mass % or higher. The upper limit is preferably 70 mass % or lower, and more preferably 60 mass % or lower. As the resin A, one kind may be used alone, or two or more kinds may be used. In a case where two or more resins A are used in combination, it is preferable that the total content of the two or more resins A is in the above-described range.

<<Copper Compound>>

The near infrared absorbing composition according to the present invention includes a copper compound. In the near infrared absorbing composition according to the present invention, it is preferable that the content of the copper compound is 25 to 75 mass % with respect to the total solid content of the near infrared absorbing composition. The upper limit is preferably 70 mass % or lower, and more preferably 65 mass % or lower. The lower limit is preferably 30 mass % or higher and more preferably 35 mass % or higher. In a case where the content of the copper compound is in the above-described range, a film having excellent infrared shielding properties can be easily formed.

In the present invention, it is preferable that the copper compound is a copper complex. It is preferable that the copper complex is a complex of copper and a compound (ligand) having a coordination site coordinated to copper. Examples of the coordination site coordinated to copper include a coordination site coordinated by an anion and a coordinating atom coordinated by an unshared electron pair. The copper complex may include two or more ligands. In a case where the copper complex includes two or more ligands, the ligands may be the same as or different from each other. The copper complex may be tetradentate-coordinated, pentadentate-coordinated, or hexadentate-coordinated, more preferably tetradentate-coordinated or pentadentate-coordinated, and still more preferably pentadentate-coordinated. In addition, in the copper complex, it is preferable that copper and the ligand form a 5-membered ring and/or a 6-membered ring. This copper complex is stable in shape and has excellent complex stability.

In the present invention, it is also preferable that the copper complex is a copper complex other than a phthalocyanine copper complex. Here, the phthalocyanine copper complex is a copper complex in which a compound having a phthalocyanine skeleton is used as a ligand. In the compound having a phthalocyanine skeleton, the π-electron conjugated system is spread across the molecules thereof such that a planar structure is formed. The phthalocyanine copper complex absorbs light by π-π* transition. In order to absorb light in an infrared range by π-π* transition, it is necessary that a compound which forms a ligand has a long conjugated structure. However, in a case where the conjugated structure of the ligand is long, visible light transmittance tend to deteriorate. Therefore, the phthalocyanine copper complex may have insufficient visible light transmittance.

In addition, it is also preferable that the copper complex is a copper complex in which a compound having an absorption maximum in a wavelength range of 400 to 600 nm is used as a ligand. The copper complex in which a compound having an absorption maximum in a wavelength range of 400 to 600 nm is used as a ligand has absorption in a visible range (for example, a wavelength range of 400 to 600 nm). Therefore, visible light transmittance may be insufficient. Examples of the compound having an absorption maximum in a wavelength range of 400 to 600 nm include a compound which has a long conjugated structure and absorbs a large amount of light by π-π* transition. Specifically, a compound having a phthalocyanine skeleton can be used.

It is preferable that the copper complex includes a compound having a carbon atom bonded to a hydrogen atom as a ligand. According to this aspect, a film having high moisture fastness can be easily obtained.

In addition, it is also preferable that the copper complex includes a compound having a coordinating atom coordinated by an unshared electron pair as a ligand.

In addition, it is also preferable that the copper complex is a compound (hereinafter, also referred to as “multidentate ligand”) having at least two coordination sites as a ligand.

The number of coordination sites in the multidentate ligand is more preferably at least 3, and still more preferably 3 to 5. The multidentate ligand acts as a chelating ligand to a copper component. That is, it is presumed that, by at least two coordinating atoms in the multidentate ligand being chelating-coordinated to copper, the structure of the copper complex is distorted, high transmittance in a visible range can be obtained, infrared absorption capability can be improved, and a color value can also be improved. Thus, even in a case where a near infrared cut filter is used for a long period of time, characteristics thereof do not deteriorate, and a camera module can be stably manufactured.

The copper complex can be obtained by mixing, reaction, or the like of a compound (ligand) having a coordination site coordinated to copper with a copper component (copper or a compound including copper). The compound (ligand) having a coordination site coordinated to copper may be a low molecular weight compound or a polymer. Both a low molecular weight compound and a polymer may also be used in combination.

It is preferable that the copper component is a compound including divalent copper. As the copper component, one kind may be used alone, or two or more kinds may be used in combination. As the copper component, for example, copper oxide or a copper salt can be used. As the copper salt, for example, copper carboxylate (for example, copper acetate, copper ethylacetoacetate, copper formate, copper benzoate, copper stearate, copper naphthenate, copper citrate, or copper 2-ethylhexanoate), copper sulfonate (for example, copper methasulfonate), copper phosphate, copper phosphoric acid ester, copper phosphonate, copper phosphonic acid ester, copper phosphinate, copper amide, copper sulfone amide, copper imide, copper acyl sulfone imide, copper bissulfone imide, copper methide, alkoxy copper, phenoxy copper, copper hydroxide, copper carbonate, copper sulfate, copper nitrate, copper perchlorate, copper fluoride, copper chloride, copper bromide is preferable, copper carboxylate, copper sulfonate, copper sulfone amide, copper imide, copper acyl sulfone imide, copper bissulfone imide, alkoxy copper, phenoxy copper, copper hydroxide, copper carbonate, copper fluoride, copper chloride, copper sulfate, copper nitrate, is more preferable, copper carboxylate, copper acyl sulfone imide, phenoxy copper, copper chloride, copper sulfate, copper nitrate is still more preferable, and copper carboxylate, copper acyl sulfone imide, copper chloride, copper sulfate is even still more preferable.

In the present invention, it is preferable that the copper complex is a compound having an absorption maximum in a wavelength range of 700 to 1200 nm. It is more preferable the absorption maximum of the copper complex is present in a wavelength range of 720 to 1200 nm, and it is still more preferable the absorption maximum of the copper complex is present in a wavelength range of 800 to 1100 nm. The absorption maximum can be measured, for example, using Cary 5000 UV-Vis-NIR (spectrophotometer, manufactured by Agilent Technologies Inc.).

The molar absorption coefficient of the copper complex at the absorption maximum in the wavelength range is preferably 120 (L/mol·cm) or higher, more preferably 150 (L/mol·cm) or higher, still more preferably 200 (L/mol·cm) or higher, even still more preferably 300 (L/mol·cm) or higher, and even yet still more preferably 400 (L/mol·cm) or higher. The upper limit is not particularly limited and is, for example, 30000 (L/mol·cm) or lower. In a case where the molar absorption coefficient of the copper complex is 100 (L/mol·cm) or higher, a film having infrared shielding properties can be formed although the film is thin.

The gram absorption coefficient of the copper complex at 800 nm is preferably 0.11 (L/g·cm) or higher, more preferably 0.15 (L/g·cm) or higher, and still more preferably 0.24 (L/g·cm) or higher.

In the present invention, the molar absorption coefficient and the gram absorption coefficient of the copper complex can be obtained by dissolving the copper complex in a solvent to prepare a solution having a concentration of 1 g/L and measuring an absorption spectrum of the solution in which the copper complex is dissolved. As a measuring device, for example, UV-1800 manufactured by Shimadzu Corporation (wavelength range: 200 to 1100 nm) or Cary 5000 manufactured by Agilent Technologies Inc. (wavelength range: 200 to 1300 nm) can be used. Examples of the measurement solvent include water, N,N-dimethylformamide, propylene glycol monomethyl ether, 1,2,4-trichlorobenzene, and acetone. In the present invention, a solvent in which the copper complex as the measurement target is soluble is selected from the above-described measurement solvents. In particular, in a case where a copper complex that is soluble in propylene glycol monomethyl ether is used, it is preferable that propylene glycol monomethyl ether is used as the measurement solvent. “Soluble” represents a state where the solubility of the copper complex in the solvent at 25° C. is higher than 0.01 g/100 g Solvent.

In the present invention, the molar absorption coefficient and the gram absorption coefficient of the copper complex are preferably values measured using any one of the above-described measurement solvents and more preferably values measured using propylene glycol monomethyl ether.

<<<Low Molecular Weight Compound Type Copper Compound>>>

In the present invention, as the copper compound, for example, a copper complex represented by the following Formula (Cu-1) can be used. This copper complex is a copper compound in which a ligand L is coordinated to copper as central metal, and the copper is typically divalent copper. For example, the copper complex can be obtained, for example, by mixing, reaction, or the like of a compound which forms the ligand L or a salt thereof with a copper component.

Cu(L)ₙ₁.(X)ₙ₂ Formula (Cu-1)

In the formula, L represents a ligand coordinated to copper, and X represents a counter ion. n1 represents an integer of 1 to 4. n2 represents an integer of 0 to 4.

X represents a counter ion. The copper compound site may be a neutral complex having no charge, a cationic complex, or an anionic complex. In this case, optionally, a counter ion is present to neutralize the charge of the copper compound.

In a case where the counter ion is a negative counter ion, for example, the counter ion may be an inorganic ion or an organic ion. Specific examples include a hydroxide ion, a halogen anion (for example, a fluoride ion, a chloride ion, a bromide ion, or an iodide ion), a substituted or unsubstituted alkylcarboxylate ion (for example, an acetate ion or a trifluoroacetate ion), a substituted or unsubstituted arylcarboxylate ion (for example, a benzoate ion), a substituted or unsubstituted alkylmethanesulfonate ion (for example, a methanesulfonate ion, a trifluoromethanesulfonate ion), a substituted or unsubstituted arylsulfonate ion (for example, a p-toluenesulfonate ion or a p-chlorobenzenesulfonate ion), an aryldisulfonate ion (for example, a 1,3-benzenedisulfonate ion, a 1,5-naphthalene disulfonate ion, or an 2,6-naphthalenedisulfonate ion), an alkylsulfate ion (for example, a methylsulfate ion), a sulfate ion, a thiocyanate ion, a nitrate ion, a perchlorate ion, a tetrafluoroborate ion, a tetraarylborate ion, a tetrakis(pentafluorophenyl)borate ion (B⁻(C₆F5)₄), a hexafluorophosphate ion, a picrate ion, an amide ion (including amide substituted with an acyl group or a sulfonyl group), and a methide ion (including a methide substituted with an acyl group or a sulfonyl group). Among these, a halogen anion, a substituted or unsubstituted alkylcarboxylate ion, a sulfate ion, a nitrate ion, a tetrafluoroborate ion, a tetraarylborate ion, a hexafluorophosphate ion, an amide ion (including amide substituted with an acyl group or a sulfonyl group), a methide ion (including a methide substituted with an acyl group or a sulfonyl group) is preferable.

In a case where the counter ion is a positive counter ion, examples of the positive counter ion include an inorganic or organic ammonium ion (for example, a tetraalkylammonium ion such as a tetrabutylammonium ion, a triethylbenzylammonium ion, or a pyridinium ion), a phosphonium ion (for example, a tetraalkylphosphonium ion such as a tetrabutylphosphonium ion, an alkyltriphenylphosphonium ion, or a triethylphenylphosphonium ion), an alkali metal ion, and a proton.

In addition, the counter ion may be a metal complex ion. In particular, the counter ion may be a salt of a copper complex, that is, a cationic copper complex or an anionic copper complex.

The ligand L is a compound having a coordination site coordinated to copper, and examples thereof include a compound having one or more selected from the group consisting of a coordination site coordinated to copper by an anion and a coordinating atom coordinated to copper by an unshared electron pair. The coordination site coordinated by an anion may or may not be dissociable. As the ligand L, a compound (multidentate ligand) having two or more coordination sites coordinated to copper is preferable. In addition, in order to improve visible transparency, it is preferable that a plurality of 7n-conjugated systems such as aromatic compounds are not continuously bonded to each other in the ligand L. As the ligand L, a compound (monodentate ligand) having one coordination site coordinated to copper and a compound (multidentate ligand) having two or more coordination sites coordinated to copper can also be used in combination.

Examples of the monodentate ligand include a monodentate ligand coordinated by an anion or an unshared electron pair. Examples of the ligand coordinated by an anion include a halide anion, a hydroxide anion, an alkoxide anion, a phenoxide anion, an amide anion (including amide substituted with an acyl group or a sulfonyl group), an imide anion (including imide substituted with an acyl group or a sulfonyl group), an anilide anion (including anilide substituted with an acyl group or a sulfonyl group), a thiolate anion, a hydrogen carbonate anion, a carboxylate anion, a thiocarboxylate anion, a dithiocarboxylate anion, a hydrogen sulfate anion, a sulfonate anion, a dihydrogen phosphate anion, a phosphoric acid diester anion, a phosphonic acid monoester anion, a hydrogen phosphonate anion, a phosphinate anion, a nitrogen-containing heterocyclic anion, a nitrate anion, a hypochlorite anion, a cyanide anion, a cyanate anion, an isocyanate anion, a thiocyanate anion, an isothiocyanate anion, and an azide anion. Examples of the monodentate ligand coordinated by an unshared electron pair include water, alcohol, phenol, ether, amine, aniline, amide, imide, imine, nitrile, isonitrile, thiol, thioether, a carbonyl compound, a thiocarbonyl compound, sulfoxide, a heterocyclic ring, carbonic acid, carboxylic acid, sulfuric acid, sulfonic acid, phosphoric acid, phosphonic acid, phosphinic acid, nitric acid, and an ester thereof.

The anion in the multidentate ligand may be an anion capable of coordination to a copper atom in the copper component and is preferably an oxygen anion, a nitrogen anion, or a sulfur anion. It is preferable that the coordination site coordinated by an anion is at least one selected from the following Group (AN-1) of monovalent functional groups or Group (AN-2) of divalent functional groups. In the following structural formulae, a wave line represents a binding site to an atomic group constituting a ligand.

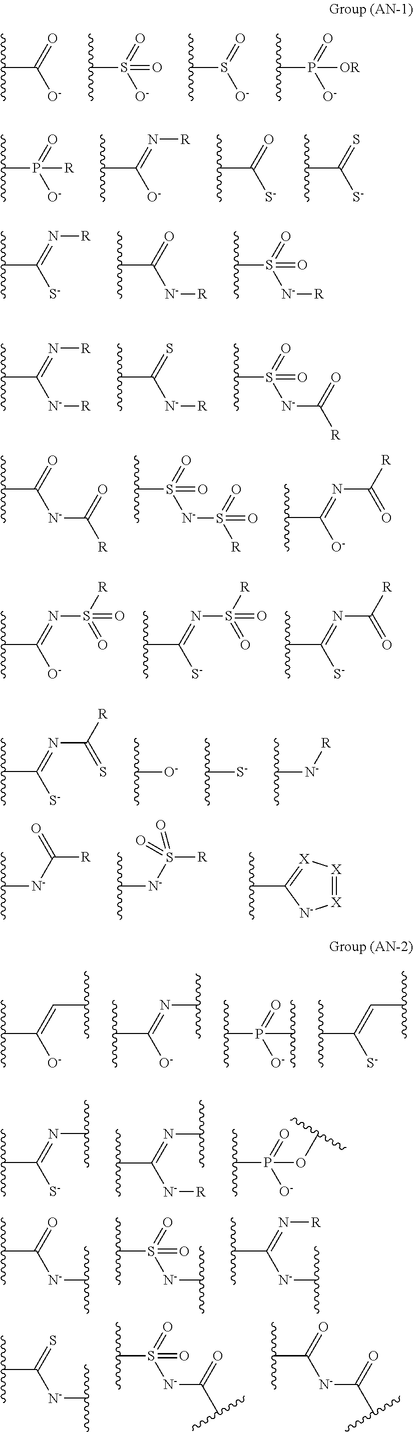

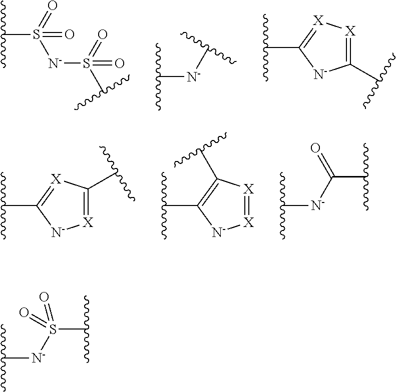

In the formulae, X represents N or CR and R's each independently represent a hydrogen atom, an alkyl group, and alkenyl group, an alkynyl group, an aryl group, or a heteroaryl group.

The alkyl group represented by R may be linear, branched, or cyclic and is preferably linear. The number of carbon atoms in the alkyl group is preferably 1 to 10, more preferably 1 to 6, and still more preferably 1 to 4. Examples of the alkyl group include a methyl group. The alkyl group may have a substituent, and examples of the substituent include a halogen atom, a carboxyl group, and a heterocyclic group. The heterocyclic group as the substituent may be monocyclic or polycyclic and may be aromatic or nonaromatic. The number of heteroatoms constituting the heterocycle is preferably 1 to 3 and more preferably 1 or 2. It is preferable that the heteroatom constituting the heterocycle is a nitrogen atom. In a case where the alkyl group has a substituent, the substituent may further have a substituent.

The alkenyl group represented by R may be linear, branched, or cyclic and is preferably linear. The number of carbon atoms in the alkenyl group is preferably 1 to 10 and more preferably 1 to 6. The alkenyl group may be unsubstituted or may have a substituent. Examples of the substituent include the above-described substituents.

The alkynyl group represented by R may be linear, branched, or cyclic and is preferably linear. The number of carbon atoms in the alkynyl group is preferably 1 to 10 and more preferably 1 to 6. The alkynyl group may be unsubstituted or may have a substituent. Examples of the substituent include the above-described substituents.

The aryl group represented by R may be monocyclic or polycyclic and is preferably monocyclic. The number of carbon atoms in the aryl group is preferably 6 to 18, more preferably 6 to 12, and still more preferably 6. The aryl group may be unsubstituted or may have a substituent. Examples of the substituent include the above-described substituents.

The heteroaryl group represented by R may be monocyclic or polycyclic. The number of heteroatoms constituting the heteroaryl group is preferably 1 to 3. It is preferable that the heteroatoms constituting the heteroaryl group are a nitrogen atom, a sulfur atom, or an oxygen atom. The number of carbon atoms in the heteroaryl group is preferably 6 to 18 and more preferably 6 to 12. The heteroaryl group may have a substituent or may be unsubstituted. Examples of the substituent include the above-described substituents.

Examples of the coordination site coordinated by an anion include a monoanionic coordination site. The monoanionic coordination site represents a site that is coordinated to a copper atom through a functional group having one negative charge. Examples of the monoanionic coordination site include an acid group having an acid dissociation constant (pka) of 12 or lower. Specific examples include an acid group having a phosphorus atom (for example, a phosphoric acid diester group, a phosphonic acid monoester group, or a phosphinic acid group), a sulfo group, a carboxyl group, and an imide acid group. Among these, a sulfo group or a carboxyl group is preferable.

As the coordinating atom coordinated by an unshared electron pair, an oxygen atom, a nitrogen atom, a sulfur atom, or a phosphorus atom is preferable, an oxygen atom, a nitrogen atom, or a sulfur atom is more preferable, an oxygen atom or a nitrogen atom is still more preferable, and a nitrogen atom is even still more preferable. In a case where the coordinating atom coordinated by an unshared electron pair is a nitrogen atom, it is preferable that an atom adjacent to the nitrogen atom is a carbon atom or a nitrogen atom.

It is preferable that the coordinating atom coordinated by an unshared electron pair is included in a ring or at least one partial structure selected from the following Group (UE-1) of monovalent functional groups, Group (UE-2) of divalent functional groups, and Group (UE-3) of trivalent functional groups. In the following structural formulae, a wave line represents a binding site to an atomic group constituting a ligand.

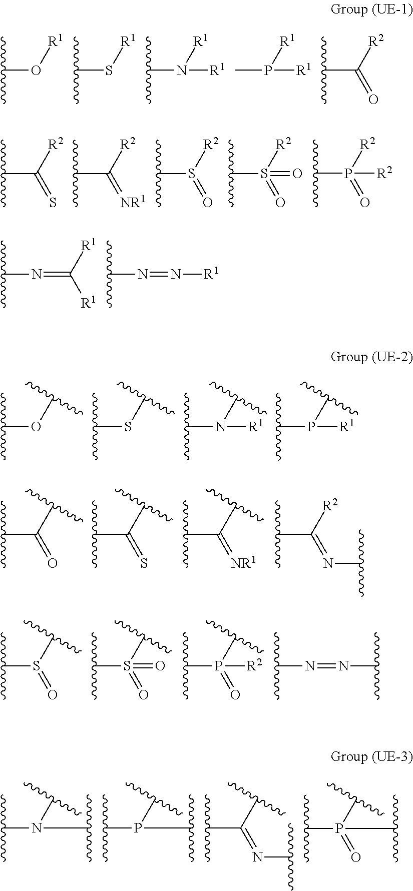

In Groups (UE-1) to (UE-3), R¹ represents a hydrogen atom, an alkyl group, an alkenyl group, an alkynyl group, an aryl group, or a heteroaryl group, and R² represents a hydrogen atom, an alkyl group, an alkenyl group, an alkynyl group, an aryl group, a heteroaryl group, an alkoxy group, an aryloxy group, a heteroaryloxy group, an alkylthio group, an arylthio group, a heteroarylthio group, an amino group, or an acyl group.

The coordinating atom coordinated by an unshared electron pair is included in a ring. In a case where the coordinating atom coordinated by an unshared electron pair is included in a ring, the ring including the coordinating atom coordinated by an unshared electron pair may be monocyclic or polycyclic and may be aromatic or nonaromatic. The ring including the coordinating atom coordinated by an unshared electron pair is preferably a 5- to 12-membered ring and more preferably a 5- to 7-membered ring.

The ring including the coordinating atom coordinated by an unshared electron pair may have a substituent. Examples of the substituent include a linear, branched, or cyclic alkyl group having 1 to 10 carbon atoms, an aryl group having 6 to 12 carbon atoms, a halogen atom, a silicon atom, an alkoxy group having 1 to 12 carbon atoms, an acyl group having 2 to 12 carbon atoms, an alkylthio group having 1 to 12 carbon atoms, and a carboxyl group.

In a case where the ring including the coordinating atom coordinated by an unshared electron pair has a substituent, the substituent may further have a substituent. Examples of the substituent include a group which includes a ring including a coordinating atom coordinated by an unshared electron pair, a group which includes at least one partial structure selected from Groups (UE-1) to (UE-3), an alkyl group having 1 to 12 carbon atoms, an acyl group having 2 to 12 carbon atoms, and a hydroxyl group.

In a case where the coordinating atom coordinated by an unshared electron pair is included in a partial structure selected from Groups (UE-1) to (UE-3), R¹ represents a hydrogen atom, an alkyl group, an alkenyl group, an alkynyl group, an aryl group, or a heteroaryl group, and R² represents a hydrogen atom, an alkyl group, an alkenyl group, an alkynyl group, an aryl group, a heteroaryl group, an alkoxy group, an aryloxy group, a heteroaryloxy group, an alkylthio group, an arylthio group, a heteroarylthio group, an amino group, or an acyl group.

The alkyl group, the alkenyl group, the alkynyl group, the aryl group, and the heteroaryl group have the same definitions and the same preferable ranges as the alkyl group, the alkenyl group, the alkynyl group, the aryl group, and the heteroaryl group described above regarding the coordination site coordinated by an anion.

The number of carbon atoms in the alkoxy group is preferably 1 to 12 and more preferably 3 to 9.

The number of carbon atoms in the aryloxy group is preferably 6 to 18 and more preferably 6 to 12.

The heteroaryloxy group may be monocyclic or polycyclic. The heteroaryl group constituting the heteroaryloxy group has the same definition and the same preferable range as the heteroaryl group described above regarding the coordination site coordinated by an anion.

The number of carbon atoms in the alkylthio group is preferably 1 to 12 and more preferably 1 to 9.

The number of carbon atoms in the arylthio group is preferably 6 to 18 and more preferably 6 to 12.

The heteroarylthio group may be monocyclic or polycyclic. The heteroaryl group constituting the heteroarylthio group has the same definition and the same preferable range as the heteroaryl group described above regarding the coordination site coordinated by an anion.

The number of carbon atoms in the acyl group is preferably 2 to 12 and more preferably 2 to 9.

In a case where the ligand has a coordination site coordinated by an anion and a coordinating atom coordinated by an unshared electron pair in one molecule, the number of atoms linking the coordination site coordinated by an anion and the coordinating atom coordinated by an unshared electron pair is preferably 1 to 6 and more preferably 1 to 3. With the above-described configuration, the structure of the copper complex is more likely modified. Thus a color value can be further improved, and the molar absorption coefficient can be easily increased while improving visible light transmittance. As the atoms linking the coordination site coordinated by an anion and the coordinating atom coordinated by an unshared electron pair, one kind or two or more kinds may be used. A carbon atom or a nitrogen atom is preferable.

In a case where the ligand has two or more coordinating atoms coordinated by an unshared electron pair in one molecule, the number of coordinating atoms coordinated by an unshared electron pair may be 3 or more and is preferably 2 to 5 and more preferably 4. The number of atoms linking the coordinating atoms coordinated by an unshared electron pair is preferably 1 to 6, more preferably 1 to 3, and still more preferably 2 or 3. With the above-described configuration, the structure of the copper complex is more likely modified, and thus color value can be further improved. As the atom linking the coordinating atoms coordinated by an unshared electron pair, one kind or two or more kinds may be used. As the atom linking the coordinating atoms coordinated by an unshared electron pair, a carbon atom is preferable.

In the present invention, it is preferable that the ligand is a compound (multidentate ligand) having at least two coordination sites. The number of coordination sites in the ligand is more preferably at least 3, still more preferably 3 to 5, and even still more preferably 4 or 5.

Examples of the multidentate ligand include a compound having one or more coordination sites coordinated by an anion and one or more coordinating atoms coordinated by an unshared electron pair, a compound having two or more coordinating atoms coordinated by an unshared electron pair, and a compound having two coordination sites coordinated by an anion. As each of the compounds, one kind may be used alone, or two or more kinds may be used in combination. In addition, as the compound which forms the ligand, a compound having only one coordination site can also be used.

It is preferable that the multidentate ligand is a compound represented by any one of the following Formulae (IV-1) to (IV-14). For example, in a case where the ligand is a compound having four coordination sites, a compound represented by the following Formula (IV-3), (IV-6), (IV-7), or (IV-12) is preferable, and a compound represented by the following formula (IV-12) is more preferable because the ligand can be more strongly coordinated to the metal center to form a stable tetradentate-coordinated complex having high heat resistance. In addition, for example, in a case where the ligand is a compound having five coordination sites, the following Formula (IV-4), (IV-8) to (IV-11), (IV-13), or (IV-14) is preferable, a compound represented by the following Formula (IV-9), (IV-10), (IV-13), or (IV-14) is more preferable, and a compound represented by the following Formula (IV-13) is still more preferable because the multidentate ligand can be more strongly coordinated to the metal center to form a stable pentadentate-coordinated complex having high heat resistance.

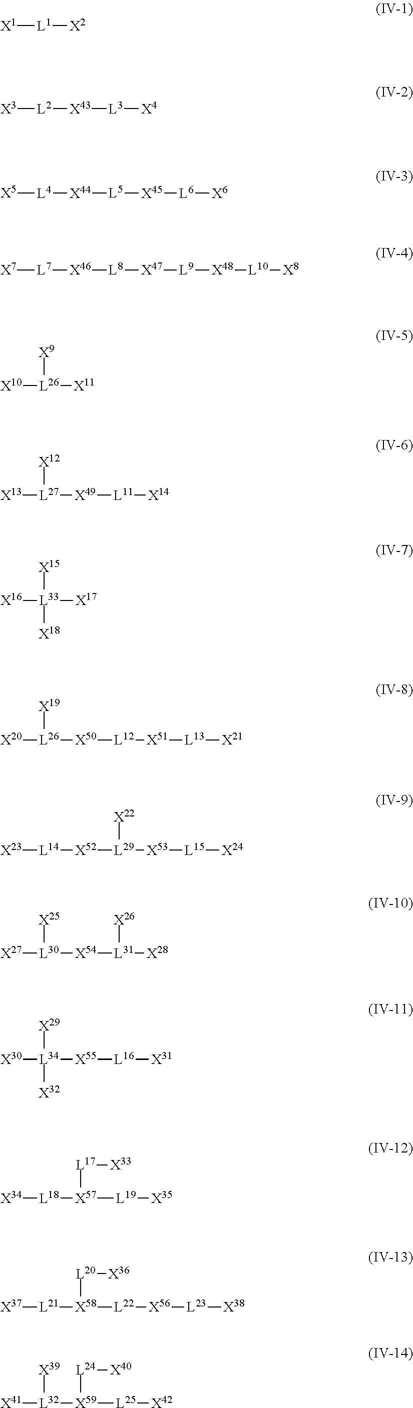

In Formulae (IV-1) to (IV-14), it is preferable that X¹ to X⁵⁹ each independently represent a coordination site, L′ to L²⁵ each independently represent a single bond or a divalent linking group, L²⁶ to L³² each independently represent a trivalent linking group, and L³³ to L³⁴ each independently represent a tetravalent linking group.

It is preferable that X¹ to X⁴² each independently represent a group which includes a ring including a coordinating atom coordinated by an unshared electron pair or at least one selected from Group (AN-1) or Group (UE-1).

It is preferable that X⁴³ to X⁵⁶ each independently represent a group which includes a ring including a coordinating atom coordinated by an unshared electron pair or at least one selected from Group (AN-2) or Group (UE-2).

It is preferable that X⁵⁷ to X⁵⁹ each independently represent at least one selected from Group (UE-3).

L¹ to L²⁵ each independently represent a single bond or a divalent linking group. As the divalent linking group, an alkylene group having 1 to 12 carbon atoms, an arylene group having 6 to 12 carbon atoms, —SO—, —O—, —SO₂—, or a group including a combination of the above-described groups is preferable, and an alkylene group having 1 to 3 carbon atoms, a phenylene group, —SO₂—, or a group of a combination of the above-described groups is more preferable.

L²⁶ to L³² each independently represent a trivalent linking group. Examples of the trivalent linking group include a group obtained by removing one hydrogen atom from the divalent linking group.

L³³ to L³⁴ each independently represent a tetravalent linking group. Examples of the tetravalent linking group include a group obtained by removing two hydrogen atoms from the divalent linking group.

Here, regarding R in Groups (AN-1) and (AN-2) and R¹ in Groups (UE-1) to (UE-3), R's, R¹'s, or R and R¹ may be linked to each other to form a ring.

For example, specific examples of Formula (IV-2) include the following compound (IV-2A). X³, X⁴, and X⁴³ represent the following groups, L² and L³ represent a methylene group, and R¹ represents a methyl group. R¹'s may be linked to each other to form a ring and have a structure represented by the following Formula (IV-2B) or (IV-2C).

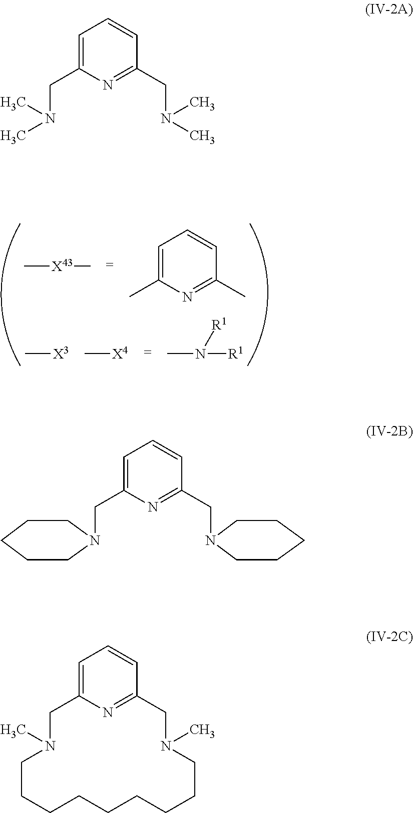

Specific examples of the compound which forms the ligand include the following compounds and salts thereof. Examples of an atom constituting the salts include a metal atom and tetrabutylammonium. As the metal atom, an alkali metal atom or an alkali earth metal atom is more preferable. Examples of the alkali metal atom include sodium and potassium. Examples of the alkali earth metal atom include calcium and magnesium. In addition, the details can be found in paragraphs “0022” to “0042” of JP2014-41318A and paragraphs “0021” to “0039” of JP2015-43063A, the contents of which are incorporated herein by reference.

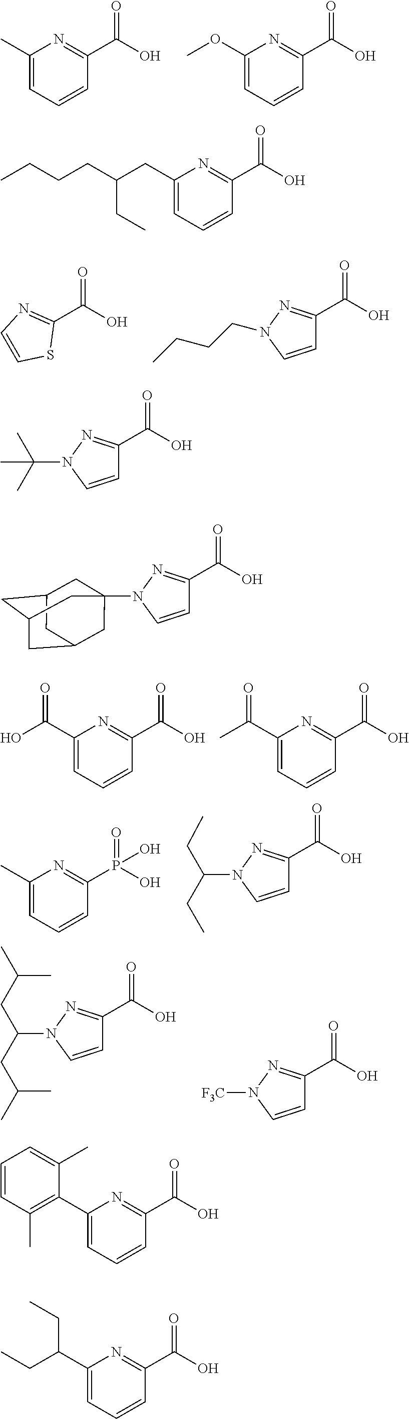

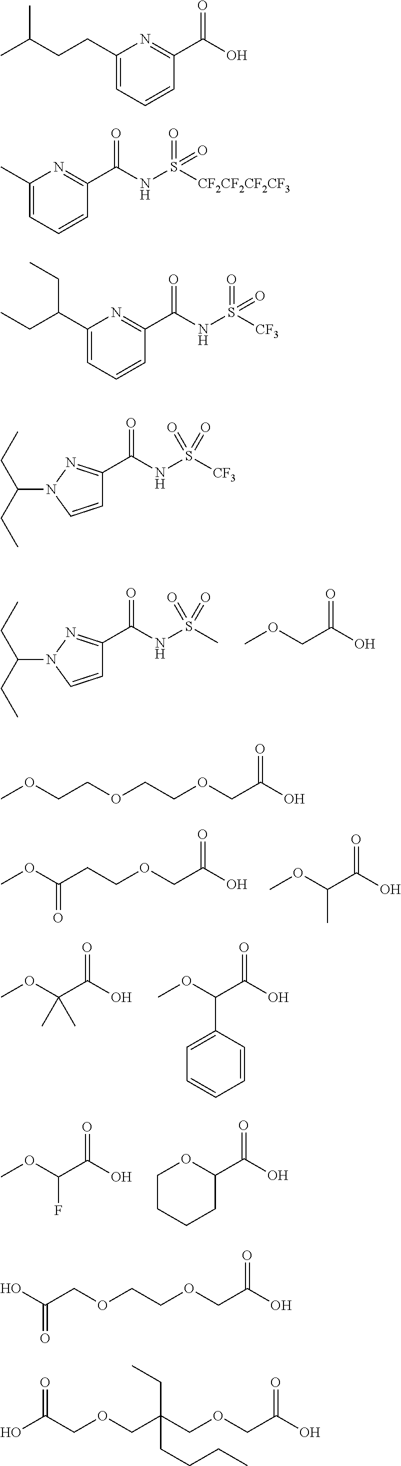

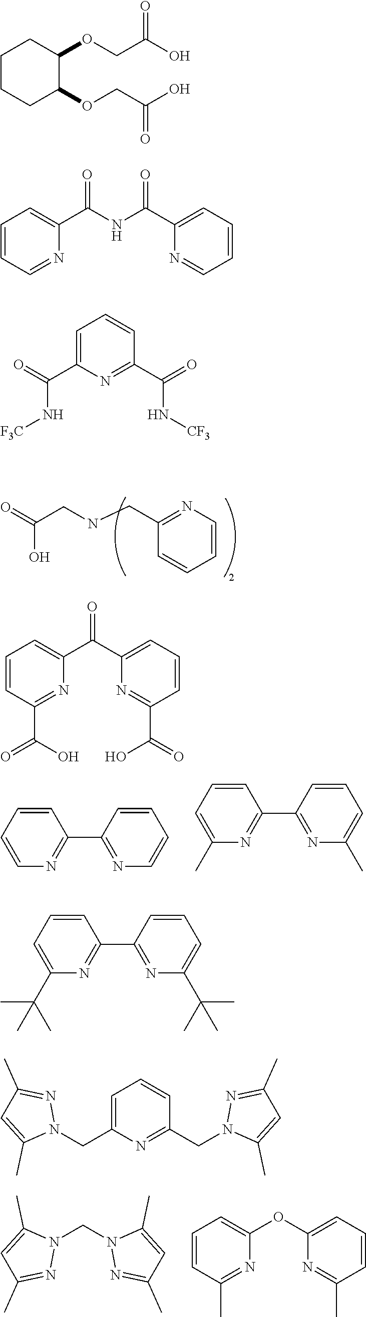

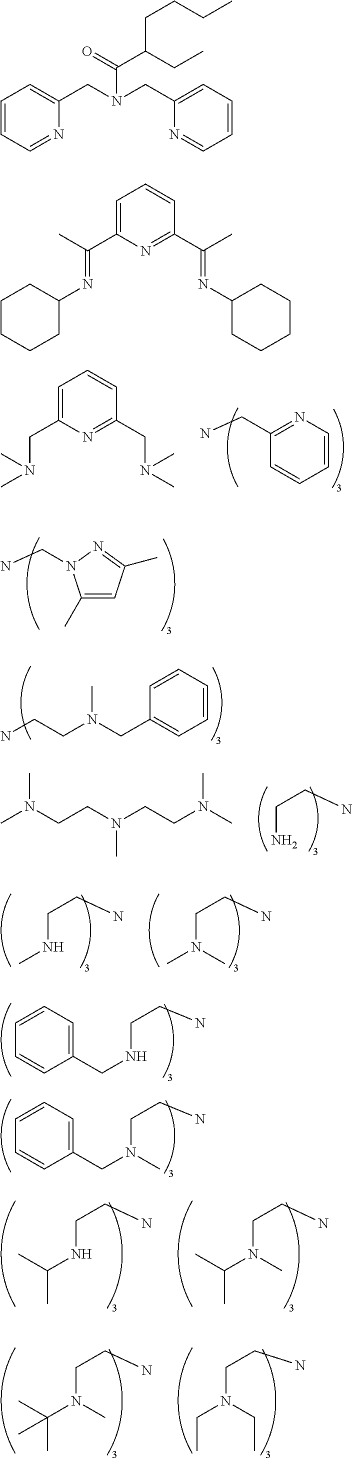

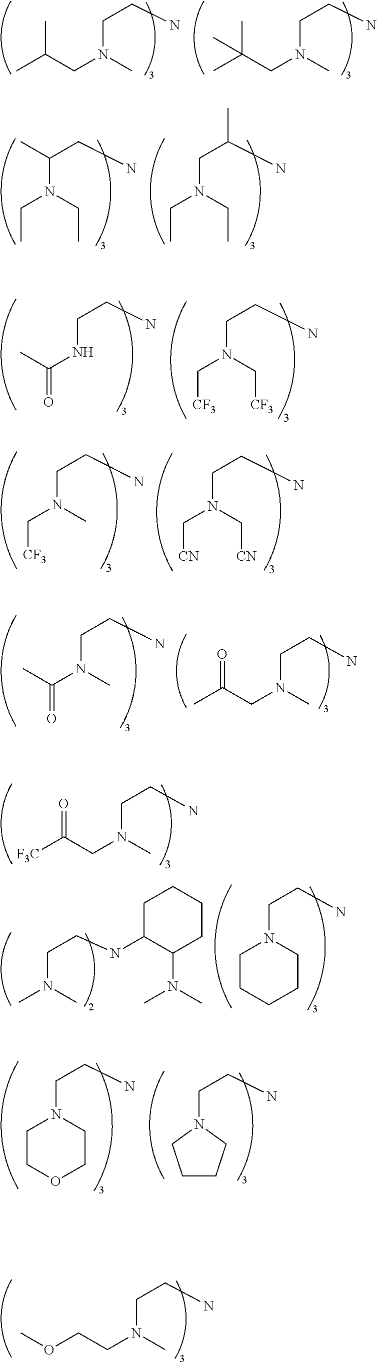

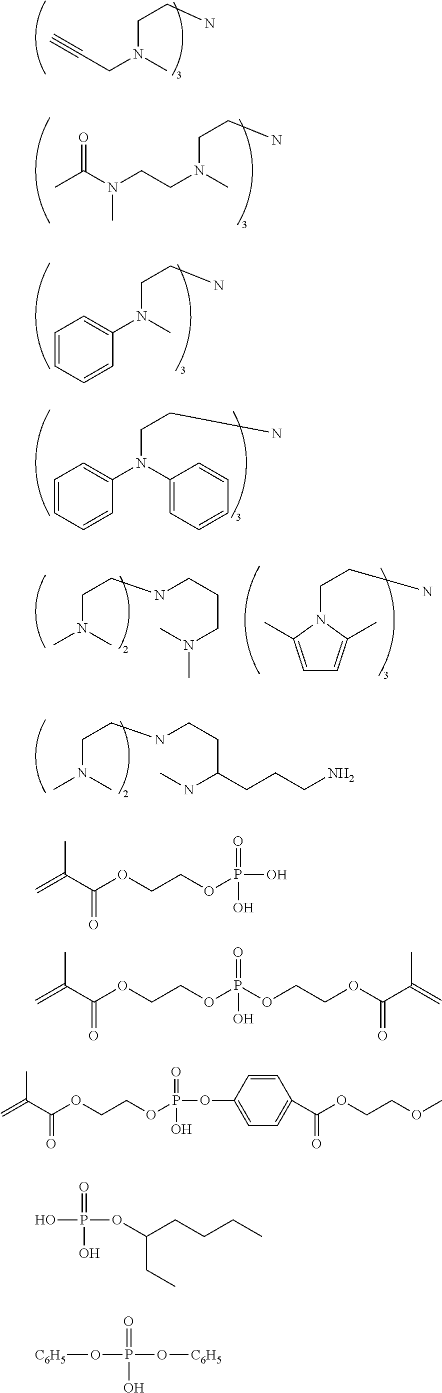

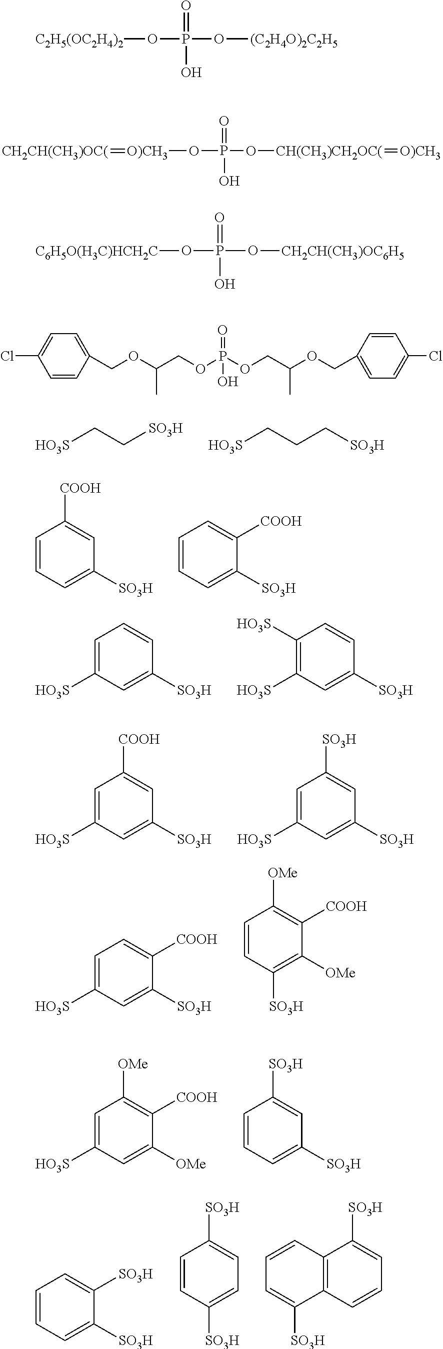

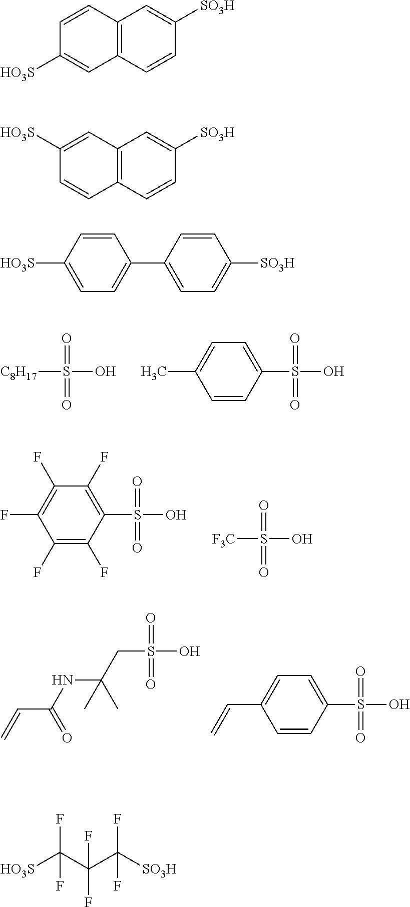

As the copper complex used in the present invention, for example, the following aspects (1) to (5) are preferable, the aspects (2) to (5) are more preferable, the aspects (3) to (5) are still more preferable, and the aspect (4) is even still more preferable.

(1) a copper complex which includes one or two compounds having two coordination sites as a ligand

(2) a copper complex which includes a compound having three coordination sites as a ligand

(3) a copper complex which includes a compound having three coordination sites and a compound having two coordination sites as a ligand

(4) a copper complex which includes a compound having four coordination sites as a ligand

(5) a copper complex which includes a compound having five coordination sites as a ligand

In the aspect (1), it is preferable that the compound having two coordination sites is a compound having two coordinating atoms coordinated by an unshared electron pair or a compound having a coordination site coordinated by an anion and a coordinating atom coordinated by an unshared electron pair. In addition, in a case where the copper complex includes two compounds having two coordination sites as a ligand, the compounds as the ligand may be the same as or different from each other.

In addition, in the aspect (1), the copper complex may further include the monodentate ligand. The number of monodentate ligands may be 0 or 1 to 3. Regarding the kind of the monodentate ligand, a monodentate ligand coordinated by an anion or a monodentate ligand coordinated by an unshared electron pair is preferable. In a case where the compound having two coordination sites is a compound having two coordinating atoms coordinated by an unshared electron pair, a monodentate ligand coordinated by an anion is more preferable because a coordination force is strong. In a case where the compound having two coordination sites is a compound having a coordination site coordinated by an anion and a coordinating atom coordinated by an unshared electron pair, a monodentate ligand coordinated by an unshared electron pair is more preferable because the entire complex has no charge.

In the aspect (2), as the compound having three coordination sites, a compound having a coordinating atom coordinated by an unshared electron pair is preferable, and a compound having three coordinating atoms coordinated by an unshared electron pair is more preferable.

In addition, in the aspect (2), the copper complex site may further include a monodentate ligand. The number of monodentate ligands may be 0. In addition, the number of monodentate ligands may be 1 or more and is preferably 1 to 3, more preferably 1 or 2, and still more preferably 2. Regarding the kind of the monodentate ligand, a monodentate ligand coordinated by an anion or a monodentate ligand coordinated by an unshared electron pair is preferable, and a monodentate ligand coordinated by an anion is more preferable due to the above-described reason.

In the aspect (3), as the compound having three coordination sites, a compound having a coordination site coordinated by an anion and a coordinating atom coordinated by an unshared electron pair is preferable, and a compound having two coordination sites coordinated by an anion and one coordinating atom coordinated by an unshared electron pair is more preferable. Further, it is still more preferable that the two coordination sites coordinated by an anion are different from each other. In addition, as the compound having two coordination sites, a compound having a coordinating atom coordinated by an unshared electron pair is preferable, and a compound having two coordinating atoms coordinated by an unshared electron pair is more preferable. In particular, it is preferable that the compound having three coordination sites is a compound having two coordination sites coordinated by an anion and one coordinating atom coordinated by an unshared electron pair and the compound having two coordination sites is a compound having two coordinating atoms coordinated by an unshared electron pair.

In addition, in the aspect (3), the copper complex site may further include a monodentate ligand. The number of monodentate ligands may be 0 or 1 or more. The number of monodentate ligand is preferably 0.

In the aspect (4), as the compound having four coordination sites, a compound having a coordinating atom coordinated by an unshared electron pair is preferable, a compound having two or more coordinating atoms coordinated by an unshared electron pair is more preferable, and a compound having four coordinating atoms coordinated by an unshared electron pair is still more preferable.

In addition, in the aspect (4), the copper complex site may further include a monodentate ligand. The number of monodentate ligands may be 0, 1 or more, or 2 or more. The number of monodentate ligand is preferably 1. Regarding the kind of the monodentate ligand, a monodentate ligand coordinated by an anion or a monodentate ligand coordinated by an unshared electron pair is preferable.

In the aspect (5), as the compound having five coordination sites, a compound having a coordinating atom coordinated by an unshared electron pair is preferable, a compound having two or more coordinating atoms coordinated by an unshared electron pair is more preferable, and a compound having five coordinating atoms coordinated by an unshared electron pair is still more preferable.

In addition, in the aspect (5), the copper complex site may further include a monodentate ligand. The number of monodentate ligands may be 0 or 1 or more. The number of monodentate ligand is preferably 0.

[Copper Phosphate Complex]

In the present invention, as the copper compound, a copper phosphate complex can also be used. The copper phosphate complex has copper as central metal and has a phosphate compound as a ligand. As the phosphate compound which forms the ligand of the copper phosphate complex, a compound represented by the following Formula (L-100) or a salt thereof is preferable.

(HO)ₙ—P(═O)—(OR¹)₃₋ₙ Formula (L-100)

In the formula, R¹ represents an alkyl group having 1 to 18 carbon atoms, an aryl group having 6 to 18 carbon atoms, an aralkyl group having 1 to 18 carbon atoms, or an alkenyl group having 1 to 18 carbon atoms. Alternatively, —OR¹ represents a polyoxyalkyl group having 4 to 100 carbon atoms, a (meth)acryloyloxyalkyl group having 4 to 100 carbon atoms, or a (meth)acryloylpolyoxyalkyl group having 4 to 100 carbon atoms, and n represents 1 or 2. In a case where n represents 1, R²'s may be the same as or different from each other.

In the formula, it is preferable that at least one —OR¹ represents a (meth)acryloyloxyalkyl group having 4 to 100 carbon atoms or a (meth)acryloylpolyoxyalkyl group having 4 to 100 carbon atoms, and it is more preferable that at least one —OR¹ represents a (meth)acryloyloxyalkyl group having 4 to 100 carbon atoms. Each of the number of polyoxyalkyl groups, the number of (meth)acryloyloxyalkyl groups, and the number of (meth)acryloylpolyoxyalkyl groups is preferably 4 to 20 and more preferably 4 to 10.

The molecular weight of the phosphate compound is preferably 300 to 1500 and more preferably 320 to 900.

Specific examples of the phosphate compound include the above-described ligand. In addition, the details can be found in paragraphs “0022” to “0042” of JP2014-41318A, the content of which is incorporated herein by reference.

[Copper Sulfate Complex]

In the present invention, as the copper compound, a copper sulfate complex can also be used. The copper sulfate complex has copper as central metal and has a sulfonic acid compound as a ligand. As the sulfonic acid compound which forms the ligand of the copper sulfate complex, a compound represented by the following Formula (L-200) or a salt thereof is preferable.

R²—SO₂—OH Formula (L-200)

In the formula, R² represents a monovalent organic group. Examples of the monovalent organic group include an alkyl group, an aryl group, and a heteroaryl group.

The alkyl group may be linear, branched, or cyclic and is preferably linear. The number of carbon atoms in the alkyl group is preferably 1 to 30, more preferably 1 to 20, and still more preferably 1 to 10.

The aryl group may be monocyclic or polycyclic and is preferably monocyclic. The number of carbon atoms in the aryl group is preferably 6 to 25 and more preferably 6 to 10.

The heteroaryl group may be monocyclic or polycyclic. The number of heteroatoms constituting the heteroaryl group is preferably 1 to 3. It is preferable that the heteroatoms constituting the heteroaryl group are a nitrogen atom, a sulfur atom, or an oxygen atom. The number of carbon atoms in the heteroaryl group is preferably 6 to 18 and more preferably 6 to 12.

The alkyl group, the aryl group, and the heteroaryl group may be unsubstituted or may have a substituent. Examples of the substituent include a polymerizable group (preferably a group having an ethylenically unsaturated bond such as a vinyl group a (meth)acryloyloxy group, or a (meth)acryloyl group), a halogen atom (a fluorine atom, a chlorine atom, a bromine atom, or an iodine atom), an alkyl group, a carboxylic acid (for example, —CO₂CH₃), an alkyl halide group, an alkoxy group, a methacryloyloxy group, an acryloyloxy group, an ether group, an alkylsulfonyl group, an arylsulfonyl group, a sulfide group, an amido group, an acyl group, a hydroxyl group, a carboxyl group, a sulfonate group, an acid group containing a phosphorus atom, an amino group, a carbamoyl group, and a carbamoyloxy group.

As the alkyl halide group, an alkyl group substituted with a fluorine atom is preferable. In particular, an alkyl group having 1 to 10 carbon atoms which has two or more fluorine atoms is preferable. The alkyl halide group may be linear, branched, or cyclic and is preferably linear or branched. The number of carbon atoms in the alkyl halide group is preferably 1 to 10, more preferably 1 to 5, and still more preferably 1 to 3. In the alkyl group substituted with a fluorine atom, it is preferable that a terminal structure is (—CF₃). The substitution ratio of the alkyl group substituted with a fluorine atom is preferably 50% to 100%, and more preferably 80% to 100%. Here, the substitution ratio of the alkyl group substituted with a fluorine atom represents a ratio (%) at which a hydrogen atom is substituted with a fluorine atom in the alkyl group substituted with a fluorine atom. In particular, as the alkyl halide group, a perfluoroalkyl group is more preferable, a perfluoroalkyl group having 1 to 10 carbon atoms is still more preferable, and a trifluoroethyl group or a trifluoromethyl group is even still more preferable.

The alkyl group, the aryl group, and the heteroaryl group may have a divalent linking group. Examples of the divalent linking group include —(CH₂)ₘ— (m represents an integer of 1 to 10, preferably an integer of 1 to 6, and more preferably an integer of 1 to 4), a cyclic alkylene group having 5 to 10 carbon atoms, or a group including a combination of one of the above-described groups with at least one selected from the group consisting of —O—, —COO—, —S—, —NH—, and —CO— is preferable.

In Formula (L-200), R² represents preferably an organic group having a formula weight of 300 or lower, more preferably an organic group having a formula weight of 50 to 200, and still more preferably an organic group having a formula weight of 60 to 100.

The molecular weight of the sulfonic acid compound represented by Formula (L-200) is preferably 80 to 750, more preferably 80 to 600, and still more preferably 80 to 450.

It is preferable that the copper sulfate complex has a structure represented by the following Formula (L-201).

R^{2A}—SO₂—O—* (L-201)

In the formula, R^{2A} has the same definition and the same preferable range as R² in Formula (L-200).

Specific examples of the sulfonic acid compound include the above-described ligand. In addition, the details can be found in paragraphs “0021” to “0039” of JP2015-43063A, the content of which is incorporated herein by reference.

<<<Polymer Type Copper Compound>>>

In the present invention, as the copper compound, a copper-containing polymer having a copper complex site at a polymer side chain can be used. It is presumed that, since the copper-containing polymer has a copper complex site at a polymer side chain, a crosslinked structure is formed between side chains of the polymer with copper as a source, and a film having excellent heat resistance can be obtained.

Examples of the copper complex site include copper and a site (coordination site) coordinated to copper. Examples of the site coordinated to copper include a site coordinated by an anion or an unshared electron pair. In addition, it is preferable that the copper complex site includes a site tetradentate- or pentadentate-coordinated to copper. The details of the coordination site are as described above regarding the low molecular weight compound type copper compound, and a preferable range is also the same.

Examples of the copper-containing polymer include, a polymer having a coordination site (also referred to as “polymer (B1)”), a polymer obtained from a reaction with a copper component, a polymer having a reactive site at a polymer side chain (hereinafter, also referred to as “polymer (B2)”), and a polymer obtained from a reaction with a copper complex having a functional group which is reactive with the reactive site in the polymer (B2).

(Polymer (B1))

It is preferable that the polymer (B1) having a coordination site has a group represented by the following Formula (1) at a side chain.

*-L¹-Y¹ (1)

In Formula (1), L¹ represents a single bond or a linking group, Y¹ represents a group having one or more selected from the group consisting of a coordination site coordinated to a copper component by an anion and a coordinating atom coordinated to a copper component by an unshared electron pair, and * represents a direct bond to the polymer.

In Formula (1), Y¹ represents a group having one or more selected from the group consisting of a coordination site coordinated to a copper component by an anion and a coordinating atom coordinated to a copper component by an unshared electron pair, and preferably a group having two or more coordination sites coordinated by an anion, a group having two or more coordinating atoms coordinated by an unshared electron pair, or a group having one or more coordinating atoms coordinated by an unshared electron pair and one or more coordination sites coordinated by an anion.

In a case where L¹ represents a linking group in Formula (1), examples of the divalent linking group include an alkylene group, an arylene group, a heteroarylene group, —O—, —S—, —CO—, —COO—, —OCO—, —SO₂—, —NR¹⁰— (R¹⁰ represents a hydrogen atom or an alkyl group and preferably a hydrogen atom), and a group including a combination thereof.

The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic.

As the arylene group, an arylene group having 6 to 18 carbon atoms is preferable, an arylene group having 6 to 14 carbon atoms is more preferable, an arylene group having 6 to 10 carbon atoms is still more preferable, and a phenylene group is even still more preferable.

The heteroarylene group is not particularly limited, and a 5-membered or 6-membered ring is preferable. Examples of a heteroatom include a nitrogen atom, a sulfur atom, and an oxygen atom. The number of heteroatoms is preferably 1 to 3. The heteroarylene group may be a monocycle or a fused ring and is preferably a monocycle or a fused ring composed of 2 to 8 rings, and more preferably a monocycle or a fused ring composed of 2 to 4 rings.

In a case where L¹ represents a trivalent or higher valent linking group, examples of the trivalent or higher valent linking group include groups obtained by removing one or more hydrogen atoms from the above-described examples of the divalent linking group.

It is preferable that the polymer (B1) includes a repeating unit represented by the following Formula (B1-1).

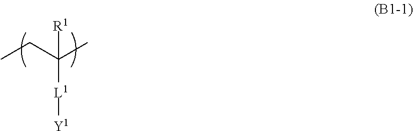

In Formula (B1-1), R¹ represents a hydrogen atom or a hydrocarbon group, L¹ represents a single bond or a linking group, and Y¹ represents a group having one or more selected from the group consisting of a coordination site coordinated to a copper component by an anion and a coordinating atom coordinated to a copper component by an unshared electron pair.

In Formula (B1-1), R¹ represents a hydrogen atom or a hydrocarbon group. Examples of the hydrocarbon group include a linear, branched, or cyclic aliphatic hydrocarbon group and an aromatic hydrocarbon group. The hydrocarbon group may have a substituent but is preferably unsubstituted. The number of carbon atoms in the hydrocarbon group is preferably 1 to 10, more preferably 1 to 5, and still more preferably 1 to 3. In addition, the hydrocarbon group is preferably a methyl group. It is preferable that R¹ represents a hydrogen atom or a methyl group.

L¹ and Y¹ in Formula (B1-1) have the same definitions and the same preferable ranges as L¹ and Y¹ in Formula (1).

Examples of the repeating unit represented by Formula (B1-1) include repeating units represented by the following Formulae (B1-1-1) to (B1-1-4). The following formula (B1-1-1) or (B1-1-2) is preferable.

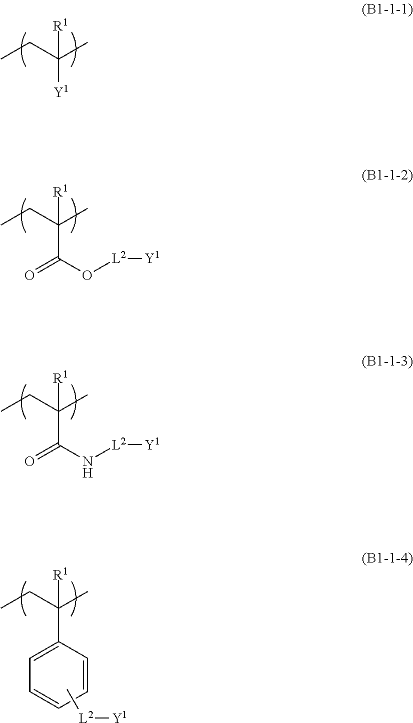

In Formulae (B1-1-1) to (B1-1-4), R¹ represents a hydrogen atom or a hydrocarbon group, L² represents a single bond or a linking group, and Y¹ represents a group having one or more selected from the group consisting of a coordination site coordinated to a copper component by an anion and a coordinating atom coordinated to a copper component by an unshared electron pair.

R¹ in Formulae (B1-1-1) to (B1-1-4) has the same definition and the same preferable range as R¹ in Formula (B1-1).

Y¹ in Formulae (B1-1-1) to (B1-1-4) has the same definition and the same preferable range as Y¹ in Formula (B1-1).

L² in Formulae (B1-1-2) to (B1-1-4) has the same definition and the same preferable range as L¹ in Formula (B1-1).

The polymer (B1) may include other repeating units in addition to the repeating unit represented by Formula (B1-1). The details of components constituting the other repeating units can be found in the description of copolymerization components in paragraphs “0068” to “0075” of JP2010-106268A (corresponding to paragraphs “0112” to “0118” of US2011/0124824A), the content of which is incorporated herein by reference.

In addition, the polymer (B1) has a group having one or more selected from the group consisting of a coordination site coordinated to a copper component by an anion and a coordinating atom coordinated to a copper component by an unshared electron pair, and a polymer having an aromatic hydrocarbon group and/or an aromatic heterocyclic group at a main chain (hereinafter, also referred to as “aromatic group-containing polymer”) may be used. The aromatic group-containing polymer is not particularly limited as long as it has at least one selected from the group consisting of an aromatic hydrocarbon group and an aromatic heterocyclic group at a main chain. The aromatic group-containing polymer may have two or more selected from the group consisting of an aromatic hydrocarbon group and an aromatic heterocyclic group.

The number of carbon atoms in the aromatic hydrocarbon group is preferably 6 to 20, more preferably 6 to 15, and still more preferably 6 to 12. In particular, a phenyl group, a naphthyl group, or a biphenyl group is preferable. The aromatic hydrocarbon group may be monocyclic or polycyclic and is preferably monocyclic.

The number of carbon atoms in the aromatic heterocyclic group is preferably 2 to 30. It is preferable that the aromatic heterocyclic group is a 5- or 6-membered ring. The aromatic heterocyclic group is preferably a monocycle or a fused ring composed of 2 to 8 rings, and more preferably a monocycle or a fused ring composed of 2 to 4 rings. Examples of a heteroatom included in the aromatic heterocyclic group include a nitrogen atom, an oxygen atom, and a sulfur atom. Among these, a nitrogen atom or an oxygen atom is preferable.

It is preferable that the aromatic group-containing polymer is at least one polymer selected from the group consisting of a polyethersulfone polymer, a polysulfone polymer, a polyether ketone polymer, a polyphenylene ether polymer, a polyimide polymer, a polybenzimidazole polymer, a polyphenylene polymer, a phenol resin polymer, a polycarbonate polymer, a polyamide polymer, and a polyester polymer. Examples of the respective polymers will be shown below.

Polyethersulfone polymer: a polymer having a main chain structure represented by (—O-Ph-SO₂-Ph) (Ph represents a phenylene group; hereinafter the same shall be applied)

Polysulfone polymer: a polymer having a main chain structure represented by (—O-Ph-Ph-O-Ph-SO₂-Ph-)

Polyether ketone polymer: a polymer having a main chain structure represented by (—O-Ph-O-Ph-C(═O)-Ph-)

Polyphenylene ether polymer: a polymer having a main chain structure represented by (-Ph-O—, -Ph-S—)

Polyphenylene polymer: a polymer having a main chain structure represented by (-Ph-)

Phenol resin polymer: a polymer having a main chain structure represented by (-Ph(OH)—CH₂—)

Polycarbonate polymer: a polymer having a main chain structure represented by (-Ph-O—C(═O)—O—)

Polyamide polymer: a polymer having a main chain structure represented by (-Ph-C(═O)—NH—)

Polyester polymer: a polymer having a main chain structure represented by (-Ph-C(═O)O—)

Examples of the polyethersulfone polymer, the polysulfone polymer, and the polyether ketone polymer can be found in the description of a main chain structure in paragraph “0022” of JP2006-310068A and paragraph “0028” of JP2008-27890A, the contents of which are incorporated herein by reference. Examples of the polyimide polymer can be found in the description of a main chain structure in paragraph “0047” to “0058” of JP2002-367627A and paragraphs “0018” and “0019” of JP2004-35891A, the contents of which are incorporated herein by reference.

For example, it is preferable that the aromatic group-containing polymer includes a repeating unit represented by the following Formula (B10-1)

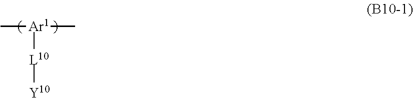

(In Formula (B10-1), Ar¹ represents an aromatic hydrocarbon group and/or an aromatic heterocyclic group, L¹⁰ represents a single bond or a divalent linking group, and Y¹⁰ represents a group having one or more selected from the group consisting of a coordination site coordinated to a copper component by an anion and a coordinating atom coordinated to a copper component by an unshared electron pair.)

In a case where Ar¹ in Formula (B10-1) represents an aromatic hydrocarbon group, the aromatic hydrocarbon group represented by Ar¹ has the same definition range and the same preferable range as the above-described aromatic hydrocarbon group. In a case where Ar¹ represents an aromatic heterocyclic group, the aromatic heterocyclic group represented by Ar¹ has the same definition range and the same preferable range as the above-described aromatic heterocyclic group. Ar¹ may have a substituent. Examples of the substituent include an alkyl group, a polymerizable group (preferably a polymerizable group having a carbon-carbon double bond), a halogen atom (a fluorine atom, a chlorine atom, a bromine atom, or an iodine atom), a carboxylate group, an alkyl halide group, an alkoxy group, a methacryloyloxy group, an acryloyloxy group, an ether group, a sulfonyl group, a sulfide group, an amido group, an acyl group, a hydroxyl group, a carboxyl group, and an aralkyl group. Among these, an alkyl group (preferably an alkyl group having 1 to 3 carbon atoms) is preferable.

It is preferable that L¹⁰ in Formula (B10-1) represents a single bond. In a case where L¹⁰ represents a divalent linking group, examples of the divalent linking group include the linking group described above regarding L¹ in Formula (B1-1), and a preferable range thereof is also the same.

Y¹⁰ in Formulae (B10-1) has the same definition and the same preferable range as Y¹ in Formula (B1-1).

The weight-average molecular weight of the polymer (B1) is preferably 2000 or higher, more preferably 2000 to 2000000, and still more preferably 6000 to 200000. By adjusting the weight-average molecular weight of the polymer (B1) to be in the above-described range, the heat resistance of the obtained film tends to be further improved.

(Polymer (B2))

As the polymer (B2), any polymer having a reactive site which is reactive with the functional group of the copper complex can be preferably used. It is preferable that the reactive site is present at a side chain of the polymer. Examples of a preferable combination of the reactive site of the polymer (B2) and the functional group of the copper complex and a bond formed from the reaction include the following (1) to (12). Among these, (1) to (6) are preferable. In the following formulae, the left side represents the reactive site of the polymer and the functional group of the copper complex, and the right side represents a bond that is obtained by causing them to react with each other. R represents a hydrogen atom or an alkyl group and may be bonded to the polymer main chain. X represents a halogen atom.

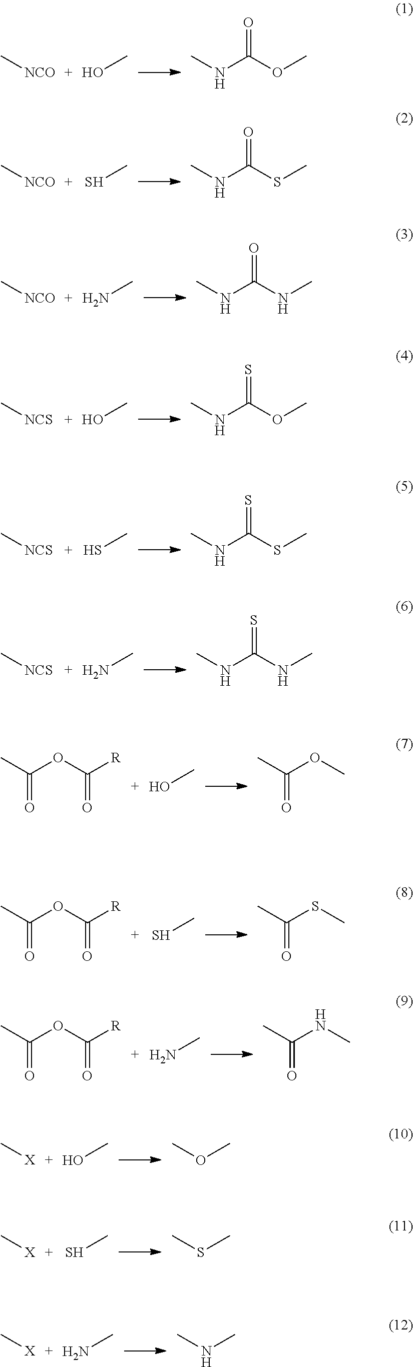

For example, in a case where R is bonded to the polymer main chain, (7) to (9) have the following structure.

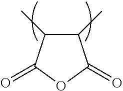

It is preferable that the polymer (B2) includes a repeating unit represented by the following Formula (B2-1).

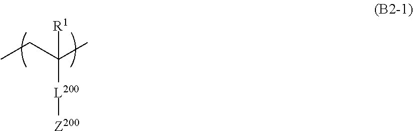

In the formula, R¹ represents a hydrogen atom or a hydrocarbon group, L²⁰⁰ represents a single bond or a linking group, and Z²⁰⁰ represents a reactive site.

R¹ represents a hydrogen atom or a hydrocarbon group. Examples of the hydrocarbon group include a linear, branched, or cyclic aliphatic hydrocarbon group and an aromatic hydrocarbon group. The hydrocarbon group may have a substituent but is preferably unsubstituted. The number of carbon atoms in the hydrocarbon group is preferably 1 to 10, more preferably 1 to 5, and still more preferably 1 to 3. In addition, the hydrocarbon group is preferably a methyl group. It is preferable that R¹ represents a hydrogen atom or a methyl group.

L²⁰⁰ represents a single bond or a linking group. Examples of the linking group represented by L² include a linking group having a combination including at least one selected from the group consisting of an alkylene group, an arylene group, a heteroarylene group, —O—, —S—, —CO—, —C(═O)O—, —SO₂—, and NR¹⁰ (R¹⁰ represents a hydrogen atom or an alkyl group and preferably a hydrogen atom).

Z²⁰⁰ represents a reactive site. The reactive site may be any site which is reactive with the functional group of the copper complex. Examples of the reactive site include —NCO, —NCS, —C(═O)OC(═O)—R, and a halogen atom. R represents a hydrogen atom or an alkyl group and may be bonded to the polymer main chain.

Examples of the repeating unit represented by Formula (B2-1) include repeating units represented by the following Formulae (B2-1-1) to (B2-1-3). The following formula (B2-1-1) is preferable.

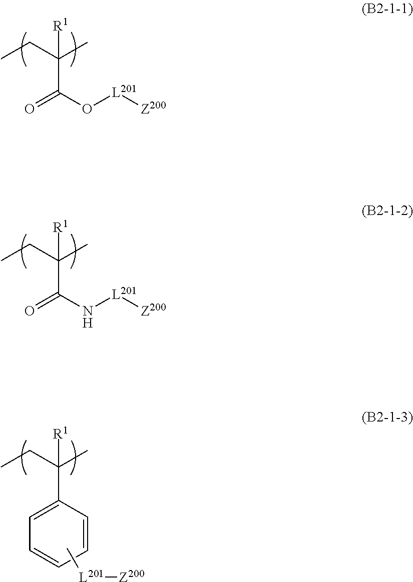

In the formula, R¹ represents a hydrogen atom or a hydrocarbon group, L²⁰¹ represents a single bond or a linking group, and Z²⁰⁰ represents a reactive site.

R¹ and Z²⁰⁰ in the formula have the same definitions and the preferable ranges as R¹ and Z²⁰⁰ in Formula (B2-1).

L²⁰¹ in the formula represents a single bond or a linking group. Examples of the linking group represented by L² include a linking group having a combination including at least one selected from the group consisting of an alkylene group, an arylene group, a heteroarylene group, —O—, —S—, —CO—, —C(═O)O—, —SO₂—, and NR¹⁰ (R¹⁰ represents a hydrogen atom or an alkyl group and preferably a hydrogen atom). An alkylene group is preferable.

The polymer (B2) may include other repeating units. Examples of the other repeating units include the other repeating unit described above regarding the colorant polymer (B1).

The weight-average molecular weight of the polymer (B2) is preferably 2000 or higher, more preferably 2000 to 2000000, and still more preferably 6000 to 200000. By adjusting the weight-average molecular weight of the polymer (B2) to be in the above-described range, the heat resistance of the obtained film tends to be further improved.

<<Other Infrared Absorbers>

The near infrared absorbing composition according to the present invention may include infrared absorber (also referred to as “other infrared absorbers”) other than the copper compound. In the present invention, the infrared absorbers refer to compounds which have absorption in an infrared wavelength range (preferably a wavelength range of 700 to 1200 nm) and allow transmission of light having a wavelength in a visible range (preferably a range of 400 to 650 nm). As the infrared absorbers, a compound having an absorption maximum in a range of 700 to 1200 nm is preferable, and a compound having an absorption maximum in a range of 700 to 1000 nm is more preferable.

Examples of the infrared absorbers include a cyanine compound, a pyrrolopyrrole compound, a squarylium compound, a phthalocyanine compound, a naphthalocyanine compound, a diimmonium compound, a thiol complex compound, a transition metal oxide compound, a quaterrylene compound, and a croconium compound. Among these, a cyanine compound, a pyrrolopyrrole compound, a squarylium compound, a phthalocyanine compound, a naphthalocyanine compound, or a diimmonium compound is preferable because a film having excellent infrared shielding properties and visible transparency can be easily formed.

Examples of the pyrrolopyrrole compound include a pyrrolopyrrole compound described in paragraphs “0016” to “0058” of JP2009-263614A. As the cyanine compound, the phthalocyanine compound, the diimmonium compound, the squarylium compound, or the croconium compound, for example, a compound described in paragraphs “0010” to “0081” of JP2010-111750A may be used, the content of which is incorporated herein by reference. In addition the cyanine compound can be found in, for example, “Functional Colorants by Makoto Okawara, Masaru Matsuoka, Teijiro Kitao, and Tsuneoka Hirashima, published by Kodansha Scientific Ltd.”, the content of which is incorporated herein by reference. In addition, the phthalocyanine compound can be found in the description of paragraphs “0013” to “0029” of JP2013-195480A, the content of which is incorporated herein by reference.

In a case where the near infrared absorbing composition according to the present invention includes the other infrared absorbers, the content of the other infrared absorbers is preferably 0.1 to 40 mass % with respect to the total solid content of the near infrared absorbing composition. The lower limit is preferably 0.5 mass % or higher and more preferably 1 mass % or higher.

<<Inorganic Particles>>

The near infrared absorbing composition according to the present invention may include inorganic particles. As the inorganic particles, one kind may be used alone, or two or more kinds may be used in combination.

The inorganic particles mainly function to shield (absorb) infrared light. As the inorganic particles, metal oxide particles or metal particles are preferable from the viewpoint of further improving infrared shielding properties.

Examples of the metal oxide particles include indium tin oxide (ITO) particles, antimony tin oxide (ATO) particles, zinc oxide (ZnO) particles, Al-doped zinc oxide (Al-doped ZnO) particles, fluorine-doped tin dioxide (F-doped SnO₂) particles, and niobium-doped titanium dioxide (Nb-doped TiO₂) particles.

Examples of the metal particles include silver (Ag) particles, gold (Au) particles, copper (Cu) particles, and nickel (Ni) particles. In order to simultaneously realize infrared shielding properties and photolithographic properties, it is preferable that the transmittance in an exposure wavelength range (365 to 405 nm) is high. From this point of view, indium tin oxide (ITO) particles or antimony tin oxide (ATO) particles are preferable.

The shape of the inorganic particles is not particularly limited and may have a sheet shape, a wire shape, or a tube shape irrespective of whether or not the shape is spherical or non-spherical.

In addition, as the inorganic particles, a tungsten oxide compound can be used. Specifically, a tungsten oxide compound represented by the following Formula (compositional formula) (I) is more preferable.

MₓW_{y}O_{z} (I)

M represents metal, W represents tungsten, and O represents oxygen.

0.001<x/y≤1.1

2.2≤z/y≤3.0

Examples of the metal represented by M include an alkali metal, an alkali earth metal, Mg, Zr, Cr, Mn, Fe, Ru, Co, Rh, Ir, Ni, Pd, Pt, Cu, Ag, Au, Zn, Cd, Al, Ga, In, Tl, Sn, Pb, Ti, Nb, V, Mo, Ta, Re, Be, Hf, Os, and Bi. Among these, an alkali metal is preferable, Rb or Cs is more preferable, and Cs is still more preferable. As the metal represented by M, one kind or two or more kinds may be used.

By adjusting x/y to be 0.001 or higher, infrared light can be sufficiently shielded. By adjusting x/y to be 1.1 or lower, production of an impurity phase in the tungsten oxide compound can be reliably avoided.

By adjusting z/y to be 2.2 or higher, chemical stability as a material can be further improved. By adjusting z/y to be 3.0 or lower, infrared light can be sufficiently shielded.

Specific examples of the tungsten oxide compound represented by Formula (I) include Cs_{0.33}WO₃, Rb_{0.33}WO₃, K_{0.33}WO₃, and Ba_{0.33}WO₃. Among these, Cs_{0.33}WO₃ or Rb_{0.33}WO₃ is preferable, and Cs_{0.33}WO₃ is more preferable.

The tungsten oxide compound is available in the form of, for example, a dispersion of tungsten particles such as YMF-02 (manufactured by Sumitomo Metal Mining Co., Ltd.).

The average particle size of the inorganic particles is preferably 800 nm or less, more preferably 400 nm or less, and still more preferably 200 nm or less. By adjusting the average particle size of the inorganic particles to be in the above-described range, transmittance in a visible range can be reliably improved. From the viewpoint of avoiding light scattering, the less the average particle size, the better. However, due to the reason of handleability during manufacturing or the like, the average particle size of the inorganic particle is typically 1 nm or more.

The content of the inorganic particles is preferably 0.01 to 30 mass % with respect to the total solid content of the near infrared absorbing composition. The lower limit is preferably 0.1 mass % or higher and more preferably 1 mass % or higher. The upper limit is preferably 20 mass % or lower, and more preferably 10 mass % or lower.

<<Solvent>>

It is preferable that the near infrared absorbing composition according to the present invention includes a solvent. The solvent is not particularly limited as long as the respective components can be uniformly dissolved or dispersed therein, and can be appropriately selected according to the purpose. For example, water or an organic solvent can be used.

Examples of the organic solvent include an alcohol, a ketone, an ester, an aromatic hydrocarbon, a halogenated hydrocarbon, dimethylformamide, dimethylacetamide, dimethyl sulfoxide, and sulfolane. Among these, one kind may be used alone, or two or more kinds may be used in combination.

Specific examples of the alcohol, the aromatic hydrocarbon, and the halogenated hydrocarbon can be found in, for example, paragraph “0136” of JP2012-194534A, the content of which is incorporated herein by reference.

Specific examples of the ester, the ketone, and the ether can be found in, for example, paragraph “0497” of JP2012-208494A (corresponding to paragraph “0609” of US2012/0235099A). Other examples include n-amyl acetate, ethyl propionate, dimethyl phthalate, ethyl benzoate, methyl sulfate, acetone, methyl isobutyl ketone, diethyl ether, and ethylene glycol monobutyl ether acetate.

As the solvent, at least one selected from the group consisting of 1-methoxy-2-propanol, cyclopentanone, cyclohexanone, propylene glycol monomethyl ether acetate, N-methyl-2-pyrrolidone, butyl acetate, ethyl lactate, and propylene glycol monomethyl ether is preferably used.

In the present invention, an solvent having a low metal content is preferable. For example, the metal content in the solvent is preferably 10 ppb or lower. Optionally, a solvent having a metal content at a ppt level may be used. For example, such a high-purity solvent is available from Toyo Gosei Co., Ltd.

Examples of a method of removing impurities such as metal from the solvent include distillation (for example, molecular distillation or thin-film distillation) and filtering using a filter. During the filtering using a filter, the pore size of a filter is preferably 10 nm or less, more preferably 5 nm or less, and still more preferably 3 nm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

The content of the solvent is preferably 5 to 60 mass % with respect to the total solid content of the near infrared absorbing composition according to the present invention. The lower limit is more preferably 10 mass % or higher. The upper limit is more preferably 40 mass % or lower. As the solvent, one kind or two or more kinds may be used. In a case where two or more solvents are used, it is preferable that the total content of the two or more solvents is in the above-described range.

<<Compound Having Crosslinking Group (Crosslinking Compound)>>

The near infrared absorbing composition according to the present invention may include a compound having a crosslinking group (hereinafter, also referred to as “crosslinking compound”) as a component other than the resin. By the near infrared absorbing composition according to the present invention including the crosslinking compound, a film having excellent heat resistance and solvent resistance can be manufactured. As the crosslinking compound, a well-known compound which is crosslinkable by a radical, an acid, or heat can be used. As the crosslinking compound, a compound which is crosslinkable by heat is preferable.

Examples of the crosslinking compound include a compound having a group having an ethylenically unsaturated bond, a cyclic ether group, a methylol group, or an alkoxysilyl group. Examples of the group having an ethylenically unsaturated bond include a vinyl group, a styryl group, a (meth)allyl group, and a (meth)acryloyl group. Among these, a (meth)allyl group or a (meth)acryloyl group is preferable. Examples of the cyclic ether group include an epoxy group and an oxetanyl group. Among these, an epoxy group is preferable. Examples of the alkoxysilyl group include a monoalkoxysilyl group, a dialkoxysilyl group, and a trialkoxysilyl group. Among these, a dialkoxysilyl group or a trialkoxysilyl group is preferable, and a trialkoxysilyl group is more preferable. As the crosslinking compound, a compound having a cyclic ether group or a compound having an alkoxysilyl group is preferable, and a compound having an alkoxysilyl group is more preferable.

The crosslinking compound may be in the form of a monomer or a polymer and is preferably a monomer.

(Compound which has Group Having Ethylenically Unsaturated Bond)

In the present invention, as the crosslinking compound, a compound which has a group having an ethylenically unsaturated bond can be used. It is preferable that the compound which has a group having an ethylenically unsaturated bond is a monomer. The molecular weight of the compound is preferably 100 to 3000. The upper limit is preferably 2000 or lower and more preferably 1500 or lower. The lower limit is preferably 150 or higher and more preferably 250 or higher. The compound is preferably a (meth)acrylate compound having 3 to 15 functional groups and more preferably a (meth)acrylate compound having 3 to 6 functional groups.

Examples of the compound which has a group having an ethylenically unsaturated bond can be found in paragraphs “0033” and “0034” of JP2013-253224A, the content of which is incorporated herein by reference. As the compound which has a group having an ethylenically unsaturated bond, ethyleneoxy-modified pentaerythritol tetraacrylate (as a commercially available product, NK ESTER ATM-35E manufactured by Shin-Nakamura Chemical Co., Ltd.), dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.), or a structure in which the (meth)acryloyl group is bonded through an ethylene glycol or a propylene glycol residue is preferable. In addition, oligomers of the above-described examples can be used. In addition, the compound having an ethylenically unsaturated bond can be found in the description of a polymerizable compound in paragraphs “0034” to “0038” of JP2013-253224A, the content of which is incorporated herein by reference. Examples of the compound having an ethylenically unsaturated bond include a polymerizable monomer in paragraph “0477” of JP2012-208494A (corresponding to paragraph “0585” of US2012/0235099A), the content of which is incorporated herein by reference.

In addition, diglycerin ethylene oxide (EO)-modified (meth)acrylate (as a commercially available product, M-460 manufactured by Toagosei Co., Ltd.) is preferable. Pentaerythritol tetraacrylate (A-TMMT manufactured by Shin-Nakamura Chemical Co., Ltd.) or 1,6-hexanediol diacrylate (KAYARAD HDDA manufactured by Nippon Kayaku Co., Ltd.) is also preferable. Oligomers of the above-described examples can be used. For examples, RP-1040 (manufactured by Nippon Kayaku Co., Ltd.) is used.

The compound which has a group having an ethylenically unsaturated bond may have an acid group such as a carboxyl group, a sulfo group, or a phosphate group. Examples of the compound having an acid group include an ester of an aliphatic polyhydroxy compound and an unsaturated carboxylic acid. A compound having an acid group obtained by causing a nonaromatic carboxylic anhydride to react with an unreacted hydroxyl group of an aliphatic polyhydroxy compound is preferable. In particular, it is more preferable that, in this ester, the aliphatic polyhydroxy compound is pentaerythritol and/or dipentaerythritol. Examples of a commercially available product of the monomer having an acid group include M-305, M-510, and M-520 of ARONIX series as polybasic acid-modified acrylic oligomer (manufactured by Toagosei Co., Ltd.). The acid value of the compound having an acid group is preferably 0.1 to 40 mgKOH/g. The lower limit is preferably 5 mgKOH/g or higher. The upper limit is preferably 30 mgKOH/g or lower.

In addition, a compound having a caprolactone structure is also preferable as the compound which has a group having an ethylenically unsaturated bond. The compound having a caprolactone structure is not particularly limited as long as it has a caprolactone structure in the molecule thereof, and examples thereof include ε-caprolactone-modified polyfunctional (meth)acrylate obtained by esterification of a polyhydric alcohol, (meth)acrylic acid, and ε-caprolactone, the polyhydric alcohol being, for example, trimethylolethane, ditrimethylolethane, trimethylolpropane, ditrimethylolpropane, pentaerythritol, dipentaerythritol, tripentaerythritol, glycerin, diglycerol, or trimethylolmelamine. Examples of the compound having a caprolactone structure can be found in paragraphs “0042” to “0045” of JP2013-253224A, the content of which is incorporated herein by reference. Examples of the compound having a caprolactone structure include: DPCA-20, DPCA-30, DPCA-60, and DPCA-120 which are commercially available as KAYARADDPCA series manufactured by Nippon Kayaku Co., Ltd.; SR-494 (manufactured by Sartomer) which is a tetrafunctional acrylate having four ethyleneoxy chains; and TPA-330 (manufactured by Nippon Kayaku Co., Ltd.) which is a trifunctional acrylate having three isobutyleneoxy chains.

As the compound which has a group having an ethylenically unsaturated bond, a urethane acrylate described in JP1973-41708B (JP-S48-41708B), JP1976-37193A (JP-S51-37193A), JP1990-32293B (JP-H2-32293B), or JP1990-16765B (JP-H2-16765B), or a urethane compound having a ethylene oxide skeleton described in JP1983-49860B (JP-S58-49860B), JP1981-17654B (JP-S56-17654B), JP1987-39417B (JP-S62-39417B), or JP1987-39418B (JP-S62-39418B) is also preferable. In addition, a curable coloring composition having an excellent film speed can be obtained by using an addition-polymerizable compound having an amino structure or a sulfide structure in the molecules described in JP1988-277653A (JP-S63-277653A), JP1988-260909A (JP-S63-260909A), or JP1989-105238A (JP-H1-105238A).

Examples of a commercially available product of the polymerizable compound include URETHANE OLIGOMER UAS-10 and UAB-140 (manufactured by Sanyo-Kokusaku Pulp Co., Ltd.), UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600 and AI-600 (manufactured by Kyoeisha Chemical Co., Ltd.).

In the present invention, as the compound which has a group having an ethylenically unsaturated bond, a polymer which has a group having an ethylenically unsaturated bond at a side chain can be used. The content of a repeating unit which has a group having an ethylenically unsaturated bond at a side chain is preferably 5 to 100 mass % with respect to all the repeating units constituting the polymer. The lower limit is preferably 10 mass % or higher and more preferably 15 mass % or higher. The upper limit is preferably 90 mass % or lower, more preferably 80 mass % or lower, and still more preferably 70 mass % or lower.

The polymer may include other repeating units in addition to the repeating unit which has a group having an ethylenically unsaturated bond at a side chain. The other repeating units may have a functional group such as an acid group. The other repeating units may not have a functional group. Examples of the acid group include a carboxyl group, a sulfonate group, and a phosphate group. As the acid group, one kind may be used, or two or more kinds may be used. The proportion of the repeating unit having an acid group is preferably 0 to 50 mass % with respect to all the repeating units constituting the polymer. The lower limit is preferably 1 mass % or higher and more preferably 3 mass % or higher. The upper limit is more preferably 35 mass % or lower, and still more preferably 30 mass % or lower.

Specific examples of the polymer include a copolymer including (meth)allyl (meth)acrylate and (meth)acrylic acid. Examples of a commercially available product of the polymer include DIANAL NR series (manufactured by Mitsubishi Rayon Co., Ltd.), PHOTOMER 6173 (a COOH-containing polyurethane acrylic oligomer; manufactured by Diamond Shamrock Co., Ltd.), BISCOAT R-264 and KS Resist 106 (both of which are manufactured by Osaka Organic Chemical Industry Ltd.), CYCLOMER-P series (for example, ACA230AA) and PLAKCEL CF200 series (both of which manufactured by Daicel Corporation), EBECRYL 3800 (manufactured by Daicel-UCB Co., Ltd.), and ACRYCURE RD-F8 (manufactured by Nippon Shokubai Co., Ltd.).

(Compound Having Cyclic Ether Group)

In the present invention, as the crosslinking compound, a compound having a cyclic ether group can also be used. Examples of the cyclic ether group include an epoxy group and an oxetanyl group. Among these, an epoxy group is preferable.

Examples of the compound having a cyclic ether group include a polymer having a cyclic ether group at a side chain and a monomer or an oligomer having two or more cyclic ether groups in a molecule. Examples of the compound include a bisphenol A epoxy resin, a bisphenol F epoxy resin, a phenol novolac epoxy resin, a cresol novolac epoxy resin, and an aliphatic epoxy resin. In addition, a monofunctional or polyfunctional glycidyl ether compound can also be used, and a polyfunctional aliphatic glycidyl ether compound is preferable.

The weight-average molecular weight of the compound having a cyclic ether group is preferably 500 to 5000000 and more preferably 1000 to 500000. As the compound, a commercially available product may be used, or a compound obtained by introducing an epoxy group into a side chain of the polymer may be used.

Examples of a commercially available product of the compound having a cyclic ether group can be found in, for example, paragraph “0191” JP2012-155288A, the content of which is incorporated herein by reference.

In addition, a polyfunctional aliphatic glycidyl ether compound such as DENACOL EX-212L, EX-214L, EX-216L, EX-321L, or EX-850L (all of which are manufactured by Nagase ChemteX Corporation) can be used. The above-described examples are low-chlorine products, but a commercially available product which is not a low-chlorine product such as EX-212, EX-214, EX-216, EX-321, or EX-850 can also be used.

Other examples include: ADEKA RESIN EP-4000S, EP-4003S, EP-4010S, and EP-4011S (all of which are manufactured by Adeka Corporation); NC-2000, NC-3000, NC-7300, XD-1000, EPPN-501, and EPPN-502 (all of which are manufactured by Adeka Corporation); JER1031S, CELLOXIDE 2021P, CELLOXIDE 2081, CELLOXIDE 2083, CELLOXIDE 2085, EHPE 3150, EPOLEAD PB 3600, and EPOLEAD PB 4700 (all of which are manufactured by Daicel Corporation); and CYCLOMER P ACA 200M, CYCLOMER P ACA 230AA, CYCLOMER P ACA Z250, CYCLOMER P ACA Z251, CYCLOMER P ACA Z300, and CYCLOMER P ACA Z320 (all of which are manufactured by Daicel Corporation).

Further, examples of a commercially available product of the phenol novolac epoxy resin include JER-157S65, JER-152, JER-154, and JER-157S70 (all of which are manufactured by Mitsubishi Chemical Corporation).

In addition, specific examples of a polymer having an oxetanyl group at a side chain and a polymerizable monomer or an oligomer having two or more oxetanyl groups in a molecule ARONE OXETANE OXT-121, OXT-221, OX-SQ, and PNOX (all of which are manufactured by Toagosei Co., Ltd.).

As the compound having an epoxy group, an unsaturated compound having a glycidyl group such as glycidyl (meth)acrylate or allyl glycidyl ether as an epoxy group can be used, and an unsaturated compound having an alicyclic epoxy group is preferable. Examples of the compound having an epoxy group can be found in, for example, paragraph “0045” of JP2009-265518A, the content of which is incorporated herein by reference.

The compound having a cyclic ether group may include a polymer having an epoxy group or an oxetanyl group as a repeating unit.

(Compound Having Alkoxysilyl Group)

In the present invention, as the crosslinking compound, a compound having an alkoxysilyl group can also be used. The number of carbon atoms in the alkoxy group of the alkoxysilyl group is preferably 1 to 5, more preferably 1 to 3, and still more preferably 1 or 2. It is preferable that two or more alkoxysilyl groups are present in one molecule, and it is more preferable that two or three alkoxysilyl groups are present in one molecule. Specific examples of the compound having an alkoxysilyl group include methyl trimethoxysilane, dimethyl dimethoxysilane, phenyl trimethoxysilane, methyltriethoxysilane, and dimethyl diethoxysilane, phenyltriethoxysilane, n-propyltrimethoxysilane, n-propyltriethoxysilane, hexyl trimethoxysilane, hexyl triethoxysilane, octyl triethoxysilane, decyl trimethoxysilane, 1,6-bis(trimethoxysilyl)hexane, trifluoropropyltrimethoxysilane, hexamethyldisilazane, vinyl trimethoxysilane, vinyltriethoxysilane, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, N-(vinylbenzyl)-2-aminoethyl-3-aminopropyltrimethoxysilane, tris-(3-trimethoxysilylpropyl)isocyanurate, 3-ureidopropyltriethoxysilane, 3-mercaptopropylmethyldimethoxysilane, 3-mercaptopropyltrimethoxysilane, and bis(triethoxysilylpropyl)tetrasulfide, and 3-isocyanatepropyltriethoxysilane. In addition, the following compounds can also be used.

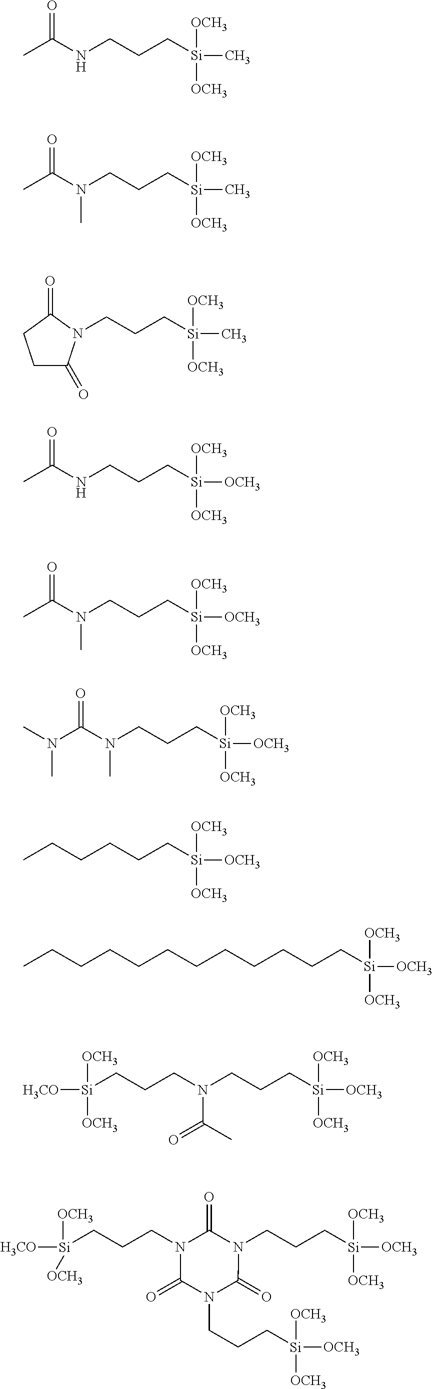

Examples of a commercially available product of the silane coupling agent include KBM-13, KBM-22, KBM-103, KBE-13, KBE-22, KBE-103, KBM-3033, KBE-3033, KBM-3063, KBM-3066, KBM-3086, KBE-3063, KBE-3083, KBM-3103, KBM-3066, KBM-7103, SZ-31, KPN-3504, KBM-1003, KBE-1003, KBM-303, KBM-402, KBM-403, KBE-402, KBE-403, KBM-1403, KBM-502, KBM-503, KBE-502, KBE-503, KBM-5103, KBM-602, KBM-603, KBM-903, KBE-903, KBE-9103, KBM-573, KBM-575, KBM-9659, KBE-585, KBM-802, KBM-803, KBE-846, KBE-9007, X-40-1053, X-41-1059A, X-41-1056, X-41-1805, X-41-1818, X-41-1810, X-40-2651, X-40-2655A, KR-513, KC-89S, KR-500, X-40-9225, X-40-9246, X-40-9250, KR-401N, X-40-9227, X-40-9247, KR-510, KR-9218, KR-213, X-40-2308, and X-40-9238 (all of which are manufactured by Shin-Etsu Chemical Co., Ltd.).

In addition, as the compound having an alkoxysilyl group, a polymer having an alkoxysilyl group or a chlorosilyl group at a side chain can also be used.

In a case where the near infrared absorbing composition according to the present invention includes a crosslinking compound, the content of the crosslinking compound is preferably 1 to 90 mass % with respect to the total solid content of the near infrared absorbing composition. The lower limit is preferably 5 mass % or higher, more preferably 10 mass % or higher, and still more preferably 20 mass % or higher. The upper limit is preferably 80 mass % or lower, and more preferably 75 mass % or lower. As the crosslinking compound, one kind may be used alone, or two or more kinds may be used. In a case where two or more crosslinking compounds are used in combination, it is preferable that the total content of the two or more crosslinking compounds is in the above-described range.

The near infrared absorbing composition according to the present invention may not substantially include the crosslinking compound. “Substantially not including the crosslinking compound” represents that the content of the crosslinking compound is preferably 0.5 mass % or lower, more preferably 0.1 mass % or lower, and still more preferably 0% with respect to the total solid content of the near infrared absorbing composition.

<<Catalyst>>

The near infrared absorbing composition according to the present invention may include a catalyst. By the near infrared absorbing composition including the catalyst, a film having high solvent resistance and heat resistance can be easily obtained. In addition, for example, in a case where a resin having a repeating unit having an alkoxysilyl group is used, or in a case where the compound having an alkoxysilyl group is used as the crosslinking compound, by the near infrared absorbing composition including the catalyst, crosslinking of the alkoxysilyl group is promoted, and a film having higher solvent resistance and heat resistance can be easily obtained.

Examples of the catalyst include an organic metal catalyst, an acid catalyst, and an amine catalyst. Among these, an organic metal catalyst is preferable. In the present invention, it is preferable that the organic metal catalyst is at least one selected from the group consisting of an oxide, a sulfide, a halide, a carbonate, a carboxylate, a sulfonate, a phosphate, a nitrate, a sulfate, an alkoxide, a hydroxide, and an acetylacetonato complex which may have a substituent, the at least one including at least one metal selected from the group consisting of Na, K, Ca, Mg, Ti, Zr, Al, Zn, Sn, and Bi. Among these, at least one selected from the group consisting of a halide of the metal, a carboxylate of the metal, a nitrate of the metal, a sulfate of the metal, a hydroxide of the metal, and an acetylacetonato complex of the metal which may have a substituent is preferable, and an acetylacetonato complex of the metal is more preferable. In particular, an acetylacetonato complex of Al is preferable. Specific examples of the organic metal catalyst include aluminum tris(2,4-pentanedionate).

In a case where the near infrared absorbing composition according to the present invention includes the catalyst, the content of the catalyst is preferably 0.01 to 5 mass % with respect to the total solid content of the near infrared absorbing composition. The upper limit is more preferably 3 mass % or lower, and still more preferably 1 mass % or lower. The lower limit is more preferably 0.05 mass % or higher.

<<Other Resins>>

The near infrared absorbing composition according to the present invention may include resins (hereinafter, also referred to as “other resins”) other than the resin A, the copper compound, and the crosslinking compound. Examples of the other resins include a resin having an acid group. The details of the resin having an acid group can be found in paragraphs “0558” to “0571” of JP2012-208494A (corresponding to paragraphs “0685” to “0700” of US2012/0235099A), the content of which is incorporated herein by reference.

In a case where the near infrared absorbing composition according to the present invention includes the other resins, the content of the other resins is preferably 1 to 80 mass % with respect to the total solid content of the near infrared absorbing composition. The lower limit is preferably 5 mass % or higher and more preferably 7 mass % or higher. The upper limit is preferably 50 mass % or lower, and more preferably 30 mass % or lower.

<<Surfactant>>

The near infrared absorbing composition according to the present invention may include a surfactant. Among these surfactants, one kind may be used alone, or two or more kinds may be used in combination. The content of the surfactant is preferably 0.0001 to 5 mass % with respect to the total solid content of the near infrared absorbing composition. The lower limit is preferably 0.005 mass % or higher and more preferably 0.01 mass % or higher. The upper limit is preferably 2 mass % or lower, and more preferably 1 mass % or lower.

As the surfactants, various surfactants such as a fluorine surfactant, a nonionic surfactant, a cationic surfactant, an anionic surfactant, or a silicone surfactant can be used. It is preferable that the near infrared absorbing composition includes at least one of a fluorine surfactant or a silicone surfactant. The interfacial tension between a coated surface and a coating solution decreases, and the wettability on the coated surface is improved. Therefore, liquid properties (in particular, fluidity) of the composition are improved, and uniformity in coating thickness and liquid saving properties can be further improved. As a result, even in a case where a thin film having a thickness of several micrometers is formed using a small amount of the coating solution, a film having a uniform thickness with reduced unevenness in thickness can be formed.

The fluorine content in the fluorine surfactant is preferably 3 to 40 mass %. The lower limit is preferably 5 mass % or higher and more preferably 7 mass % or higher. The upper limit is more preferably 30 mass % or lower, and still more preferably 25 mass % or lower. In a case where the fluorine content is in the above-described range, there are advantageous effects in the uniformity in the thickness of the coating film and liquid saving properties, and the solubility is also excellent.

Examples of the fluorine surfactant include a surfactant described in paragraphs “0060” to “0064” of JP2014-41318A (paragraphs “0060” to “0064” of corresponding WO2014/17669), the content of which is incorporated herein by reference. Examples of a commercially available product of the fluorine surfactant include: MEGAFAC F-171, F-172, F-173, F-176, F-177, F-141, F-142, F-143, F-144, R³⁰, F-437, F-475, F-479, F-482, F-554, and F-780 (all of which are manufactured by DIC Corporation); FLUORAD FC430, FC431, and FC171 (all of which are manufactured by Sumitomo 3M Ltd.); and SURFLON S-382, SC-101, SC-103, SC-104, SC-105, SC1068, SC-381, SC-383, S393, and KH-40 (all of which are manufactured by Asahi Glass Co., Ltd.).

As the fluorine surfactant, a compound described in paragraphs “0015” to “0158” of JP2015-117327A can also be used.

As the fluorine surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

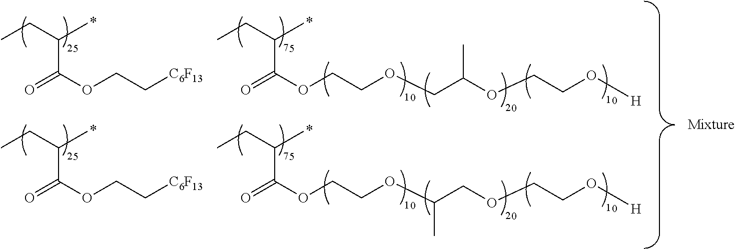

The weight-average molecular weight of the compound is preferably 3000 to 50000 and, for example, 14000.

In addition, a fluorine-containing polymer having an ethylenically unsaturated group at a side chain can also be preferably used as the fluorine surfactant. Specific examples include compounds described in paragraphs “0050” of “0090” and paragraphs “0289” to “0295” of JP2010-164965A, for example, MEGAFACE RS-101, RS-102, RS-718K, and RS-72K manufactured by DIC Corporation.

Specific examples of the nonionic surfactant include nonionic surfactants described in paragraph “0553” of JP2012-208494A (corresponding to paragraph “0679” of US2012/0235099A), the content of which is incorporated herein by reference.

Specific examples of the cationic surfactant include cationic surfactants described in paragraph “0554” of JP2012-208494A (corresponding to paragraph “0680” of US2012/0235099A), the content of which is incorporated herein by reference.

Specific examples of the anionic surfactant include W004, W005, and W017 (manufactured by Yusho Co., Ltd.).

Specific examples of the silicone surfactant include silicone surfactants described in paragraph “0556” of JP2012-208494A (corresponding to paragraph “0682” of US2012/0235099A), the content of which is incorporated herein by reference.

<<Other Components>>

Examples of other components which can be used in combination with the near infrared absorbing composition according to the present invention include a dispersant, a sensitizer, a curing accelerator, a filler, a thermal curing accelerator, a thermal polymerization inhibitor, a polymerization initiator, and a plasticizer. Further, an accelerator for accelerating adhesion to a substrate surface and other auxiliary agents (for example, conductive particles, a filler, an antifoaming agent, a flame retardant, a leveling agent, a peeling accelerator, an antioxidant, an aromatic chemical, a surface tension adjuster, or a chain transfer agent) may be used in combination. By the near infrared absorbing composition appropriately including the components, properties of a desired near infrared cut filter such as stability or film properties can be adjusted. The details of the components can be found in, for example, paragraph “0183” of JP2012-003225A (corresponding to “0237” of US2013/0034812A) and paragraphs “0101” to “0104” and “0107” to “0109” of JP2008-250074A, the content of which is incorporated herein by reference. In addition, examples of the antioxidant include a phenol compound, a phosphite compound, and a thioether compound. A phenol compound having a molecular weight of 500 or higher, a phosphite compound having a molecular weight of 500 or higher, or a thioether compound having a molecular weight of 500 or higher is more preferable. Among these compounds, a mixture of two or more kinds may be used. As the phenol compound, an arbitrary phenol compound which is known as a phenol antioxidant can be used. As the phenol compound, for example, a hindered phenol compound is preferable. In particular, a compound having a substituent at a position (ortho position) adjacent to a phenolic hydroxyl group is preferable. As the substituent, a substituted or unsubstituted alkyl group having 1 to 22 carbon atoms is preferable, and a methyl group, an ethyl group, a propionyl group, an isopropionyl group, a butyl group, an isobutyl group, a t-butyl group, a pentyl group, an isopentyl group, a t-pentyl group, a hexyl group, an octyl group, an isooctyl group, or a 2-ethylhexyl group is more preferable. In addition, a compound (antioxidant) having a phenol group and a phosphite group in the same molecule is also preferable. In addition, as the antioxidant, a phosphorus-based antioxidant can also be preferably used. Examples of the phosphorus-based antioxidant include at least one compound selected from the group consisting of tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-t-butyldibenzo[d,f][1,3,2]dioxaphosphepin-2-yl)oxy]ethyl]amine, and ethyl bis(2,4-di-t-butyl-6-methylphenyl)phosphite. The phosphorus-based antioxidant is easily commercially available, and examples of the commercially available product include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G, ADEKA STAB AO-80, and ADEKA STAB AO-330 (all of which are manufactured by Adeka Corporation). The content of the antioxidant is preferably 0.01 to 20 mass % and more preferably 0.3 to 15 mass % with respect to the mass of the total solid content of the composition. As the antioxidant, one kind may be used alone, or two or more kinds may be used. In a case where two or more antioxidants are used in combination, it is preferable that the total content of the two or more antioxidants is in the above-described range.

<Preferable Aspects of Near Infrared Absorbing Composition>

Examples of a preferable aspect of the near infrared absorbing composition according to the present invention include the following aspects.

(1) An aspect in which the copper compound is a copper complex which includes a compound having a carbon atom bonded to a hydrogen atom as a ligand, the resin A is a resin including a repeating unit represented by Formula (A) (preferably a repeating unit represented by Formula (A1-1), and more preferably at least one repeating unit selected from the group consisting of repeating units represented by the following Formulae (A1-2) to (A1-4)), and the radical trapping agent is an oxime compound (preferably an oxime ester compound)

(2) An aspect in which the resin A includes a repeating unit having a crosslinking group (preferably an alkoxysilyl group) in the aspect (1)

(3) An aspect in which the resin A includes a repeating unit represented by Formula (A) and a repeating unit having a crosslinking group (preferably an alkoxysilyl group) in the aspect (1)

(4) An aspect in which the near infrared absorbing composition further includes a compound (crosslinking compound) having a crosslinking group (preferably an alkoxysilyl group) as a component other than the resin A in the aspect (1)

(5) An aspect in which the radical trapping agent is the compound represented by (I) in any one of the aspects (1) to (4)

(6) An aspect in which the copper compound is a copper complex which includes a compound having at least two coordination sites as a ligand in any one of the aspects (1) to (5)

<Preparation and Use of Near Infrared Absorbing Composition>

The near infrared absorbing composition according to the present invention can be prepared by mixing the above-described components with each other.

During the preparation of the composition, the respective components constituting the composition may be mixed with each other collectively, or may be mixed with each other sequentially after dissolved and/or dispersed in a solvent. In addition, during mixing, the order of addition or working conditions are not particularly limited.

It is preferable that the near infrared absorbing composition according to the present invention is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (having a high density and an ultrahigh molecular weight) such as polyethylene or polypropylene (PP). Among these materials, polypropylene (including high-density polypropylene) or nylon is preferable.

The pore size of the filter is suitably about 0.01 to 7.0 μm and is preferably about 0.01 to 3.0 μm and more preferably about 0.05 to 0.5 μm. In the above-described range, fine foreign matter can be reliably removed. In addition, a fibrous filter material is also preferably used, and examples of the filter material include polypropylene fiber, nylon fiber, and glass fiber. Specifically, a filter cartridge of SBP type series (manufactured by Roki Techno Co., Ltd.; for example, SBP008), TPR type series (for example, TPR002 or TPR005), SHPX type series (for example, SHPX003), or the like can be used.

In a filter is used, a combination of different filters may be used. At this time, the filtering using a first filter may be performed once, or twice or more.

In addition, a combination of first filters having different pore sizes in the above-described range may be used. Here, the pore size of the filter can refer to a nominal value of a manufacturer of the filter. A commercially available filter can be selected from various filters manufactured by Pall Corporation, Toyo Roshi Kaisha, Ltd., Entegris Japan Co., Ltd. (former Mykrolis Corporation), or Kits Microfilter Corporation.

A second filter may be formed of the same material as that of the first filter. The pore diameter of the second filter is preferably 0.2 to 10.0 μm, more preferably 0.2 to 7.0 μm, and still more preferably 0.3 to 6.0 μm. In the above-described range, foreign matter can be removed while allowing the component particles included in the composition to remain.

The near infrared absorbing composition according to the present invention can be made liquid. Therefore, a near infrared cut filter can be easily manufactured, for example, by applying the near infrared absorbing composition according to the present invention to a substrate or the like and drying the near infrared absorbing composition.

In a case where the near infrared cut filter is formed by applying the near infrared absorbing composition according to the present invention, the viscosity of the near infrared absorbing composition is preferably 1 to 3000 mPa·s. The lower limit is preferably 10 mPa·s or higher and more preferably 100 mPa·s or higher. The upper limit is preferably 2000 mPa s or lower and more preferably 1500 mPa·s or lower.

The total solid content of the near infrared absorbing composition according to the present invention changes depending on a coating method and, for example, is preferably 1 to 50 mass %. The lower limit is more preferably 10 mass % or higher. The upper limit is more preferably 30 mass % or lower.

The use of the near infrared absorbing composition according to the present invention is not particularly limited. The near infrared absorbing composition can be preferably used for forming a near infrared cut filter or the like. For example, the near infrared absorbing composition can be preferably used, for example, for a near infrared cut filter (for example, a near infrared cut filter for a wafer level lens) on a light receiving side of a solid image pickup element or as a near infrared cut filter on a back surface side (opposite to the light receiving side) of a solid image pickup element In particular, the near infrared absorbing composition can be preferably used as a near infrared cut filter on a light receiving side of a solid image pickup element.

In addition, with the near infrared absorbing composition according to the present invention, a near infrared cut filter can be obtained in which heat resistance is high and high infrared shielding properties can be realized while maintaining a high transmittance in a visible range. Further, the thickness of the near infrared cut filter can be reduced, which contributes to a reduction in the height of a camera module or an image display device.

<Film, Near Infrared Cut Filter>

Next, a film according to the present invention will be described. The film according to the present invention is formed using the above-described near infrared absorbing composition according to the present invention. The film according to the present invention can be preferably used as a near infrared cut filter.

In addition, the near infrared cut filter according to the present invention is formed using the above-described near infrared absorbing composition according to the present invention.

It is preferable that the light transmittance of the near infrared cut filter according to the present invention satisfies at least one of the following (1) to (9), it is more preferable that the light transmittance of the near infrared cut filter according to the present invention satisfies all the following (1) to (9), and it is still more preferable that the light transmittance of the near infrared cut filter according to the present invention satisfies all the following (1) to (9).

(1) A light transmittance at a wavelength of 400 nm is preferably 80% or higher, more preferably 90% or higher, still more preferably 92% or higher, and even still more preferably 95% or higher

(2) A light transmittance at a wavelength of 450 nm is preferably 80% or higher, more preferably 90% or higher, still more preferably 92% or higher, and even still more preferably 95% or higher

(3) A light transmittance at a wavelength of 500 nm is preferably 80% or higher, more preferably 90% or higher, still more preferably 92% or higher, and even still more preferably 95% or higher

(4) A light transmittance at a wavelength of 550 nm is preferably 80% or higher, more preferably 90% or higher, still more preferably 92% or higher, and even still more preferably 95% or higher

(5) A light transmittance at a wavelength of 700 nm is preferably 20% or lower, more preferably 15% or lower, still more preferably 10% or lower, and even still more preferably 5% or lower

(6) A light transmittance at a wavelength of 750 nm is preferably 20% or lower, more preferably 15% or lower, still more preferably 10% or lower, and even still more preferably 5% or lower

(7) A light transmittance at a wavelength of 800 nm is preferably 20% or lower, more preferably 15% or lower, still more preferably 10% or lower, and even still more preferably 5% or lower

(8) A light transmittance at a wavelength of 850 nm is preferably 20% or lower, more preferably 15% or lower, still more preferably 10% or lower, and even still more preferably 5% or lower

(9) A light transmittance at a wavelength of 900 nm is preferably 20% or lower, more preferably 15% or lower, still more preferably 10% or lower, and even still more preferably 5% or lower

A light transmittance of the film and the near infrared cut filter according to the present invention in a wavelength range of 400 to 550 nm is preferably 85% or higher, more preferably 90% or higher, and still more preferably 95% or higher. The higher the transmittance in a visible range, the better. It is preferable that the transmittance in a wavelength range of 400 to 550 nm is high. In addition, it is preferable that a light transmittance at one point in a wavelength range of 700 to 800 nm is 20% or lower, and it is more preferable that a light transmittance in the entire wavelength range of 700 to 800 nm is 20% or lower.

The thickness of the near infrared cut filter can be appropriately selected according to the purpose. For example, the thickness is preferably 500 μm or less, more preferably 300 μm or less, still more preferably 250 μm or less, and even still more preferably 200 μm or less. For example, the lower limit of the thickness is preferably 0.1 μm or more, more preferably 0.2 μm or more, and still more preferably 0.5 μm or more.

In the film and the near infrared cut filter according to the present invention, a change rate of an absorbance at a wavelength of 400 nm measured before and after heating at 200° C. for 5 minute is preferably 6% or lower and more preferably 3% or lower, the change rate being expressed by the following expression. In addition, a change rate of an absorbance at a wavelength of 800 nm measured before and after heating at 200° C. for 5 minute is preferably 6% or lower and more preferably 3% or lower, the change rate being expressed by the following expression. In a case where the change rate of the absorbance is in the above-described range, a near infrared cut filter having excellent heat resistance in which discoloration caused by heating is suppressed can be obtained.

Change Rate (%) of Absorbance at Wavelength of 400 nm=|(Absorbance at Wavelength of 400 nm before Test-Absorbance at Wavelength of 400 nm after Test)/Absorbance at Wavelength of 400 nm before Test|×100(%)

Change Rate (%) of Absorbance at Wavelength of 800 nm=|(Absorbance at Wavelength of 800 nm before Test-Absorbance at Wavelength of 800 nm after Test)/Absorbance at Wavelength of 800 nm before Test|×100(%)

The near infrared cut filter may further include an ultraviolet-infrared reflection film or an ultraviolet absorbing layer in addition to the film according to the present invention. By the near infrared cut filter including the ultraviolet-infrared reflection film, an effect of improving incidence angle dependency can be obtained. The details of the ultraviolet-infrared reflection film can be found in the description of a reflecting layer described in paragraphs “0033” to “0039” of JP2013-68688A and paragraphs “0110” to “0114” of WO2015/099060, the contents of which are incorporated herein by reference. By including the ultraviolet absorbing layer, a near infrared cut filter having excellent ultraviolet shielding properties can be obtained. The details of the ultraviolet absorbing layer can be found in the description of an absorbing layer described in paragraphs “0040” to “0070” and paragraphs “0119” of “0145” of WO2015/099060.

The film and the near infrared cut filter according to the present invention can be used, for example, as a lens that has an ability to absorb and cut near infrared light (a camera lens for a digital camera, a mobile phone, or a vehicle-mounted camera, or an optical lens such as an a f-θ lens or a pickup lens), an optical filter for a semiconductor light receiving element, a near infrared absorbing film or a near infrared absorbing plate that shields heat rays for power saving, an agricultural coating agent for selective use of sunlight, a recording medium using heat absorbed from near infrared light, a near infrared light for an electronic apparatus or a picture, an eye protector, sunglasses, a heat ray shielding film, a filter for reading and recording an optical character, a filter for preventing classified documents from being copied, an electrophotographic photoreceptor, or a filter for laser welding. In addition, the near infrared cut filter according to the present invention is also useful as a noise cut filter for a CCD camera or a filter for a CMOS image sensor.

<Method of Manufacturing Near Infrared Cut Filter>

The near infrared cut filter according to the present invention can be manufactured using the above-described near infrared absorbing composition according to the present invention. Specifically, the near infrared cut filter can be manufactured through the following steps including: a step of applying the near infrared absorbing composition according to the present invention to a support or the like to form a near infrared absorbing composition layer; and a step of drying the near infrared absorbing composition layer. The thickness and a laminate structure are not particularly limited and can be appropriately selected depending on the purpose. In addition, a step of forming a pattern may be further performed.

In the step of forming the near infrared absorbing composition layer, as a method of applying the near infrared absorbing composition, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using metal or the like; and a nanoimprint lithography method. The application method using an ink jet method is not particularly limited as long as the near infrared absorbing composition can be ejected using this method, and examples thereof include a method (in particular, pp. 115 to 133) described in “Extension of Use of Ink Jet—Infinite Possibilities in Patent-” (February, 2005, S.B. Research Co., Ltd.) and methods described in JP2003-262716A, JP2003-185831A, JP2003-261827A, JP2012-126830A, and JP2006-169325A in which a composition to be ejected is replaced with the near infrared absorbing composition according to the present invention. In a case where the drop casting method is used, it is preferable that a drop range of the near infrared absorbing composition in which a photoresist is used as a partition wall is formed on the support such that a film having a predetermined uniform thickness can be obtained. A desired thickness can be obtained by adjusting the drop amount and solid content concentration of the near infrared absorbing composition and the area of the drop range. The thickness of the dried film is not particularly limited and can be appropriately selected depending on the purpose.

The support may be a transparent substrate such as glass. In addition, the support may be a solid image pickup element. In addition, the support may be another substrate that is provided on a light receiving side of a solid image pickup element. In addition, the support may be a planarizing layer or the like that is provided on a light receiving side of a solid image pickup element.

In the step of drying the near infrared absorbing composition layer, drying conditions vary depending on the kinds of the respective components and the solvent, ratios therebetween, and the like. For example, it is preferable that the film is dried at a temperature of 60° C. to 150° C. for 30 seconds to 15 minutes.

Examples of a method used in the step of forming a pattern include a method including: a step of applying the near infrared absorbing composition according to the present invention to a support or the like to form a composition layer having a film shape (near infrared absorbing composition layer); a step of exposing the composition layer in a pattern shape; and a step of forming a pattern by removing a non-exposed portion by development. In the step of forming a pattern, a pattern may be formed using a photolithography method or using a dry etching method.

The method of manufacturing a near infrared cut filter may include other steps. The other steps are not particularly limited and can be appropriately selected depending on the purpose. Examples of the other steps include a substrate surface treatment step, a pre-heating step (pre-baking step), a curing step, and a post-heating step (post-baking step).

<<Pre-Heating Step and Post-Heating Step>>

A heating temperature in the pre-heating step and the post-heating step is preferably 80° C. to 200° C. The upper limit is preferably 150° C. or lower. The lower limit is preferably 90° C. or higher. In addition, a heating time in the pre-heating step and the post-heating step is preferably 30 seconds to 240 seconds. The upper limit is preferably 180 seconds or shorter. The lower limit is preferably 60 seconds or longer.

<<Curing Step>>

By performing the curing step, the mechanical strength of the near infrared cut filter is improved. The curing step is not particularly limited and can be appropriately selected depending on the purpose. For example, an exposure treatment or a heating treatment is preferably used. Here, in the present invention, “exposure” denotes irradiation of not only light at various wavelengths but also radiation such as an electron beam or an X-ray.

It is preferable that exposure is performed by irradiation of radiation. As the radiation which can be used for exposure, ultraviolet light such as an electron beam, KrF, ArF, a g-ray, a h-ray, or an i-ray or visible light is preferably used. Examples of an exposure type include exposure using a stepper and exposure using a high-pressure mercury lamp. The exposure dose is preferably 5 to 3000 mJ/cm². The upper limit is preferably 2000 mJ/cm² or lower and more preferably 1000 mJ/cm² or lower. The lower limit is preferably 10 mJ/cm² or higher and more preferably 50 mJ/cm² or higher. Examples of an exposure method include a method of exposing the entire area of the formed film. By exposing the entire area of the formed film, a crosslinking reaction of a crosslinking component is promoted, the curing of the film further progresses, and mechanical strength and durability are improved. An exposure device is not particularly limited and can be appropriately selected depending on the purpose, and examples thereof include an ultraviolet exposure device such as an ultrahigh pressure mercury lamp.

Examples of a method for the heat treatment include a method of heating the entire area of the formed film. Due to the heat treatment, the film hardness of the pattern is improved. The heating temperature is preferably 100° C. to 260° C. The lower limit is preferably 120° C. or higher and more preferably 160° C. or higher. The upper limit is preferably 240° C. or lower and more preferably 220° C. or lower. In a case where the heating temperature is in the above-described range, a film having excellent strength is likely to be obtained. The heating time is preferably 1 to 180 minutes. The lower limit is preferably 3 minutes or longer. The upper limit is preferably 120 minutes or shorter. A heater can be appropriately selected from well-known devices without any particular limitation, and examples thereof include a dry oven, a hot plate, and an infrared heater.

<Solid Image Pickup Element and Camera Module>

A solid image pickup element according to the present invention includes the film or the near infrared cut filter according to the present invention. In addition, a camera module according to the present invention includes the film or the near infrared cut filter according to the present invention.

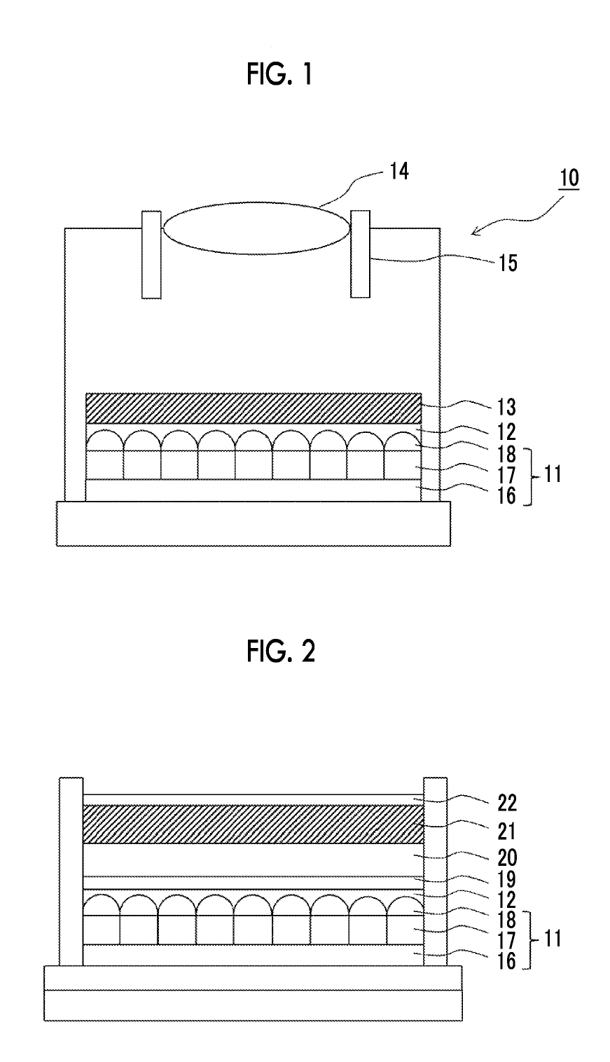

FIG. 1 is a schematic cross-sectional view showing a configuration of a camera module including a near infrared cut filter according to an embodiment of the present invention.

A camera module 10 shown in FIG. 1 includes: a solid image pickup element 11; a planarizing layer 12 that is provided on a main surface side (light receiving side) of the solid image pickup element 11; a near infrared cut filter 13; and a lens holder 15 that is disposed above the near infrared cut filter 13 and has an imaging lens 14 in an internal surface. In the camera module 10, an incidence ray hv incident from the outside reaches an image pickup element portion of the solid image pickup element 11 after sequentially passing through the imaging lens 14, the near infrared cut filter 13, and the planarizing layer 12.

For example, the solid image pickup element 11 includes a photodiode (not shown), an interlayer insulator (not shown), a base layer (not shown), color filters 17, an overcoat (not shown), and microlenses 18 that are formed in this order on a main surface (upper surface in FIG. 1) of a substrate 16. The color filters 17 (a red color filter, a green color filter, a blue color filter) and the microlenses 18 are disposed respectively corresponding to the solid image pickup element 11. In addition, instead of providing the near infrared cut filter 13 on the surface of the planarizing layer 12, the near infrared cut filter 13 may be formed on a surface of the microlenses 18, between the base layer and the color filters 17, or between the color filters 17 and the overcoat. For example, the near infrared cut filter 13 may be provided at a position at a distance of less than 2 mm (more preferably 1 mm) from the surfaces of the microlenses 18. By providing the near infrared cut filter at this position, the step of forming the near infrared cut filter 13 can be simplified, and unnecessary near infrared light for the microlens 18 can be sufficiently cut. Therefore, infrared shielding properties can be further improved.

The film or the near infrared cut filter according to the present invention has excellent heat resistance and thus can be provided for a solder reflow step. By manufacturing a camera module through the solder reflow step, automatic packaging of an electronic component packaging substrate or the like where soldering is required to be performed can be realized, and thus productivity can be significantly improved compared to a case where the solder reflow step is not used. Further, since automatic packaging can be performed, the cost can be reduced. In a case where the near infrared cut filter according to the present invention is provided for the solder reflow step, the near infrared cut filter is exposed to a temperature of about 250° C. to 270° C. Therefore, it is preferable that the near infrared cut filter has enough heat resistance to withstand the solder reflow step (hereinafter, also referred to as “solder reflow resistance”). In this specification, “having solder reflow resistance” represents that the properties as the near infrared cut filter can be maintained before and after heating at 180° C. for 1 minute. It is preferable that the properties as the near infrared cut filter can be maintained before and after heating at 230° C. for 10 minutes. It is more preferable that the properties as the near infrared cut filter can be maintained before and after heating at 250° C. for 3 minutes. In a case where the near infrared cut filter does not have solder reflow resistance, when the near infrared cut filter is held under the above-described conditions, infrared shielding properties may deteriorate, or a function as a film may be insufficient.

The camera module may further include an ultraviolet absorbing layer. According to this aspect, ultraviolet shielding properties can be improved. The details of the ultraviolet absorbing layer can be found in paragraphs “0040” to “0070” and paragraphs “0119” of “0145” of WO2015/099060, the content of which is incorporated herein by reference. In addition, the camera module may further include an ultraviolet-infrared reflection film described below. Both the ultraviolet absorbing layer and the ultraviolet-infrared reflection film may be used in combination, or only one of the ultraviolet absorbing layer or the ultraviolet-infrared reflection film may be used.

FIGS. 2 to 4 are schematic cross-sectional views showing an example of the vicinity of the near infrared cut filter in the camera module.

As shown in FIG. 2, the camera module includes the solid image pickup element 11, the planarizing layer 12, an ultraviolet-infrared reflection film 19, a transparent substrate 20, a near infrared light absorbing layer (near infrared cut filter) 21, and an antireflection layer 22 in this order. The ultraviolet-infrared reflection film 19 has an effect of imparting or improving an effect of the near infrared cut filter. For example, the details of the ultraviolet-infrared reflection film 19 can be found in paragraphs “0033” to “0039” of JP2013-68688A and paragraphs “0110” to “0114” of WO2015/099060, the content of which is incorporated herein by reference. The transparent substrate 20 allows transmission of light in a visible range. For example, the details of the transparent substrate 20 can be found in paragraphs “0026” to “0032” of JP2013-68688A, the content of which is incorporated herein by reference. The near infrared light absorbing layer 21 can be formed by applying the near infrared absorbing composition according to the present invention. The antireflection layer 22 has a function of preventing reflection of light incident on the near infrared cut filter to improve the transmittance and to effectively utilize the incidence ray. For example, the details of the antireflection layer 22 can be found in paragraph “0040” of JP2013-68688A, the content of which is incorporated herein by reference.

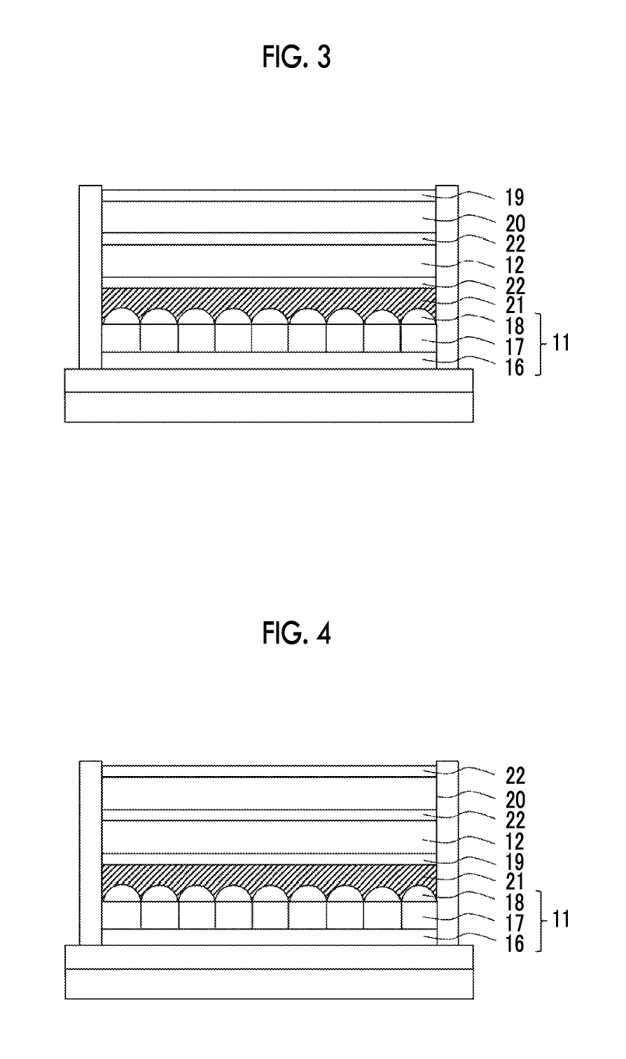

As shown in FIG. 3, the camera module may include the solid image pickup element 11, the near infrared light absorbing layer (near infrared cut filter) 21, the antireflection layer 22, the planarizing layer 12, the antireflection layer 22, the transparent substrate 20, and the ultraviolet-infrared reflection film 19 in this order.

As shown in FIG. 4, the camera module may include the solid image pickup element 11, the near infrared light absorbing layer (near infrared cut filter) 21, the ultraviolet-infrared reflection film 19, the planarizing layer 12, the antireflection layer 22, the transparent substrate 20, and an antireflection layer 22 in this order.

<Image Display Device>

An image display device includes the film or the near infrared cut filter according to the present invention. The film or the near infrared cut filter according to the present invention can also be used in an image display device such as a liquid crystal display device or an organic electroluminescence (organic EL) display device. For example, by using the near infrared cut filter in combination with the respective colored pixels (for example, red, green, blue), the near infrared cut filter can be used for the purpose of shielding infrared light included in light emitted from a backlight (for example, a white light emitting diode (white LED)) of a display device to prevent a malfunction of a peripheral device, or for the purpose of forming an infrared pixel in addition to the respective color display pixels.

The definition of a display device and the details of each display device can be found in, for example, “Electronic Display Device (by Akiya Sasaki, Kogyo Chosakai Publishing Co., Ltd., 1990)” or “Display Device (Sumiaki Ibuki, Sangyo Tosho Co., Ltd.). In addition, the details of a liquid crystal display device can be found in, for example, “Next-Generation Liquid Crystal Display Techniques (Edited by Tatsuo Uchida, Kogyo Chosakai Publishing Co., Ltd., 1994)”. The liquid crystal display device to which the present invention is applicable is not particularly limited. For example, the present invention is applicable to various liquid crystal display devices descried in “Next-Generation Liquid Crystal Display Techniques”.

The image display device may include a white organic EL element. It is preferable that the white organic EL element has a tandem structure. The tandem structure of the organic EL element is described in, for example, JP2003-45676A, or pp. 326-328 of “Forefront of Organic EL Technology Development—Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples. Unless specified otherwise, “part(s)” and “%” represent “part(s) by mass” and “mass %”.

<Measurement of Weight-Average Molecular Weight (Mw)>

The weight-average molecular weight (Mw) was measured using the following method.

Kind of Column: TSKgel Super AWM-H (manufactured by Tosoh Corporation, 6.0 mm (Inner diameter)×15.0 cm)

Developing Solvent: a 10 mmol/L lithium bromide N-methylpyrrolidinone (NMP) solution

Column temperature: 40° C.

Flow rate (sample injection volume): 10 μL

Device name: HLC-8220 GPC (manufactured by Tosoh Corporation)

Calibration curve base resin: polystyrene

<Measurement of Radical Generating Temperature of Resin>

The radical generating temperature of a resin was measured by electron spin resonance (ESR).

For the ESR measurement, EMX (manufactured by Bruker Biospin) and microwaves of X-band (9.4 GHz) were used. For the heating measurement, a variable temperature control unit ER4131VT (manufactured by Bruker Biospin) was used.

<Preparation of Near Infrared Absorbing Composition>

Materials shown below were mixed in mixing amounts shown below in a table to prepare a near infrared absorbing composition. Proportions of respective components in the table is proportions (mass %) with respect to solid content.

TABLE 1

| | | | | | | | Radical | | | | | | | |
|---|---|---|---|---|---|---|---|---|---|---|---|---|---|---|
| | Copper | | Copper | | | | Trapping | | | | Crosslinking | | | |
| | Compound 1 | | Compound 2 | | Resin | | Agent | | Catalyst | | Compound | | | Solid |
| | | Content | | Content | | Content | | Content | | Content | | Content | | content |
| | | (mass | | (mass | | (mass | | (mass | | (mass | | (mass | | (mass |
| | Kind | %) | Kind | %) | Kind | %) | Kind | %) | Kind | %) | Kind | %) | Solvent | %) |
| Example 1 | Cu1 | 40 | — | — | P1 | 54.9 | R1 | 5 | Al(acac)3 | 0.1 | | | XAN | 30 |
| Example 2 | Cu1 | 40 | — | — | P1 | 54.9 | R2 | 5 | Al(acac)3 | 0.1 | | | XAN | 30 |
| Example 3 | Cu1 | 40 | — | — | P1 | 54.9 | R3 | 5 | Al(acac)3 | 0.1 | | | XAN | 30 |
| Example 4 | Cu1 | 40 | — | — | P1 | 54.9 | R4 | 5 | Al(acac)3 | 0.1 | | | XAN | 30 |
| Example 5 | Cu1 | 40 | — | — | P1 | 54.9 | R5 | 5 | Al(acac)3 | 0.1 | | | XAN | 30 |
| Example 6 | Cu1 | 40 | — | — | P1 | 54.9 | R6 | 5 | Al(acac)3 | 0.1 | | | XAN | 30 |
| Example 7 | Cu1 | 40 | — | — | P1 | 54.9 | R7 | 5 | Al(acac)3 | 0.1 | | | XAN | 30 |
| Example 8 | Cu1 | 40 | — | — | P2 | 54.9 | R1 | 5 | Al(acac)3 | 0.1 | | | XAN | 30 |
| Example 9 | Cu1 | 40 | — | — | P3 | 54.9 | R1 | 5 | Al(acac)3 | 0.1 | | | XAN | 30 |
| Example 10 | Cu1 | 40 | — | — | P2 | 19.9 | R1 | 5 | Al(acac)3 | 0.1 | S1 | 35 | XAN | 30 |
| Example 11 | Cu1 | 40 | — | — | P3 | 19.9 | R1 | 5 | Al(acac)3 | 0.1 | S1 | 35 | XAN | 30 |
| Example 12 | Cu1 | 40 | — | — | P4 | 54.9 | R1 | 5 | Al(acac)3 | 0.1 | | | XAN | 30 |
| Example 13 | Cu1 | 40 | — | — | P5 | 54.9 | R1 | 5 | Al(acac)3 | 0.1 | | | AN | 30 |
| Example 14 | Cu1 | 40 | — | — | P6 | 54.9 | R1 | 5 | Al(acac)3 | 0.1 | | | XAN | 30 |
| Example 15 | Cu1 | 40 | — | — | P7 | 54.9 | R1 | 5 | Al(acac)3 | 0.1 | | | XAN | 30 |
| Example 16 | Cu1 | 40 | — | — | P8 | 54.9 | R1 | 5 | Al(acac)3 | 0.1 | | | XAN | 30 |
| Example 17 | Cu1 | 40 | — | — | P9 | 54.9 | R1 | 5 | Al(acac)3 | 0.1 | | | XAN | 30 |
| Example 18 | Cu1 | 40 | — | — | P10 | 54.9 | R1 | 5 | Al(acac)3 | 0.1 | | | XAN | 30 |
| Example 19 | Cu1 | 40 | — | — | P11 | 54.9 | R1 | 5 | Al(acac)3 | 0.1 | | | XAN | 30 |
| Example 20 | Cu1 | 40 | — | — | P12 | 54.9 | R1 | 5 | Al(acac)3 | 0.1 | | | XAN | 30 |
| Example 21 | Cu1 | 40 | — | — | P13 | 54.9 | R1 | 5 | Al(acac)3 | 0.1 | | | XAN | 30 |
| Example 22 | Cu1 | 40 | — | — | P1 | 54.9 | R1 | 2.5 | Al(acac)3 | 0.1 | | | XAN | 30 |
| Example 23 | Cu1 | 40 | — | — | P1 | 54.9 | R1 | 10 | Al(acac)3 | 0.1 | | | XAN | 30 |
| Example 24 | Cu2 | 40 | — | — | P1 | 54.9 | R1 | 5 | Al(acac)3 | 0.1 | | | XAN | 30 |
| Example 25 | Cu3 | 40 | — | — | P1 | 54.9 | R1 | 5 | Al(acac)3 | 0.1 | | | XAN | 30 |
| Example 26 | Cu4 | 40 | — | — | P1 | 54.9 | R1 | 5 | Al(acac)3 | 0.1 | | | XAN | 30 |
| Example 27 | Cu5 | 40 | — | — | P1 | 54.9 | R1 | 5 | Al(acac)3 | 0.1 | | | XAN | 30 |
| Example 28 | Cu1 | 40 | — | — | P1 | 54.9 | R8 | 5 | Al(acac)3 | 0.1 | | | XAN | 30 |
| Example 29 | Cu1 | 40 | — | — | P1 | 54.9 | R9 | 5 | Al(acac)3 | 0.1 | | | XAN | 30 |
| Example 30 | Cu1 | 40 | — | — | P1 | 54.9 | R10 | 5 | Al(acac)3 | 0.1 | | | XAN | 30 |
| Example 31 | Cu1 | 40 | — | — | P1 | 54.9 | R11 | 5 | Al(acac)3 | 0.1 | | | XAN | 30 |
| Example 32 | Cu1 | 40 | — | — | P1 | 49.4 | R1 | 5 | Al(acac)3 | 0.1 | S2 | 5.5 | XAN | 30 |
| Example 33 | Cu1 | 40 | — | — | P1 | 49.4 | R1 | 5 | Al(acac)3 | 0.1 | S3 | 5.5 | XAN | 30 |
| Example 34 | Cu1 | 20 | Cu6 | 20 | P1 | 54.9 | R1 | 5 | Al(acac)3 | 0.1 | | | XAN | 30 |
| Example 35 | Cu1 | 20 | Cu7 | 20 | P1 | 54.9 | R1 | 5 | Al(acac)3 | 0.1 | | | XAN | 30 |
| Example 36 | Cu1 | 20 | Cu8 | 20 | P1 | 54.9 | R1 | 5 | Al(acac)3 | 0.1 | | | XAN | 30 |
| Example 37 | Cu1 | 20 | Cu9 | 20 | P1 | 54.9 | R1 | 5 | Al(acac)3 | 0.1 | | | XAN | 30 |
| Comparative | Cu1 | 40 | — | — | P1 | 59.9 | — | — | Al(acac)3 | 0.1 | | | XAN | 30 |
| Example 1 | | | | | | | | | | | | | | |

(Copper Compound)

Cu1: The Following Structure

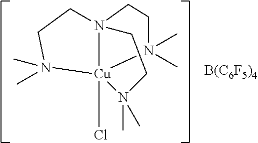

The following compound (A2-14) and copper (II) chloride dihydrate (manufactured by Wako Pure Chemical Industries, Ltd.) were mixed with each other in methanol at a molar ratio of 1:1 and were stirred for 10 minutes. This reaction solution was dried under a reduced pressure to obtain solid matter. The obtained solid matter was dissolved in water, and an excess amount of a lithium tetrakis(pentafluorophenyl)borate (manufactured by Tokyo Chemical Industry Co., Ltd.) aqueous solution was added to the solution while stirring them. The precipitated solid was collected by filtration. As a result a copper complex Cu1 was obtained.

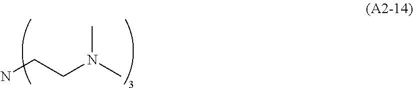

Cu2: The Following Structure

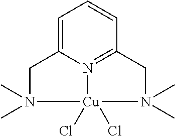

38 mg of the following compound A3-23 and 1 mL of methanol were put into a flask, and 34 mg of copper (II) chloride dihydrate (manufactured by Wako Pure Chemical Industries, Ltd.) was added to the solution while stirring them at room temperature, and then the solution was stirred for 10 minutes. The obtained blue solution was dried under reduced pressure. As a result, a copper complex Cu2 was obtained as a green solid. “rt” represents room temperature.

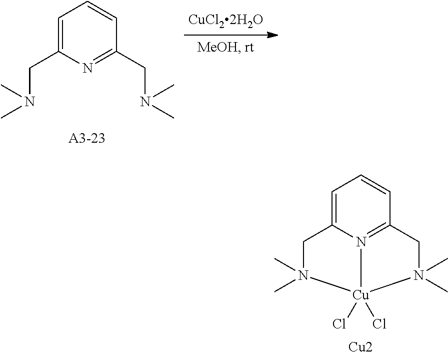

Cu3: The Following Structure

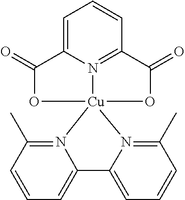

1.99 g of copper (II) acetate monohydrate (Cu(OAc)₂.H₂O), 1.67 g of the following compound A3-59 (manufactured by Wako Pure Chemical Industries, Ltd.), and 20 mL of methanol (MeOH) were put into a flask and were heated to reflux for 10 minutes. 1.84 g of the following compound A2-15 (manufactured by Tokyo Chemical Industry Co., Ltd.) was added to the solution and was further heated to reflux for 10 minutes. The solution was concentrated to about 5 mL under a reduced pressure, and then 20 mL of water was added. The precipitated solid was collected by filtration. As a result a copper complex Cu3 was obtained as a blue solid.

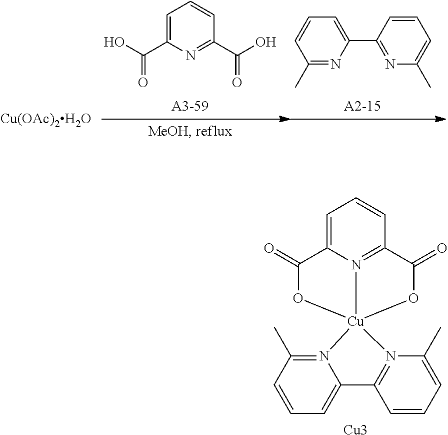

Cu4: A Copper Complex Including the Following Compound as a Ligand

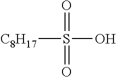

Cu5: A Copper Complex Including the Following Compound as a Ligand

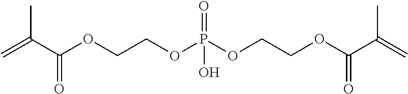 [SMILES: C=C(C)C(=O)OCCOP(=O)(O)OCCOC(=O)C(=C)C]

Cu6: The Following Structure

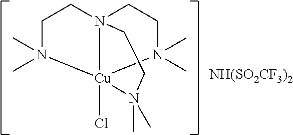

A copper complex Cu6 was synthesized using the same method as that of the copper complex Cu1, except that lithium bis(trifluoromethanesulfonyl)imide (manufactured by Mitsubishi Materials Corporation) was used instead of lithium tetrakis(pentafluorophenyl)borate. By adding water dropwise after the reaction, the solid was not sufficiently precipitated. Therefore, the solution was concentrated under a reduced pressure at 70° C. and was cooled to 0° C. As a result, crystals of the copper complex Cu6 were obtained.

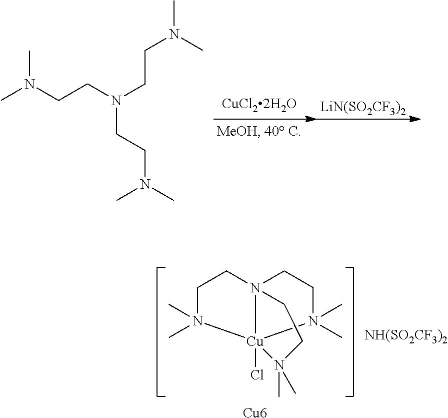

Cu7: The Following Structure

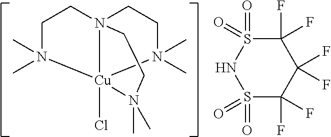

A copper complex Cu7 was synthesized using the same method as that of the copper complex Cu1, except that potassium 1,1,2,2,3,3-hexafluoropropane-1,3-bis(sulfonyl)imide (manufactured by Mitsubishi Materials Corporation) was used instead of lithium tetrakis(pentafluorophenyl)borate. By adding water dropwise after the reaction, the solid was not sufficiently precipitated. Therefore, the solution was concentrated under a reduced pressure at 70° C. and was cooled to 0° C. As a result, crystals of the copper complex Cu7 were obtained.

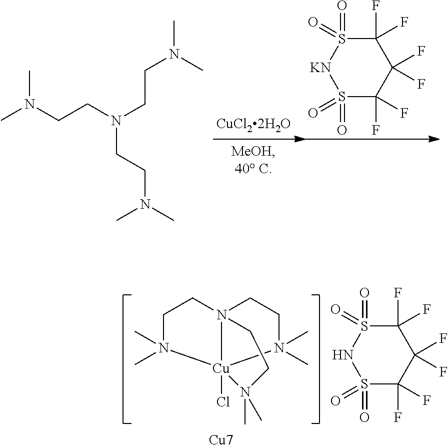

Cu8: The Following Structure

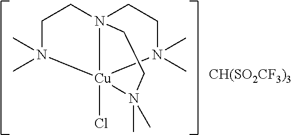

A copper complex Cu8 was synthesized using the same method as that of the copper complex Cu1, except that potassium tris(trifluoromethanesulfonyl)methide (manufactured by Central Glass Co., Ltd.) was used instead of lithium tetrakis(pentafluorophenyl)borate.

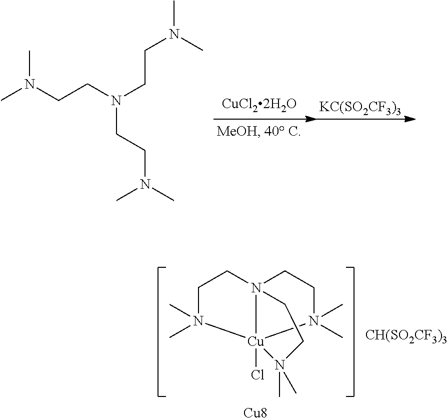

Cu9: The Following Structure

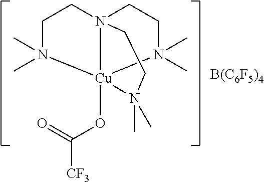

0.60 g of basic copper carbonate (copper content: 56.2%, manufactured by Kanto Chemical Co., Inc.) and 15 mL of water were put into a 200 mL three-neck flask, 1.24 g of trifluoroacetic acid was added dropwise while stirring them at room temperature, 5 mL of methanol was added, and the solution was stirred at 60° C. for 30 minutes. 1.34 g of tris[2-(dimethylamino)ethyl]amine (Me₆tren; manufactured by Tokyo Chemical Industry Co., Ltd.) was added dropwise to the solution, 5 mL of methanol was added, the solution was stirred at 0° C. for 30 minutes, and 50 mL of methanol was further added. 3.56 g of lithium tetrakis(pentafluorophenyl)borate (water content: 8.0 wt %, manufactured by Tosoh Finechem Corporation) was dissolved in 10 mL of methanol, this solution was added dropwise to the reaction solution, and the solution was stirred at 60° C. for 30 minutes. 35 mL of water was added dropwise to the obtained solution, and the precipitated solid was collected by filtration. As a result, a copper complex Cu9 was obtained as a blue solid.

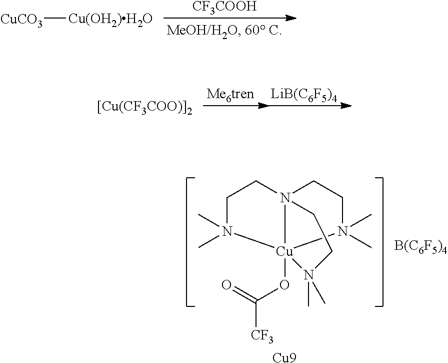

(Resin)

P1: DMSMA:DMAAm=43:57 (mol %) (Mw=7000, radical detection temperature=180° C.)

P2: polyDMAAm (Mw=8000, radical detection temperature=190° C.)

P3: polyDEAAm (Mw=7000, radical detection temperature=190° C.)

P4: VDMS:DMAAm=43:57 (mol %) (Mw=5000, radical detection temperature=180° C.)

P5: DMSMA:PhMI=43:57 (mol %) (Mw=12000, radical detection temperature=180° C.)

P6: DMSMA:cHMI=43:57 (mol %) (Mw=10000, radical detection temperature=180° C.)

P7: DMSMA:MMI=43:57 (mol %) (Mw=7000, radical detection temperature=180° C.)

P8: DMSMA:AN=43:57 (mol %) (Mw=14000, radical detection temperature=180° C.)

P9: DMSMA:NVP=43:57 (mol %) (Mw=7000, radical detection temperature=180° C.)

P10: DMSMA:NVAAm=43:57 (mol %) (Mw=6000, radical detection temperature=180° C.)

P11: DMSMA: 3-BLMA=43:57 (mol %) (Mw=8000, radical detection temperature=180° C.)

P12: DMSMA:PCMA=43:57 (mol %) (Mw=10000, radical detection temperature=180° C.)

P13: the following structure (n:m=43:57 (molar ratio), Mw=8000, radical detection temperature=180° C.)

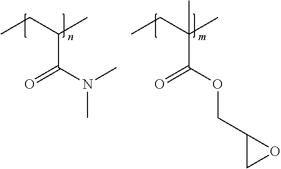

DMSMA: 3-(dimethoxymethylsilyl)propyl methacrylate

VDMS: dimethoxymethylvinylsilane

DMAAm: N,N-dimethylacrylamide

DEAAm: N,N-diethylacrylamide

PhMi: N-phenylmaleimide

cHMI: N-cyclohexylmaleimide

MMI: N-methylmaleimide

AN: acrylonitrile

NVP: N-vinylpyrrolidone

NVAAm: N-vinylacetamide

β-BLMA: β-lactone methacrylate

PCMA: propylene carbonate methacrylate

### (Radical Trapping Agent)

R1 to R11: The Following Structures

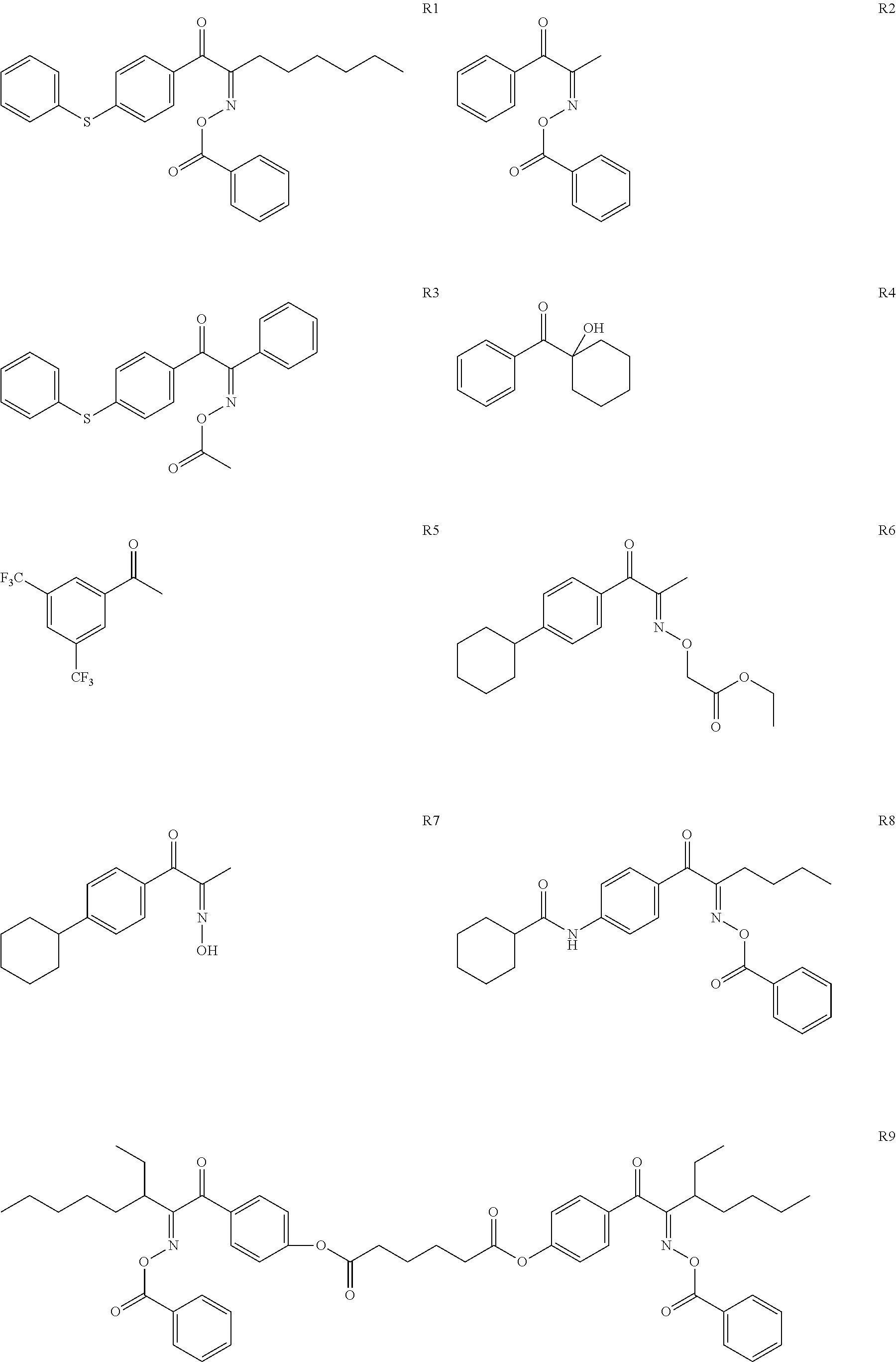

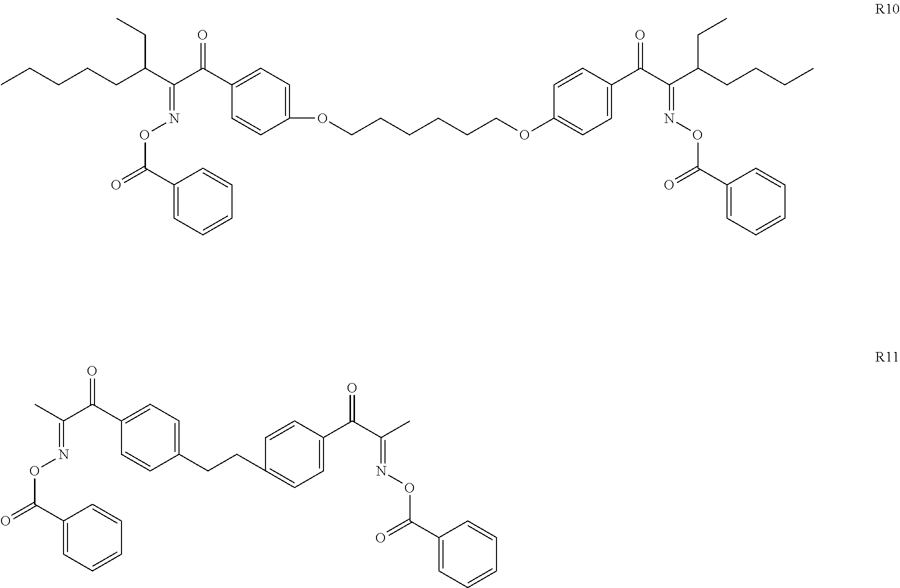 [SMILES: CCCCCC(CC)/C(=N\OC(=O)c1ccccc1)C(=O)c1ccc(OCCCCCCOc2ccc(C(=O)/C(=N/OC(=O)c3ccccc3)C(CC)CCCC)cc2)cc1 ; C/C(=N\OC(=O)c1ccccc1)C(=O)c1ccc(CCc2ccc(C(=O)/C(C)=N/OC(=O)c3ccccc3)cc2)cc1]

(Method of Radical Trapping Agent R8)

5.07 g of a compound R8-a (manufactured by Tokyo Chemical Industry Co., Ltd.), 3.21 g of triethylamine, and 100 mL of tetrahydrofuran (dehydrated) were put into a 300 mL three-neck flask in a nitrogen atmosphere, 4.27 g of cyclohexanecarbonyl chloride (manufactured by Tokyo Chemical Industry Co., Ltd.) was added dropwise while stirring them at 0° C., and the solution was heated to room temperature and was stirred for 1 hour. By adding 150 mL of water, a solid was precipitated, and the precipitated solid was collected by filtration. As a result, 7.8 g of R8-b was obtained as a white solid.

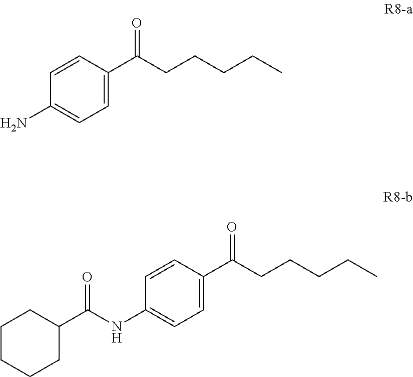 [SMILES: CCCCCC(=O)c1ccc(N)cc1 ; CCCCCC(=O)c1ccc(NC(=O)C2CCCCC2)cc1]

3.01 g of a compound R8-b and 60 mL of tetrahydrofuran were put into a 200 mL three-neck flask in a nitrogen atmosphere, 1.66 mL of concentrated hydrochloric acid (37 wt %) was added dropwise while stirring them at 0° C., and the solution was stirred at 0° C. for 30 minutes. 1.44 g of hexyl nitrite (manufactured by Tokyo Chemical Industry Co., Ltd.) and 4 mL of tetrahydrofuran were added to the solution, and the solution was stirred at room temperature for 8 hours. Water was added to the reaction solution, and liquid-liquid extraction was performed three times using ethyl acetate. As a result, an organic phase was obtained. The obtained organic phase was preliminarily dried using anhydrous magnesium sulfate, and then was concentrated under a reduced pressure to obtain brown oil. The obtained brown oil was purified by silica gel column chromatography (developing solvent: ethyl acetate/hexane mixed solution). As a result, 1.07 g of a compound R8-c was obtained.

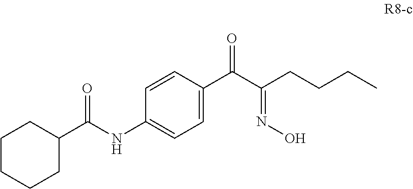 [SMILES: CCCC/C(=N\O)C(=O)c1ccc(NC(=O)C2CCCCC2)cc1]

0.33 g of the compound R8-c, 0.20 g of triethylamine, and 10 mL of tetrahydrofuran (dehydrated) were put into a 100 mL three-neck flask in a nitrogen atmosphere, 0.16 g of benzyl chloride was added dropwise while stirring them at 0° C., and the solution was heated to room temperature and was stirred for 4 hour. Saturated sodium bicarbonate aqueous solution was added to the reaction solution, and liquid-liquid extraction was performed three times using ethyl acetate. As a result, an organic phase was obtained. The obtained organic phase was preliminarily dried using anhydrous magnesium sulfate, and then was concentrated under a reduced pressure to obtain brown oil. The obtained brown oil was purified by silica gel column chromatography (developing solvent: ethyl acetate/hexane mixed solution). As a result, a compound R8 was obtained.

(Method of Radical Trapping Agent R⁹)

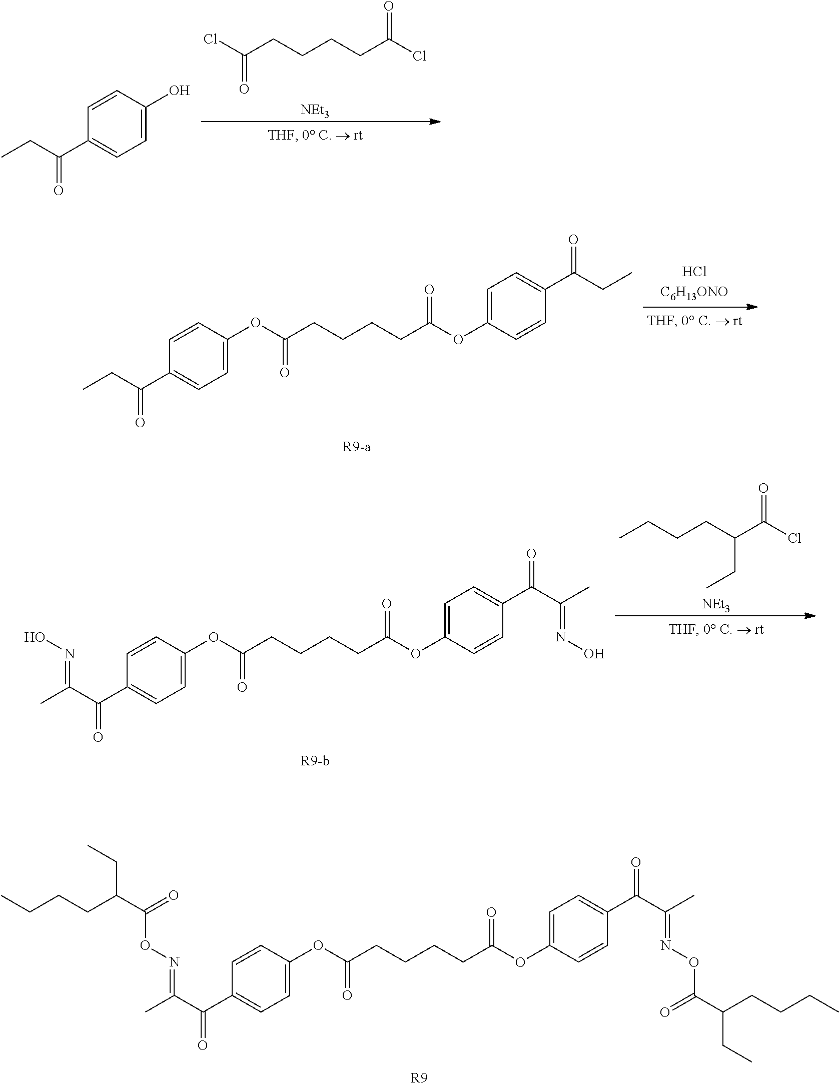

7.5 g of 4′-hydroxypropiophenone (manufactured by Tokyo Chemical Industry Co., Ltd.), 150 mL of tetrahydrofuran (dehydrated), and 8.0 g of triethylamine were put into a 300 mL three-neck flask in a nitrogen atmosphere, 6.07 g of Adipoyl Chloride (manufactured by Tokyo Chemical Industry Co., Ltd.) was added dropwise while stirring them at 0° C., and the solution was stirred at room temperature for 4 hours. By adding 100 mL of water, a solid was precipitated, and the precipitated solid was collected by filtration. As a result, 9.16 g of R9-a was obtained as a white solid.

4.1 g of R9-a and 40 mL of tetrahydrofuran were put into a 200 mL three-neck flask in a nitrogen atmosphere. 3.33 mL of concentrated hydrochloric acid was added dropwise while stirring them at 0° C., and the solution was stirred at 0° C. for 30 minutes. 2.88 g of hexyl nitrite was added dropwise to the solution, and the solution was stirred at room temperature for 5 hours. Water was added to the reaction solution, and liquid-liquid extraction was performed three times using ethyl acetate. As a result, an organic phase was obtained. The obtained organic phase was preliminarily dried using anhydrous magnesium sulfate, and then was concentrated under a reduced pressure to obtain yellow oil. The obtained yellow oil was purified by silica gel column chromatography (developing solvent: ethyl acetate/hexane mixed solution). As a result, 0.6 g of a compound R9-b was obtained.

0.13 g of R9-b, 20 mL of tetrahydrofuran (THF; dehydrated), and 0.27 g of triethylamine (MEt₃) were put into a 100 mL three-neck flask in a nitrogen atmosphere. 0.20 g of 2-ethylhexanoyl chloride (manufactured by Tokyo Chemical Industry Co., Ltd.) was added dropwise while stirring them at 0° C., and the solution was stirred at room temperature for 5 hours. Saturated sodium bicarbonate aqueous solution was added to the reaction solution, and liquid-liquid extraction was performed three times using ethyl acetate. As a result, an organic phase was obtained. The obtained organic phase was preliminarily dried using anhydrous magnesium sulfate, and then was concentrated under a reduced pressure to obtain a crude product. The obtained crude product was purified by silica gel column chromatography (developing solvent: ethyl acetate/hexane mixed solution). As a result, 0.12 g of a compound R9 was obtained.

(Method of Radical Trapping Agent R10)

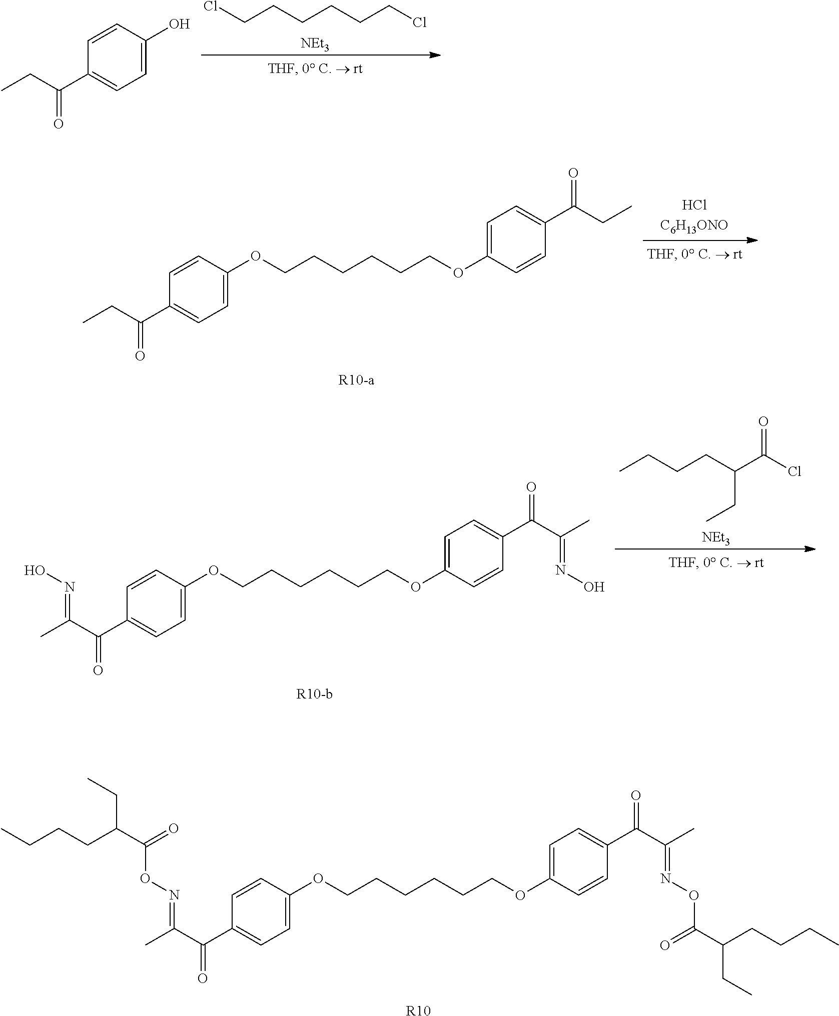

7.5 g of 4′-hydroxypropiophenone, 100 mL of N,N-dimethylformamide, 14.0 g of potassium carbonate, and 10.0 g of potassium iodide were put into a 300 mL three-neck flask in a nitrogen atmosphere and were stirred. 3.78 g of 1,6-dichlorohexane (manufactured by Tokyo Chemical Industry Co., Ltd.) was added to the solution, and the solution was stirred at 80° C. for 7 hours. 100 mL of water was put into a 500 mL three-neck flask and added dropwise to the reaction solution while stirring them. The precipitated solid was collected by filtration. As a result, R10-a was obtained as a white solid.

3.8 g of R10-a and 40 mL of tetrahydrofuran were put into a 200 mL three-neck flask in a nitrogen atmosphere. 3.33 mL of concentrated hydrochloric acid was added dropwise while stirring them at 0° C., and the solution was stirred at 0° C. for 30 minutes. 2.88 g of hexyl nitrite was added dropwise to the solution, and the solution was stirred at room temperature for 7 hours. 100 mL of water was added to the reaction solution, and the precipitated solid was collected by filtration. This crude product was recrystallized using tetrahydrofuran. As a result, 1.1 g of a compound R10-b was obtained.

0.66 g of R10-b, 50 mL of tetrahydrofuran (dehydrated), and 0.67 g of triethylamine were put into a 100 mL three-neck flask in a nitrogen atmosphere. 0.65 g of 2-ethylhexanoyl chloride was added dropwise while stirring them at 0° C., and the solution was stirred at room temperature for 5 hours. Saturated sodium bicarbonate aqueous solution was added to the reaction solution, and liquid-liquid extraction was performed three times using ethyl acetate. As a result, an organic phase was obtained. The obtained organic phase was preliminarily dried using anhydrous magnesium sulfate, and then was concentrated under a reduced pressure to obtain a crude product. The obtained crude product was purified by silica gel column chromatography (developing solvent: ethyl acetate/hexane mixed solution). As a result, 0.66 g of a compound R10 was obtained.

(Method of Radical Trapping Agent R11)

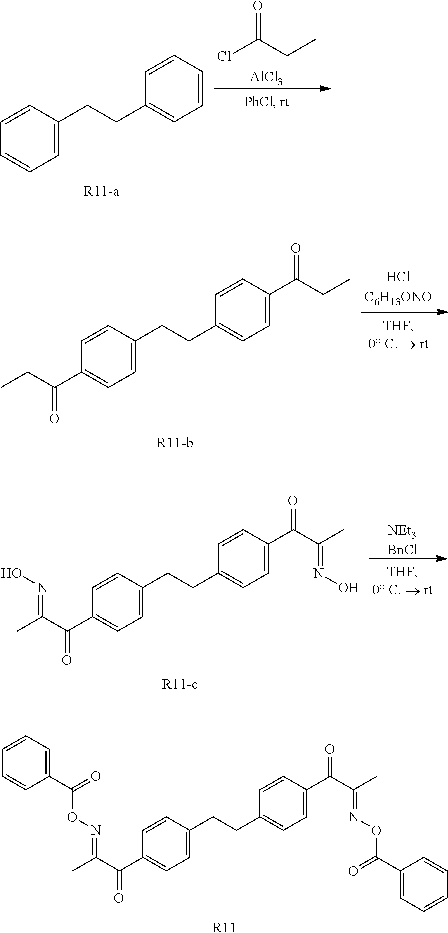

5.00 g of a compound R11-a (manufactured by Tokyo Chemical Industry Co., Ltd.) and 14.40 g of chlorobenzene were put into a 100 mL three-neck flask in a nitrogen atmosphere and were stirred. The solution was cooled with ice and was held at 10° C. or lower, 8.05 g of aluminum chloride was added, 5.58 g of propionyl chloride (manufactured by Wako Pure Chemical Industries, Ltd.), and the solution was stirred at room temperature for 5 hours. 27.4 g of 10% dilute hydrochloric acid was added to the reaction solution, and liquid-liquid extraction was performed three times using ethyl acetate. As a result, an organic phase was obtained. The obtained organic phase was preliminarily dried using anhydrous magnesium sulfate, and then was concentrated under a reduced pressure to obtain a crude product. The obtained crude product was purified by silica gel column chromatography (developing solvent: ethyl acetate/hexane). As a result, a compound R11-b was obtained.

4.50 g of a compound R11-b and 16.01 g of tetrahydrofuran were put into a 100 mL three-neck flask in a nitrogen atmosphere, and were stirred at 0° C. 6.37 g of concentrated hydrochloric acid (37 wt %) was added dropwise, and the solution was stirred at 0° C. for 30 minutes. 4.41 g of hexyl nitrite and 1.6 g of tetrahydrofuran were added to the solution, and the solution was stirred at room temperature for 2 hours. Water was added to the reaction solution, and the precipitated solid was collected by filtration. As a result, a compound R11-c was obtained.

1.00 g of the compound R11-c, 11.25 mL of tetrahydrofuran (dehydrated), and 0.69 g of triethylamine were added to a 100 mL three-neck flask in a nitrogen atmosphere and were cooled with ice. 0.96 g of benzyl chloride was added dropwise while stirring them at 50 C or lower, and the solution was stirred at room temperature for 1 hour. 10 mL of saturated sodium bicarbonate aqueous solution and 10 mL of ethyl acetate were added to the solution, and precipitated solid was collected by filtration. 150 mL of ethyl acetate was added to the solid, the solution was heated to a reflux temperature, and an insoluble component was separated by filtration. Next, the filtrate was concentrated and was cooled at 0° C. As a result, crystals precipitated, and 0.75 g of R¹¹ was obtained.

(Solvent)

XAN: cyclohexanone

### (Catalyst)

Al (acac)₃: aluminum tris(2,4-pentanedionate)

### (Crosslinking Compound)

S1: methyltriethoxysilane

S2: KBM-3066 (1,6-bis(trimethoxysilyl)hexane, manufactured by Shin-Etsu Chemical Co., Ltd.)

S3: KBM-9659 (tris-(trimethoxysilylpropyl)isocyanurate, manufactured by Shin-Etsu Chemical Co., Ltd.)

<Preparation of Near Infrared Cut Filter>

A near infrared cut filter was prepared using the near infrared absorbing composition.

Specifically, the obtained near infrared absorbing composition was applied to a glass wafer using a spin coater such that the thickness of the dried coating film was 100 μm, and then was heated using a hot plate at 150° C. for 3 hours. As a result, a near infrared cut filter was manufactured.

<<Evaluation of Infrared Shielding Properties>>

In the near infrared cut filter obtained as described above, a transmittance at a wavelength of 800 nm was measured using a spectrophotometer U-4100 (manufactured by Hitachi High-Technologies Corporation). The infrared shielding properties were evaluated based on the following standards. The results are shown in the following table.

A: transmittance at a wavelength of 800 nm≤5%

B: 5%<transmittance at a wavelength of 800 nm≤7%

C: 7%<transmittance at a wavelength of 800 nm≤10%

D: 10%<transmittance at a wavelength of 800 nm

<<Evaluation of Visible Transparency>>

In the near infrared cut filter obtained as described above, a transmittance in a wavelength range of 400 to 550 nm was measured using a spectrophotometer U-4100 (manufactured by Hitachi High-Technologies Corporation). The visible transparency was evaluated based on the following standards. The results are shown in the following table.

A: 97%≤minimum value of transmittance in a wavelength range of 400 to 550 nm

B: 95%≤minimum value of transmittance in a wavelength range of 400 to 550 nm<97%

C: 85%≤minimum value of transmittance in a wavelength range of 400 to 550 nm<95%

D: minimum value of transmittance in a wavelength range of 400 to 550 nm<85%

<<Evaluation of Heat Resistance (High Temperature, Short Time)>>

The near infrared cut filter obtained as described above was left to stand at 200° C. for 5 minutes (heat resistance test). Before and after the heat resistance test, an absorbance at 400 nm was measured, and a change rate of absorbance at 400 nm was obtained from “((Absorbance after Heat Resistance Test−Absorbance before Heat Resistance Test)/Absorbance before Heat Resistance Test)×100(%)”. The heat resistance was evaluated based on the following standards. In order to measure the absorbance, a spectrophotometer U-4100 (manufactured by Hitachi High-Technologies Corporation) was used.

A: Change Rate of Absorbance≤3%

B: 3%<Change Rate of Absorbance≤6%

C: 6%<Change Rate of Absorbance≤10%

D: 10%<Change Rate of Absorbance

<<Evaluation of Heat Resistance (Low Temperature, Long Time)>>

The near infrared cut filter obtained as described above was left to stand at 150° C. for 20 hours (heat resistance test). Before and after the heat resistance test, an absorbance at 400 nm was measured, and a change rate of absorbance at 400 nm was obtained from “((Absorbance after Heat Resistance Test−Absorbance before Heat Resistance Test)/Absorbance before Heat Resistance Test)×100(%)”. The heat resistance was evaluated based on the following standards. In order to measure the absorbance, a spectrophotometer U-4100 (manufactured by Hitachi High-Technologies Corporation) was used.

A: Change Rate of Absorbance≤3%

B: 3%<Change Rate of Absorbance≤6%

C: 6%<Change Rate of Absorbance≤10%

D: 10%<Change Rate of Absorbance

<<Evaluation of Moisture Resistance>>

The near infrared cut filter obtained as described above was left to stand in a high-temperature high-humidity environment of 85° C./relative humidity: 85% for 1 hour (moisture resistance test). Before and after the moisture resistance test, a maximum absorbance (Absλmax) of the near infrared cut filter in a wavelength range of 700 to 1400 nm and a minimum absorbance (Absλmin) in a wavelength range of 400 to 700 nm were measured using a spectrophotometer U-4100 (manufactured by Hitachi High-Technologies Corporation), and an absorbance ratio represented by “Absλmax/Absλmin” was obtained. A change rate of absorbance ratio represented by “|(Absorbance Ratio before Moisture Resistance Test−Absorbance Ratio after Moisture Resistance Test)×100|(%) was evaluated based on the following standards.

A: Change Rate of Absorbance Ratio≤2%

B: 2%<Change Rate of Absorbance Ratio≤4%

C: 4%<Change Rate of Absorbance Ratio≤7%

D: 7%<Change Rate of Absorbance Ratio

<<Evaluation of Solvent Resistance>>

The near infrared cut filter obtained as described above was dipped in methyl propylene glycol (MFG) at 25° C. for 2 minutes (solvent resistance test). Before and after the solvent resistance test, the absorbance of the near infrared cut filter at a wavelength of 800 nm was measured, and a change rate of the absorbance at a wavelength of 800 nm was obtained from the following expression. In order to measure the absorbance, a spectrophotometer U-4100 (manufactured by Hitachi High-Technologies Corporation) was used.

Change Rate (%) of Absorbance at Wavelength of 800 nm=|(Absorbance at Wavelength of 800 nm before Solvent Resistance Test−Absorbance at Wavelength of 800 nm after Solvent Resistance Test)/Absorbance at Wavelength of 800 nm before Solvent Resistance Test|×100(%)

The solvent resistance was evaluated based on the following standards.

A: Change Rate of Absorbance Ratio≤2%

B: 2%<Change Rate of Absorbance Ratio≤4%

C: 4%<Change Rate of Absorbance Ratio≤7%

D: 7%<Change Rate of Absorbance Ratio

TABLE 2

| | Heat Resistance | Heat Resistance | | | | |
|---|---|---|---|---|---|---|
| | (High | (Low | | | Infrared | |
| | Temperature, | Temperature, | Solvent | Moisture | Shielding | Visual |
| | Short Time) | Long Time) | Resistance | Resistance | Properties | Transparency |
| Example 1 | A | B | A | A | A | A |
| Example 2 | B | C | A | A | A | A |
| Example 3 | B | C | A | A | A | A |
| Example 4 | C | C | A | A | A | A |
| Example 5 | C | C | A | A | A | A |
| Example 6 | C | C | A | A | A | A |
| Example 7 | C | C | A | A | A | A |
| Example 8 | A | B | D | A | A | A |
| Example 9 | A | B | D | A | A | A |
| Example 10 | B | C | A | A | A | A |
| Example 11 | B | C | A | A | A | A |
| Example 12 | A | B | B | A | A | B |
| Example 13 | A | B | A | A | A | A |
| Example 14 | A | B | B | A | A | C |
| Example 15 | A | B | B | A | A | C |
| Example 16 | A | B | B | A | A | C |
| Example 17 | A | B | C | A | A | B |
| Example 18 | A | B | C | A | A | B |
| Example 19 | A | B | A | A | A | A |
| Example 20 | A | B | A | A | A | A |
| Example 21 | C | C | B | B | A | C |
| Example 22 | B | B | A | A | A | A |
| Example 23 | B | B | A | A | A | A |
| Example 24 | A | B | A | B | B | A |
| Example 25 | A | B | A | C | C | A |
| Example 26 | A | B | A | C | C | A |
| Example 27 | A | B | A | C | C | A |
| Example 28 | A | A | A | A | A | A |
| Example 29 | A | A | A | A | A | A |
| Example 30 | A | A | A | A | A | A |
| Example 31 | A | A | A | A | A | A |
| Example 32 | A | A | A | A | A | A |
| Example 33 | A | A | A | A | A | A |
| Example 34 | B | B | A | A | A | A |
| Example 35 | B | B | A | A | A | A |
| Example 36 | B | B | A | A | A | A |
| Example 37 | B | B | A | A | A | A |
| Comparative | D | D | A | A | A | A |
| Example 1 | | | | | | |

It was found based on the above results that, in Examples, discoloration caused by heating was small, and heat resistance was excellent. On the other hand, in Comparative Examples, discoloration caused by heating occurred, and heat resistance was poor.

In order to prepare each of near infrared cut filters according to Examples 1 to 37, a layer including an ultraviolet absorber was formed on a glass wafer described in paragraphs “0119” to “0140” of WO2015/099060. Each of the near infrared absorbing compositions according to Examples 1 to 37 was applied to a surface of the layer including the ultraviolet absorber using a spin coater such that the thickness of the dried coating film was 100 μm, and then was heated using a hot plate at 150° C. for 3 hours. As a result, a near infrared cut filter was manufactured. The near infrared cut filter prepared as described above also had excellent heat resistance.

### EXPLANATION OF REFERENCES

10: camera module
11: solid image pickup element
12: planarizing layer
13: near infrared cut filter
14: imaging lens
15: lens holder
16: substrate
17: color filter
18: microlens
19: ultraviolet-infrared reflection film
20: transparent substrate
21: near infrared light absorbing layer
22: antireflection layer

What is claimed is:

1. A near infrared absorbing composition comprising:
a copper compound;
a radical trapping agent; and
a resin which generates a radical at 180° C. or higher.

2. The near infrared absorbing composition according to claim 1,
wherein the copper compound is a copper complex which includes a compound having a carbon atom bonded to a hydrogen atom as a ligand.

3. The near infrared absorbing composition according to claim 1,
wherein the copper compound is a copper complex which includes a compound having a coordination site coordinated by an unshared electron pair as a ligand.

4. The near infrared absorbing composition according to claim 1,
wherein the copper compound is a copper complex which includes a compound having at least two coordination sites as a ligand.

5. The near infrared absorbing composition according to claim 1,
wherein the radical trapping agent is at least one selected from the group consisting of an oxime compound, a hindered amine compound, a hindered phenol compound, a sulfur-based peroxide decomposition product, a phosphorus-based peroxide decomposing agent, an N-oxyl compound, an alkylphenone compound, an aldehyde compound, and a hydroxylamine compound.

6. The near infrared absorbing composition according to claim 1,
wherein the radical trapping agent is a compound represented by the following Formula (I), and 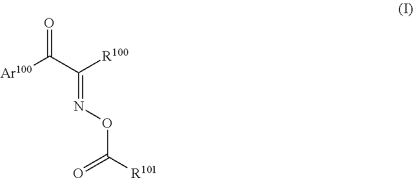
in Formula (I), Ar¹⁰⁰ represents an aryl group or a heterocyclic group, and R¹⁰⁰ and R¹⁰¹ each independently represent an alkyl group, an aryl group, or a heterocyclic group.

7. The near infrared absorbing composition according to claim 1,
wherein the radical trapping agent is an oxime compound having an amide type structure.

8. The near infrared absorbing composition according to claim 1,
wherein the radical trapping agent is an oxime compound having two or more partial structures represented by the following Formula (OX) in one molecule, and 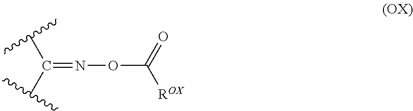
in Formula (OX), R^{OX} represents an alkyl group, an aryl group, or a heterocyclic group, and a wave line represents a linking site to an atomic group constituting the oxime compound.

9. The near infrared absorbing composition according to claim 1,
wherein a content of the radical trapping agent is 0.1 to 30 mass % with respect to a total solid content of the near infrared absorbing composition.

10. The near infrared absorbing composition according to claim 1,
wherein a content of the copper compound is 25 to 75 mass % with respect to a total solid content of the near infrared absorbing composition.

11. The near infrared absorbing composition according to claim 1,
wherein the resin which generates a radical at 180° C. or higher has a partial structure represented by the following (a) or (b) at a main chain or a side chain of a repeating unit, and 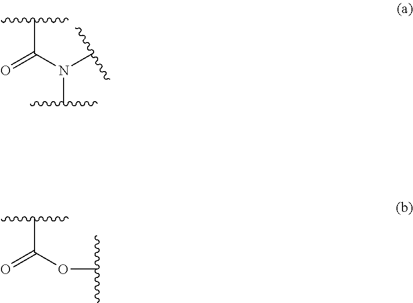
in (a) or (b), a wave line represents a linking site to an atomic group constituting the repeating unit of the resin.

12. The near infrared absorbing composition according to claim 1,
wherein the resin which generates a radical at 180° C. or higher includes a repeating unit represented by the following Formula (A), 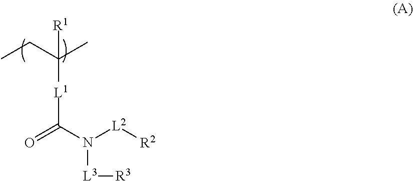
in Formula (A), R¹ represents a hydrogen atom or an alkyl group, L¹ to L³ each independently represent a single bond or a divalent linking group, R² and R³ each independently represent an aliphatic hydrocarbon group or an aromatic group,
R² may be bonded to a carbon atom of a main chain of the repeating unit or R³ to form a ring, and
L² may be bonded to a carbon atom of a main chain of the repeating unit to form a ring, and in a case where L² is bonded to a carbon atom of a main chain of the repeating unit to form a ring, R² is not present.

13. The near infrared absorbing composition according to claim 1,
wherein the resin which generates a radical at 180° C. or higher includes a repeating unit having a crosslinking group.

14. The near infrared absorbing composition according to claim 1, further comprising:
a compound having a crosslinking group as a component other than the resin which generates a radical at 180° C. or higher.

15. A film which is obtained using the near infrared absorbing composition according to claim 1.

16. A near infrared cut filter which is obtained using the near infrared absorbing composition according to claim 1.

17. A solid image pickup element comprising:
the near infrared cut filter according to claim 16.
